(19) United States
(12) Patent Application Publication
(10) Pub. No.: US 2022/0308446 A1
(43) Pub. Date: Sep. 29, 2022

(54) COLORING COMPOSITION, FILM, OPTICAL FILTER, SOLID-STATE IMAGING ELEMENT, AND IMAGE DISPLAY DEVICE

(71) Applicant: Fujifilm Corporation, Tokyo (JP)

(72) Inventors: Hiroaki IDEI, Haibara-gun (JP); Takashi KAWASHIMA, Haibara-gun (JP); Takuya TSURUTA, Haibara-gun (JP)

(73) Assignee: Fujifilm Corporation, Tokyo (JP)

(21) Appl. No.: 17/834,494

(22) Filed: Jun. 7, 2022

Related U.S. Application Data
(63) Continuation of application No. PCT/JP2020/044965, filed on Dec. 3, 2020.

(30) Foreign Application Priority Data
Dec. 10, 2019 (JP) 2019-222914
Oct. 21, 2020 (JP) 2020-176482

(51) Int. Cl. G03F 7/00; G03F 7/038; G03F 7/039; C09B 67/20; C09B 67/22; C09B 17/00; C09B 57/04; C09B 25/00; G02B 1/04; G02B 5/20

(52) U.S. Cl. CPC G03F 7/0007; G03F 7/038; G03F 7/039; C09B 67/0063; C09B 67/0033; C09B 17/00; C09B 57/04; C09B 25/00; G02B 1/04; G02B 5/208

(57) ABSTRACT

Provided are a coloring composition including a coloring material, a resin, and a solvent, in which the coloring material contains a pteridin pigment, and a content of the coloring material in a total solid content of the coloring composition is 40% by mass or more; a film formed of the coloring composition; an optical filter; a solid-state imaging element; and an image display device.

### CROSS-REFERENCE TO RELATED APPLICATIONS

This application is a Continuation of PCT International Application No. PCT/JP2020/044965 filed on Dec. 3, 2020, which claims priority under 35 U.S.C § 119(a) to Japanese Patent Application No. 2019-222914 filed on Dec. 10, 2019, and Japanese Patent Application No. 2020-176482 filed on Oct. 21, 2020. Each of the above application(s) is hereby expressly incorporated by reference, in its entirety, into the present application.

### BACKGROUND OF THE INVENTION

### 1. Field of the Invention

The present invention relates to a coloring composition including a coloring material. The present invention further relates to a film formed of the coloring composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Colored pixels of each color of the color filter are manufactured by using a coloring composition containing a coloring material. JP2010-044243A discloses an invention relating to a coloring composition for a color filter, which contains at least a pigment, a solvent, a dispersant, and a polymerizable monomer, in which the pigment contains Color Index Pigment Yellow 215 having an average primary particle diameter of 30 nm or less.

### SUMMARY OF THE INVENTION

In recent years, a film used in the optical filter or the like has been required to be thinner. In order to achieve a thin film while maintaining desired spectral characteristics, it is necessary to increase a concentration of a coloring material in a coloring composition used for film formation. However, in a case where the concentration of the coloring material in the coloring composition is increased, the coloring material and the like tend to aggregate and a viscosity tends to increase with time. In addition, in recent years, further improvement in temporal stability of the coloring composition has been desired.

Therefore, an object of the present invention is to provide a coloring composition having excellent temporal stability. Another object of the present invention is to provide a film formed of the coloring composition, an optical filter, a solid-state imaging element, and an image display device.

According to the studies conducted by the present inventors, it has been found that the above-described objects can be achieved by a coloring composition described below, thereby leading to the completion of the present invention. Therefore, the present invention provides the following.

<1> A coloring composition comprising:

a coloring material;

a resin; and

a solvent,

in which the coloring material contains a pteridin pigment, and

a content of the coloring material in a total solid content of the coloring composition is 40% by mass or more.

<2> The coloring composition according to <1>,

in which the pteridin pigment includes at least one selected from Color Index Pigment Yellow 215, a compound represented by Formula (pt-1), or a salt of the compound represented by Formula (pt-1),

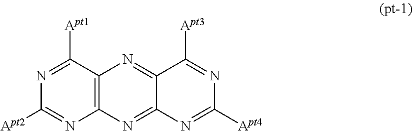

in the formula, A^{pt1} to A^{pt4} each independently represent a hydrogen atom, a hydroxy group, a thiol group, an alkyl group, an alkoxy group, an aryl group, an aryloxy group, or —NR^{pt1}R^{pt2},

R^{pt1} and R^{pt2} each independently represent a hydrogen atom, an alkyl group, an aryl group, —CO—R^{pt3}, —COO—R^{pt3}, or —CONH—R^{pt3}, and

R^{pt3} represents an alkyl group or an aryl group.

<3> The coloring composition according to <1> or <2>,

in which the coloring material further contains a yellow coloring material other than the pteridin pigment.

<4> The coloring composition according to <3>,

in which the yellow coloring material other than the pteridin pigment is at least one selected from an isoindoline compound or a quinophthalone compound.

<5> The coloring composition according to any one of <1> to <4>,

in which the coloring composition further includes at least one selected from a red coloring material or a green coloring material.

<6> The coloring composition according to any one of <1> to <5>,

in which the coloring composition contains the coloring material in an amount of 50% by mass or more in the total solid content of the coloring composition.

<7> The coloring composition according to any one of <1> to <6>,

in which the resin includes a resin having an aromatic carboxyl group.

<8> The coloring composition according to any one of <1> to <7>,

in which the resin includes a resin having an acid group and a resin having a basic group.

<9> The coloring composition according to any one of <1> to <8>, further comprising:

a polymerizable compound; and

a photopolymerization initiator.

<10> The coloring composition according to any one of <1> to <9>,

in which the coloring composition is used for a color filter or an infrared transmitting filter.

<11> A film obtained from the coloring composition according to any one of <1> to <10>.

<12> An optical filter comprising:

the film according to <11>.

<13> A solid-state imaging element comprising:

the film according to <11>.

<14> An image display device comprising:

the film according to <11>.

According to the present invention, it is possible to provide a coloring composition having excellent temporal stability. It is also possible is to provide a film formed of the coloring composition, an optical filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” is not only an independent step, but also includes a step which is not clearly distinguished from other steps in a case where an intended action of the step is obtained.

<Coloring Composition>

A coloring composition according to an embodiment of the present invention includes a coloring material, a resin, and a solvent, in which the coloring material contains a pteridin pigment, and a content of the coloring material in a total solid content of the coloring composition is 40% by mass or more.

With the coloring composition according to the embodiment of the present invention, by using a coloring material containing a pteridin pigment as the coloring material, even in a case where the content of the coloring material in the total solid content of the coloring composition is 40% by mass or more, a coloring composition having excellent temporal stability can be obtained. The detailed reason for obtaining such an effect is not clear, but in the coloring composition, a coloring agent skeleton portion of the pteridin pigment and the resin can interact with each other to improve dispersibility of the coloring material in the coloring composition. As a result, even in a case where the content of the coloring material in the total solid content of the coloring composition is increased, it is presumed that generation of aggregates or the like derived from the coloring material can be suppressed, so that increase in viscosity with time can be suppressed.

The coloring composition according to the embodiment of the present invention is preferably used as a coloring composition for a color filter or an infrared transmitting filter. More specifically, the coloring composition according to the embodiment of the present invention can be preferably used as a coloring composition for forming a pixel of a color filter or a coloring composition for forming an infrared transmitting filter.

In a case where a film having a thickness of 0.3 nm is formed of the coloring composition according to the embodiment of the present invention, the minimum value of a transmittance of the film in a wavelength region of 400 to 550 nm is preferably 20% or less, more preferably 10% or less, and still more preferably 5% or less. A coloring composition having such spectral characteristics is preferably used as a coloring composition for forming a green pixel, a red pixel, or a yellow pixel of a color filter, or a coloring composition for an infrared transmitting filter.

Hereinafter, the respective components used in the coloring composition according to the embodiment of the present invention will be described.

<<Coloring Material>>

The coloring composition according to the embodiment of the present invention contains a coloring material. As the coloring material contained in the coloring composition according to the embodiment of the present invention, a coloring material containing a pteridin pigment is preferable. The pteridin pigment is preferably a yellow coloring material. Examples of a preferred aspect of the pteridin pigment include Color Index (C. I.) Pigment Yellow 215, a compound represented by Formula (pt-1), and a salt of the compound represented by Formula (pt-1). From the reason that the temporal stability of the coloring composition can be further improved, the pteridin pigment is preferably Color Index (C. I.) Pigment Yellow 215 or a salt of the compound represented by Formula (pt-1). Hereinafter, the compound represented by Formula (pt-1) is also referred to as a compound (pt-1).

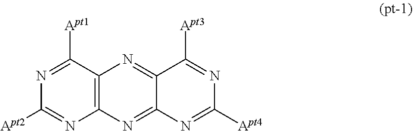

In Formula (pt-1), A^{pt1} to A^{pt4} each independently represent a hydrogen atom, a hydroxy group, a thiol group, an alkyl group, an alkoxy group, an aryl group, an aryloxy group, or —NR^{pt1}R^{pt2},

R^{pt1} and R^{pt2} each independently represent a hydrogen atom, an alkyl group, an aryl group, —CO—R^{pt3}, —COO—R^{pt3}, or —CONH—R^{pt3}, and

R^{pt3} represents an alkyl group or an aryl group.

The alkyl group represented by A^{pt1} to A^{pt4} and R^{pt1} to R^{pt3} preferably has 1 to 15 carbon atoms, more preferably has 1 to 10 carbon atoms, and still more preferably has 1 to 8 carbon atoms. The alkyl group may be linear, branched, or cyclic, and is preferably linear or branched. The alkyl group may have a substituent. Examples of the substituent include the substituent T described later.

The alkoxy group represented by A^{pt1} to A^{pt4} preferably has 1 to 15 carbon atoms, more preferably has 1 to 10 carbon atoms, and still more preferably has 1 to 8 carbon atoms. The alkoxy group may have a substituent. Examples of the substituent include the substituent T described later.

The aryl group represented by A^{pt1} to A^{pt4} and R^{pt1} to R^{pt3} preferably has 6 to 30 carbon atoms, more preferably has 6 to 20 carbon atoms, and still more preferably has 6 to 14 carbon atoms. The aryl group may have a substituent. Examples of the substituent include the substituent T described later.

The aryloxy group represented by A^{pt1} to A^{pt4} preferably has 6 to 30 carbon atoms, more preferably has 6 to 20 carbon atoms, and still more preferably has 6 to 14 carbon atoms. The aryloxy group may have a substituent. Examples of the substituent include the substituent T described later.

In Formula (pt-1), it is preferable that at least one of A^{pt1} to A^{pt4} is —NR^{pt1}R^{pt2}, it is more preferable that two to four of A^{pt1} to A^{pt4} are —NR^{pt1}R^{pt2}, it is still more preferable that three or four of A^{pt1} to A^{pt4} are —NR^{pt1}R^{pt2}, and it is particularly preferable that A^{pt1} to A^{pt4} are each independently —NR^{pt1}R^{pt2}. In addition, it is preferable that at least one of R^{pt1} or R^{pt2} is a hydrogen atom, and it is more preferable that both are hydrogen atoms. In a case where at least one of A^{pt1} to A^{pt4} is —NR^{pt1}R^{pt2}, it is presumed that the interaction between the pteridin pigment and the resin acts more strongly to form a strong network between the pteridin pigment and the resin, so that the temporal stability of the coloring composition can be further improved.

Examples of the salt of the compound (pt-1) include a sulfamate, a phosphate, and a paratoluene sulfonate, and from the reason that the temporal stability of the coloring composition can be further improved, a paratoluene sulfonate is preferable.

From the viewpoint of color value, a molecular weight of the compound (pt-1) is preferably 200 to 700 and more preferably 240 to 500.

(Substituent T)

Examples of the substituent T include a halogen atom, a nitro group, a cyano group, —OR^{t11}, —SR^{t11}, —NR^{t11}R^{t12}, —CONR^{t11}R^{t12}, —COOR^{t11}, —SO₂R^{t11}, —SO₂NR^{t11}R^{t12}, —SO₂OR^{t11}, —NR^{t11}COR^{t12}, and —NR^{t11}COOR^{t12}. R^{t11} and R^{t12} each independently represent a hydrogen atom, an alkyl group, an alkenyl group, or an aryl group. R^{t11} and R^{t12} may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear.

The alkenyl group preferably has 2 to 30 carbon atoms, more preferably has 2 to 15 carbon atoms, still more preferably has 2 to 8 carbon atoms, and particularly preferably has 2 to 5 carbon atoms.

The aryl group preferably has 6 to 30 carbon atoms, more preferably has 6 to 20 carbon atoms, and still more preferably has 6 to 14 carbon atoms.

These groups may further have a substituent. Examples of the further substituent include the groups described above as the substituent T.

Specific examples of the compound (pt-1) or the salt thereof include compounds (1) to (4) having the following structures. The compound (1) and the compound (2) are salt compounds.

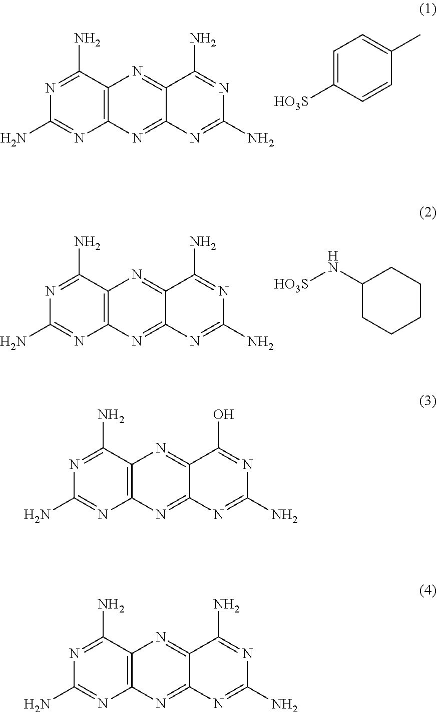 [SMILES: Nc1nc(N)c2nc3c(N)nc(N)nc3nc2n1 ; Cc1ccc(S(=O)(=O)O)cc1 ; Nc1nc(N)c2nc3c(N)nc(N)nc3nc2n1 ; O=S(=O)(O)NC1CCCCC1 ; Nc1nc(N)c2nc3c(O)nc(N)nc3nc2n1 ; Nc1nc(N)c2nc3c(N)nc(N)nc3nc2n1]

It is preferable that the coloring material used in the coloring composition according to the embodiment of the present invention further contains a yellow coloring material other than the pteridin pigment. By further containing a yellow coloring material other than the pteridin pigment, an optical filter having more excellent spectral characteristics is obtained.

As the yellow coloring material other than the pteridin pigment (hereinafter, also referred to as other yellow coloring materials), an azo compound, a quinophthalone compound, or an isoindoline compound is preferable, and an isoindoline compound or a quinophthalone compound is more preferable. Since the isoindoline compound or the quinophthalone compound has a structure similar to that of the pteridin pigment, it is presumed that the pteridin pigment and the isoindoline compound or the quinophthalone compound easily interact with each other in the coloring composition, and the dispersibility of the coloring material in the coloring composition can be further improved. Therefore, in a case of using at least one selected from the quinophthalone compound or the isoindoline compound as the other yellow coloring materials, it is presumed that the temporal stability of the coloring composition can be further improved.

Preferred specific examples of the other yellow coloring materials include C. I. Pigment Yellow 129, 138, 139, 150, 185, and compounds represented by Formulae (QP1) to (QP3).

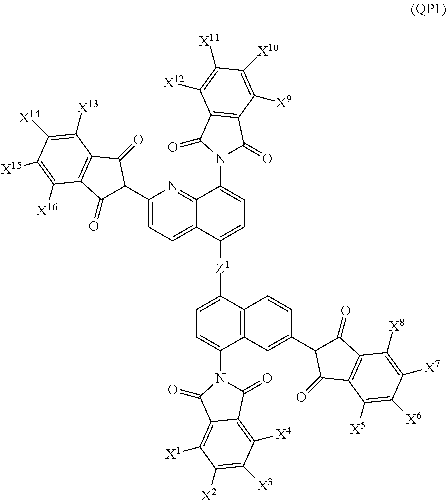

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

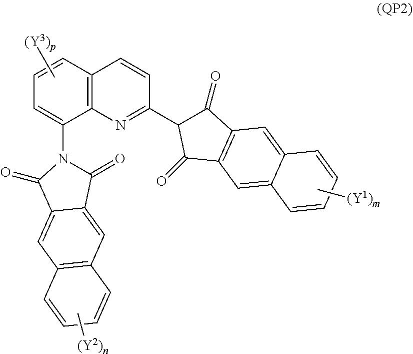

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

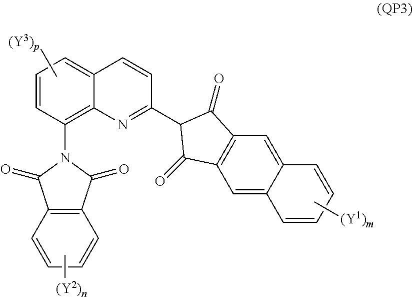

In Formula (QP3), Y¹ to Y³ each independently represent a halogen atom. n represents an integer of 0 to 4, m represents an integer of 0 to 6, and p represents an integer of 0 to 5. (n+m) is 1 or more.

In addition, as the other yellow coloring materials, yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 137, 147, 148, 151, 152, 153, 154, 155, 156, 161, 162, 164, 166, 167, 168, 169, 170, 171, 172, 173, 174, 175, 176, 177, 179, 180, 181, 182, 187, 188, 193, 194, 199, 213, 214, 228, 231, 232 (methine-based), 233 (quinoline-based), 234 (aminoketone-based), 235 (aminoketone-based), and 236 (aminoketone-based); yellow dyes such as C. I. Solvent Yellow 13, 19, 21, 25, 25:1, 62, 69, 79, 81, 82, 83, 83:1, 88, 89, 90, 151, and 161 can also be used.

In addition, as the other yellow coloring materials, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, methine dyes described in JP2019-073695A, methine dyes described in JP2019-073696A, methine dyes described in JP2019-073697A, methine dyes described in JP2019-073698A, azo dyes described in JP2020-093994A, perylene pigments described in JP2020-083982A, perylene pigments described in WO2020/105346A, quinophthalone compounds described in JP2020-517791B, and the like can also be used.

In a case where the pteridin pigment is used in combination with other yellow coloring materials, a content of the other yellow coloring materials is preferably 10 to 300 parts by mass, more preferably 20 to 200 parts by mass, and still more preferably 30 to 100 parts by mass with respect to 100 parts by mass of the pteridin pigment. In a case where the content of the other yellow coloring materials is within the above-described range, the temporal stability of the coloring composition is good. Further, it is easy to obtain more excellent spectral characteristics.

The coloring material contained in the coloring composition according to the embodiment of the present invention can further contain a coloring material having a hue other than the yellow coloring material. Examples of the coloring material having other hues to be used in combination include chromatic coloring materials such as a green coloring material, a red coloring material, a violet coloring material, a blue coloring material, and an orange coloring material, and black coloring materials. The coloring material having other hues is preferably at least one selected from a green coloring material, a red coloring material, or an orange coloring material, and more preferably at least one selected from a green coloring material or a red coloring material. The other coloring materials may be pigments or dyes.

Examples of the red coloring material include a diketopyrrolopyrrole compound, an anthraquinone compound, an azo compound, a naphthol compound, an azomethine compound, a xanthene compound, a quinacridone compound, a perylene compound, and a thioindigo compound, and from the viewpoint of temporal stability of the coloring composition, a diketopyrrolopyrrole compound, an anthraquinone compound, or an azo compound is preferable.

Specific examples of the red coloring material include red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. In addition, as the red coloring material, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, brominated diketopyrrolopyrrole compounds described in JP2020-085947A, naphtholazo compounds described in JP2012-229344A, red coloring materials described in JP6516119B, red coloring materials described in JP6525101B, brominated diketopyrrolopyrrole compounds described in paragraph No. 0229 of JP2020-090632A, anthraquinone compounds described in KR10-2019-0140741A, anthraquinone compounds described in KR10-2019-0140744A, perylene compounds described in JP2020-079396A, diketopyrrolopyrrole compounds described in paragraph Nos. 0025 to 0041 of JP2020-66702A, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

As the red coloring material, C. I. Pigment Red 122, 177, 254, 255, 264, 269, 272, and the like are particularly preferably used.

Examples of the green coloring material include a phthalocyanine compound and a squarylium compound, and from the viewpoint of temporal stability of the coloring composition, a phthalocyanine compound is preferable. Specific examples of the green coloring material include green pigments such as C. I. Pigment Green 7, 10, 36, 37, 58, 59, 62, 63, 64, 65, and 66. In addition, as the green coloring material, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green coloring material, compounds described in CN2010-6909027A, phthalocyanine compounds described in WO2012/102395A, which have phosphoric acid ester as a ligand, phthalocyanine compounds described in JP2019-008014A, phthalocyanine compounds described in JP2018-180023A, aluminum phthalocyanine compounds described in JP2020-070426A, compounds described in JP2019-038958A, squarylium compounds described in paragraph Nos. 0141 to 0151 of WO2019/167589A, and the like can be used. In addition, as the green coloring material, a core-shell type coloring agent described in JP2020-076995A can also be used.

As the green coloring material, C. I. Pigment Green 7, 36, 58, 62, 63, and the like are particularly preferably used.

Specific examples of the orange coloring material include orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

Specific examples of the violet coloring material include violet pigments such as C. I. Pigment Violet 1, 19, 23, 27, 32, 37, 42, 60, and 61.

Specific examples of the blue coloring material include blue pigments such as C. I. Pigment Blue 1, 2, 15, 15:1, 15:2, 15:3, 15:4, 15:6, 16, 22, 29, 60, 64, 66, 79, 80, 87, and 88.

Examples of the black coloring material include a bisbenzofuranone compound, an azomethine compound, a perylene compound, and an azo compound. Among these, a bisbenzofuranone compound or a perylene compound is preferable. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include compounds described in paragraph Nos. 0016 to 0020 of JP2017-226821A, and C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

In addition, as the coloring material, from the viewpoint of enhancing spectral characteristics, it is also preferable to use a halogenated zinc phthalocyanine pigment having a Raman spectrum, which is described in JP6744002B. In addition, as the coloring material, from the viewpoint of adjusting viscosity, it is also preferable to use a dioxazine pigment with controlled contact angle, which is described in WO2019/107166A.

In a case where the coloring composition according to the embodiment of the present invention contains a green coloring material in addition to the pteridin pigment, the coloring composition according to the embodiment of the present invention is preferably used as a coloring composition for forming a green pixel of a color filter. In addition, in a case where the coloring composition according to the embodiment of the present invention contains a red coloring material in addition to the pteridin pigment, the coloring composition according to the embodiment of the present invention is preferably used as a coloring composition for forming a red pixel of a color filter.

In addition, the coloring material contained in the coloring composition may contain two or more kinds of chromatic coloring materials, a combination of the two or more kinds of chromatic coloring materials may form black. Such a coloring composition is preferably used as a coloring composition for forming an infrared transmitting filter. In a case where the combination of two or more kinds of chromatic coloring materials forms black, examples of the combination of the chromatic coloring materials include the following.

(1) aspect in which a red coloring material, a blue coloring material, and a yellow coloring material are contained.

(2) aspect in which a red coloring material, a blue coloring material, a yellow coloring material, and a violet coloring material are contained.

(3) aspect in which a red coloring material, a blue coloring material, a yellow coloring material, a violet coloring material, and a green coloring material are contained.

(4) aspect in which a red coloring material, a blue coloring material, a yellow coloring material, and a green coloring material are contained.

(5) aspect in which a yellow coloring material and a violet coloring material are contained.

The coloring material contained in the coloring composition according to the embodiment of the present invention may further contain an infrared absorbing coloring material. For example, in a case of forming an infrared transmitting filter using the coloring composition according to the embodiment of the present invention, by containing an infrared absorbing coloring material in the coloring composition, a wavelength of light transmitted through a film to be obtained can be shifted to a longer wavelength side. The infrared absorbing coloring material is preferably a compound having a maximal absorption wavelength on a wavelength side longer than a wavelength of 700 nm. The infrared absorbing coloring material is preferably a compound having a maximal absorption wavelength in a wavelength range of more than 700 nm and 1800 nm or less. In addition, in the infrared absorbing coloring material, a ratio A¹/A², which is a ratio of an absorbance A¹ at a wavelength of 500 nm to an absorbance A² at the maximal absorption wavelength, is preferably 0.08 or less and more preferably 0.04 or less.

Examples of the infrared absorbing coloring material include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B. Examples of the metal oxide include indium tin oxide, antimony tin oxide, zinc oxide, Al-doped zinc oxide, fluorine-doped tin dioxide, niobium-doped titanium dioxide, and tungsten oxide. For the details of the tungsten oxide, reference can be made to paragraph No. 0080 of JP2016-006476A, the contents of which are incorporated herein by reference. Examples of the metal boride include lanthanum boride. Examples of a commercially available product of the lanthanum boride include LaB₆—F (manufactured by Japan New Metals Co., Ltd.). In addition, compounds described in WO2017/119394A can also be used as the metal boride. Examples of a commercially available product of the indium tin oxide include F-ITO (manufactured by DOWA Hi-Tech Co., Ltd.).

In addition, as the infrared absorbing coloring material, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, and the like can also be used.

A content of the coloring material in the total solid content of the coloring composition is 40% by mass or more, preferably 50% by mass or more. The upper limit is preferably 80% by mass or less, more preferably 75% by mass or less, and still more preferably 70% by mass or less.

From the viewpoint of storage stability of the coloring composition, the content of the pteridin pigment in the total solid content of the coloring composition is preferably 1% by mass or more. The upper limit is preferably 80% by mass or less, more preferably 75% by mass or less, and still more preferably 70% by mass or less. The lower limit is preferably 2% by mass or more, more preferably 5% by mass or more, and still more preferably 10% by mass or more.

From the viewpoint of storage stability of the coloring composition, the content of the pteridin pigment in the coloring material is preferably 2% by mass or more, more preferably 5% by mass or more, and still more preferably 10% by mass or more. The upper limit may be 100 mass %, 95 mass % or less, or 90 mass % or less.

In a case where the coloring composition according to the embodiment of the present invention is used as a coloring composition for forming a yellow pixel of a color filter, the content of the pteridin pigment in the coloring material is preferably 30% to 100% by mass. From the viewpoint of storage stability of the coloring composition, the lower limit is preferably 40% by mass or more and more preferably 50% by mass or more. From the viewpoint of spectral characteristics, the upper limit may be 90% by mass or less or 80% by mass or less.

In addition, in a case where the coloring composition according to the embodiment of the present invention is used as a coloring composition for forming a yellow pixel of a color filter, from the viewpoint of storage stability of the coloring composition, the content of the pteridin pigment in the total solid content of the coloring composition is preferably 5% by mass or more, more preferably 10% by mass or more, and still more preferably 20% by mass or more. The upper limit may be 70% by mass or less or 60% by mass or less.

In a case where the coloring composition according to the embodiment of the present invention is used as a coloring composition for forming a green pixel of a color filter, the content of the pteridin pigment in the coloring material is preferably 2% to 90% by mass. From the viewpoint of storage stability of the coloring composition, the lower limit is preferably 5% by mass or more and more preferably 10% by mass or more. The upper limit may be 70% by mass or less or 50% by mass or less.

In addition, in a case where the coloring composition according to the embodiment of the present invention is used as a coloring composition for forming an infrared absorbing coloring material, from the viewpoint of storage stability of the coloring composition, the content of the infrared absorbing coloring material in the coloring material is preferably 70% by mass or less, more preferably 50% by mass or less, and still more preferably 30% by mass or less.

In addition, in a case where the coloring composition according to the embodiment of the present invention is used as a coloring composition for forming a green pixel of a color filter, from the viewpoint of storage stability of the coloring composition and spectral characteristics of the film, the content of the pteridin pigment in the total solid content of the coloring composition is preferably 2% by mass or more, more preferably 3% by mass or more, and still more preferably 5% by mass or more. The upper limit is preferably 60% by mass or less, more preferably 50% by mass or less, and still more preferably 40% by mass or less.

In addition, in a case where the coloring composition according to the embodiment of the present invention is used as a coloring composition for forming a green pixel of a color filter, with respect to 100 parts by mass of the pteridin pigment, the green coloring material is contained in an amount of preferably 10 to 90 parts by mass, more preferably 30 to 80 parts by mass, and still more preferably 40 to 70 parts by mass.

In a case where the coloring composition according to the embodiment of the present invention is used as a coloring composition for forming a red pixel of a color filter, the content of the pteridin pigment in the coloring material is preferably 2% to 90% by mass. From the viewpoint of storage stability of the coloring composition, the lower limit is preferably 5% by mass or more and more preferably 10% by mass or more. The upper limit may be 70% by mass or less or 50% by mass or less.

In addition, in a case where the coloring composition according to the embodiment of the present invention is used as a coloring composition for forming a red pixel of a color filter, from the viewpoint of storage stability of the coloring composition and spectral characteristics of the film, the content of the pteridin pigment in the total solid content of the coloring composition is preferably 2% by mass or more, more preferably 3% by mass or more, and still more preferably 5% by mass or more. The upper limit is preferably 50% by mass or less, more preferably 30% by mass or less, and still more preferably 20% by mass or less.

In addition, in a case where the coloring composition according to the embodiment of the present invention is used as a coloring composition for forming a red pixel of a color filter, with respect to 100 parts by mass of the pteridin pigment, the red coloring material is contained in an amount of preferably 10 to 90 parts by mass, more preferably 30 to 80 parts by mass, and still more preferably 40 to 70 parts by mass.

In a case where the coloring composition according to the embodiment of the present invention is used as a coloring composition for forming an infrared transmitting filter, from the viewpoint of storage stability of the coloring composition and spectral characteristics of the film, the content of the pteridin pigment in the coloring material is preferably 5% to 80% by mass, more preferably 10% to 70% by mass, and still more preferably 15% to 50% by mass.

<<Resin>>

The coloring composition according to the embodiment of the present invention contains a resin. The resin is blended in, for example, an application for dispersing a pigment or the like in the coloring composition or an application as a binder. Mainly, a resin which is used for dispersing a pigment or the like in the coloring composition is also referred to as a dispersant. However, such applications of the resin are merely exemplary, and the resin can also be used for other purposes in addition to such applications.

A weight-average molecular weight (Mw) of the resin is preferably 2000 to 2000000. The upper limit is preferably 1000000 or less and more preferably 500000 or less. The lower limit is preferably 3000 or more and more preferably 5000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof. In addition, resins described in paragraph Nos. 0041 to 0060 of JP2017-206689A, resins described in paragraph Nos. 0022 to 0071 of JP2018-010856A, and block polyisocyanate resins described in JP2016-222891A can also be used.

The coloring composition according to the embodiment of the present invention preferably contains a resin having an acid group. Examples of the acid group include a carboxyl group, a phosphoric acid group, a sulfo group, and a phenolic hydroxy group. Among these acid groups, one kind may be used singly, or two or more kinds may be used in combination. The resin having an acid group can also be used as a dispersant. In a case where the coloring composition according to the embodiment of the present invention contains a resin having an acid group, a desired pattern can be formed by an alkali development. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

The coloring composition according to the embodiment of the present invention preferably contains a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the basic group included in the resin having a basic group include a group represented by Formula (a-1) and a group represented by Formula (a-2).

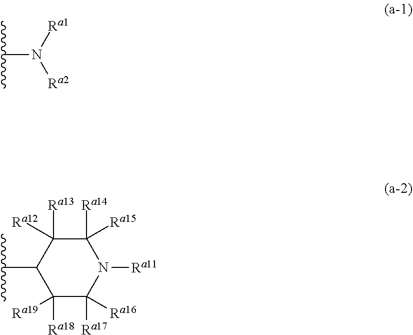

In Formula (a-1), R^{a1} and R^{a2} each independently represent a hydrogen atom, an alkyl group, or an aryl group, a wavy line represents a bonding site, and R^{a1} and R^{a2} may be bonded to each other to form a ring;

in Formula (a-2), R^{a11} represents a hydrogen atom, a hydroxy group, an alkyl group, an alkoxy group, an aryl group, an aryloxy group, an acyl group, or an oxyradical, R^{a12} to R^{a19} each independently represent a hydrogen atom, an alkyl group, or an aryl group, and a wavy line represents a bonding site.

The alkyl group represented by R^{a1}, R^{a2}, R^{a11} to R^{a19} preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear. The alkyl group may have a substituent. Examples of the substituent include the above-described substituent T.

The aryl group represented by R^{a1}, R^{a2}, R^{a11} to R^{a19} preferably has 6 to 30 carbon atoms, more preferably has 6 to 20 carbon atoms, and still more preferably has 6 to 12 carbon atoms. The aryl group may have a substituent. Examples of the substituent include the above-described substituent T.

The alkoxy group represented by R^{a11} preferably has 1 to 30 carbon atoms, more preferably has 1 to 15 carbon atoms, still more preferably has 1 to 8 carbon atoms, and particularly preferably has 1 to 5 carbon atoms. The alkoxy group may have a substituent. Examples of the substituent include the above-described substituent T.

The aryloxy group represented by R^{a11} preferably has 6 to 30 carbon atoms, more preferably has 6 to 20 carbon atoms, and still more preferably has 6 to 12 carbon atoms. The aryloxy group may have a substituent. Examples of the substituent include the above-described substituent T.

The acyl group represented by R^{a11} preferably has 2 to 30 carbon atoms, more preferably has 2 to 20 carbon atoms, and still more preferably has 2 to 12 carbon atoms. The acyl group may have a substituent. Examples of the substituent include the above-described substituent T.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK Chemie), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF). In addition, as the resin having a basic group, a block copolymer (B) described in paragraph Nos. 0063 to 0112 of JP2014-219665A or a block copolymer A1 described in paragraph Nos. 0046 to 0076 of JP2018-156021A, the contents of which are incorporated herein by reference.

It is also preferable that the coloring composition according to the embodiment of the present invention contains the resin having an acid group and the resin having a basic group, respectively. According to this aspect, the storage stability of the coloring composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

The resin also preferably includes a resin including a repeating unit derived from a compound represented by Formula (ED1) and/or a compound represented by Formula (ED2) (hereinafter, these compounds will also be referred to as an “ether dimer”).

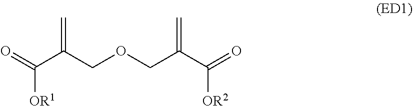

In Formula (ED1), R¹ and R² each independently represent a hydrogen atom or a hydrocarbon group having 1 to 25 carbon atoms, which may have a substituent.

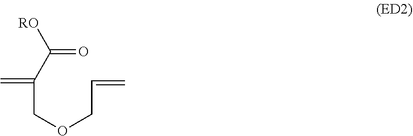

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The resin also preferably includes a resin including a repeating unit having a polymerizable group.

The resin also preferably includes a resin including a repeating unit derived from a compound represented by Formula (X).

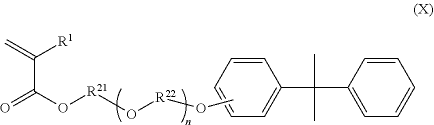

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to include a resin (hereinafter, also referred to as a resin Ac) having an aromatic carboxyl group. The resin Ac may include the aromatic carboxyl group in the main chain of the repeating unit, or in the side chain of the repeating unit. It is preferable that the aromatic carboxyl group is included in the main chain of the repeating unit. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) and a repeating unit represented by Formula (Ac-2).

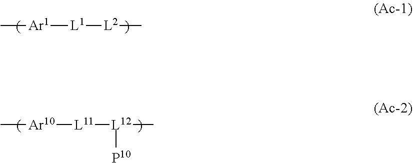

In Formula (Ac-1), Ar¹ represents a group including an aromatic carboxyl group, L¹ represents —COO— or —CONH—, and L² represents a divalent linking group.

In Formula (Ac-2), Ar¹⁰ represents a group including an aromatic carboxyl group, L¹¹ represents —COO— or —CONH—, L¹² represents a trivalent linking group, and P¹⁰ represents a polymer chain.

In Formula (Ac-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

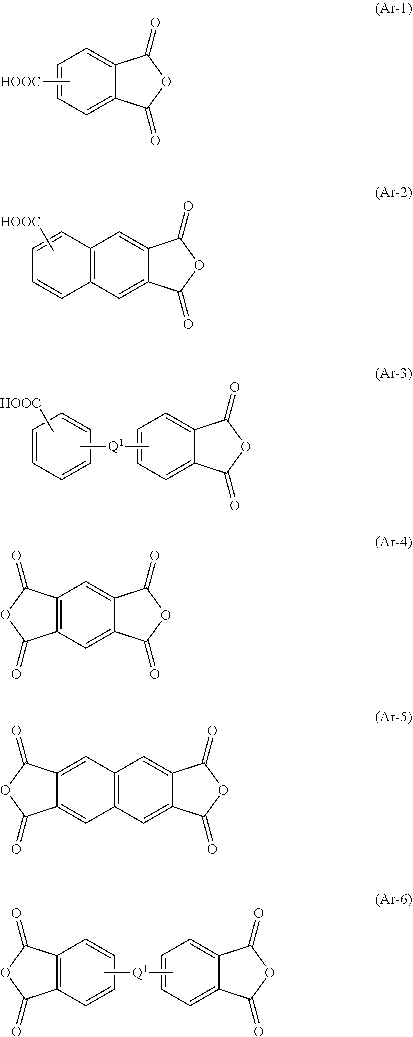

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

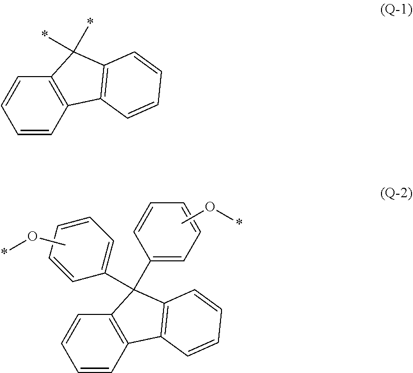

Specific examples of the group including an aromatic carboxyl group represented by Ar¹ include a group represented by Formula (Ar-11), a group represented by Formula (Ar-12), and a group represented by Formula (Ar-13).

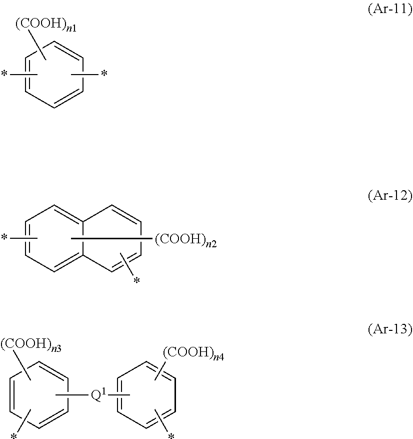

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by —O-L^{2a}-O—. Examples of L^{2a} include an alkylene group; an arylene group; a group formed by a combination of an alkylene group and an arylene group; and a group formed by a combination of at least one selected from an alkylene group or an arylene group, and at least one selected from —O—, —CO—, —COO—, —OCO—, —NH—, or —S—. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxyl group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxyl group is a resin having the repeating unit represented by Formula (Ac-2), this resin is preferably used as a dispersant.

In the coloring composition according to the embodiment of the present invention, it is also preferable to use a resin having a repeating unit represented by Formula (a1-1) (hereinafter, also referred to as a resin A). This resin is preferably used as a dispersant.

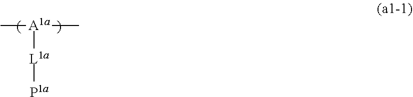

In Formula (a1-1), A^{1a} represents a molecular chain which has a structure derived from a compound having an ethylenically unsaturated bond-containing group, L^{1a} represents a single bond or a divalent linking group, and P^{1a} represents a graft chain which includes a repeating unit p1 having an oxetane group.

In Formula (a1-1), examples of the molecular chain which has a structure derived from a compound having an ethylenically unsaturated bond-containing group, represented by A^{1a}, include molecular chains which have a structure formed by polymerization of a compound having an ethylenically unsaturated bond-containing group such as (meth)acrylic acid esters, crotonic esters, vinyl esters, maleic acid diesters, fumaric acid diesters, itaconic acid diesters, (meth)acrylamides, styrenes, vinyl ethers, vinyl ketones, olefins, maleimides, and (meth)acrylonitriles. Specific examples of A^{1a} include structures represented by Formulae (A-1) to (A-5), and a structure represented by Formula (A-1) is preferable. In the formulae, * represents a bonding site with L^{1a} in Formula (a1-1), and R^{a1} to R^{a3} each independently represent a hydrogen atom, an alkyl group, or an aryl group. The alkyl group preferably has 1 to 10 carbon atoms, more preferably has 1 to 5 carbon atoms, and still more preferably has 1 to 3 carbon atoms. The alkyl group may be linear, branched, or cyclic forms, and is preferably linear or branched and more preferably linear. The aryl group preferably has 6 to 20 carbon atoms, more preferably has 6 to 12 carbon atoms, and still more preferably has 6 to 10 carbon atoms. R^{a1} is preferably a hydrogen atom or an alkyl group. R^{a2} and R^{a3} are preferably hydrogen atoms.

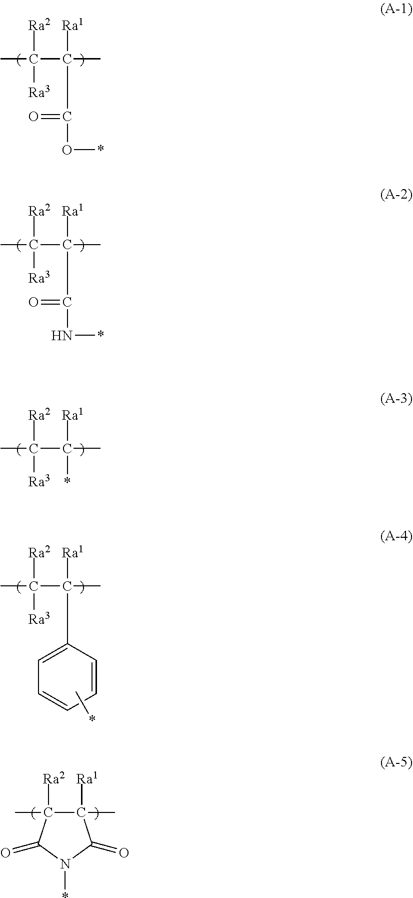

In Formula (a1-1), examples of the divalent linking group represented by L^{1a} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups. The alkylene group and the arylene group may have a substituent. Examples of the substituent include a hydroxy group and a halogen atom. The divalent linking group represented by L^{1a} is preferably a group represented by Formula (L-1).

*2-L^{3a}-X¹-L^{4a}-S—*1 (L-1)

In Formula (L-1), L^{3a} and L^{4a} each independently represent a divalent linking group, X¹ represents a single bond, —O—, —COO—, —OCO—, —NHCOO—, —OCONH—, or —NHCONH—, *1 represents a bonding site with P^{1a}, and *2 represents a bonding site with A^{1a}.

Examples of the divalent linking group represented by L^{3a} and L^{4a} in Formula (L-1) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups. The alkylene group and the arylene group may have a substituent. In a case where X¹ is —O—, —COO—, —OCO—, —NHCOO—, —OCONH—, or —NHCONH—, L^{3a} and L^{4a} are each independently preferably an alkylene group or an arylene group, and more preferably an alkylene group.

X¹ is preferably —O—, —COO—, —OCO—, —NHCOO—, —OCONH—, or —NHCONH—, and more preferably —NHCOO— or —OCONH—.

In Formula (a1-1), the graft chain represented by P^{1a} includes the above-described repeating unit p1. As the repeating unit p1, a repeating unit derived from a compound having an ethylenically unsaturated bond-containing group is preferable. Specific examples of the repeating unit p1 include a repeating unit represented by Formulae (p1-1) to (p1-4), and a repeating unit represented by Formula (p1-1) is preferable.

[symbol]

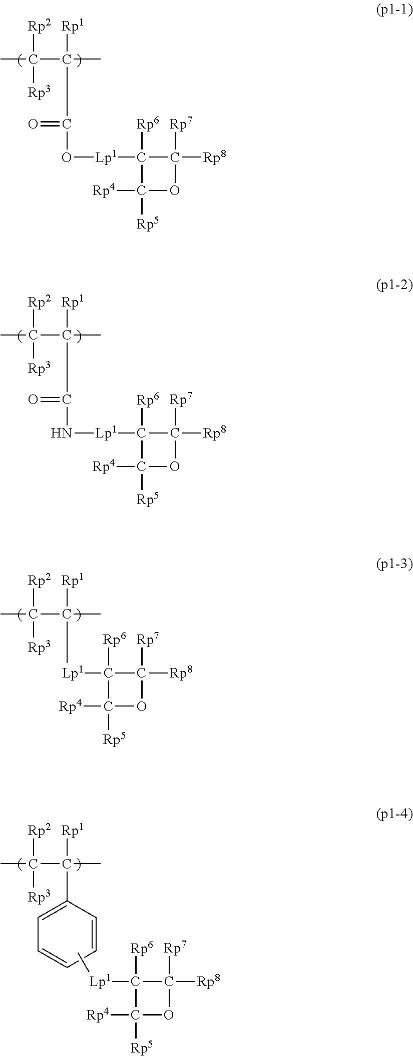

In the formulae, Rp¹ to Rp³ each independently represent a hydrogen atom, an alkyl group, or an aryl group, Lp¹ represents a divalent linking group, and Rp⁴ to Rp⁸ each independently represent a hydrogen atom or an alkyl group.

The alkyl group represented by Rp¹ to Rp³ preferably has 1 to 10 carbon atoms, more preferably has 1 to 5 carbon atoms, and still more preferably has 1 to 3 carbon atoms. The alkyl group may be linear, branched, or cyclic forms, and is preferably linear or branched and more preferably linear. The aryl group represented by Rp¹ to Rp³ preferably has 6 to 20 carbon atoms, more preferably has 6 to 12 carbon atoms, and still more preferably has 6 to 10 carbon atoms. Rp¹ is preferably a hydrogen atom or an alkyl group. Rp² and Rp³ are preferably hydrogen atoms.

The alkyl group represented by Rp⁴ to Rp⁸ preferably has 1 to 10 carbon atoms and more preferably has 1 to 5 carbon atoms. The alkyl group may be linear, branched, or cyclic forms, and is preferably linear or branched and more preferably linear. In the formulae, it is preferable that Rp⁴, Rp⁵, Rp⁷, and Rp⁸ are hydrogen atoms and Rp⁶ is an alkyl group.

Examples of the divalent linking group represented by Lp¹ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group including a combination of two or more thereof, and an alkylene group is preferable. The alkylene group and the arylene group may have a substituent. Examples of the substituent include a hydroxy group and a halogen atom.

It is also preferable that the graft chain represented by P^{1a} further includes a repeating unit p2 having a group in which a carboxy group is protected by a heat-decomposable group (hereinafter, also referred to as a protected carboxy group). According to this aspect, by heating during film formation, the heat-decomposable group is eliminated from the above-described protected carboxy group to generate a carboxy group, and the generated carboxy group can promote a crosslinking reaction of the oxetane group in the graft chain. In addition, since the carboxy group is generated in the vicinity of the oxetane group in the graft chain, the crosslinking reaction of the oxetane group can be promoted more effectively. Therefore, it is possible to form a film having more excellent heat resistance, in which film contraction after heating is further suppressed. In addition, since the carboxy group is protected by the heat-decomposable group in a state before heating, the reaction and the like of the oxetane group during storage of the coloring composition can be suppressed, and the storage stability of the coloring composition is also excellent.

Here, the group (protected carboxy group) in which the carboxy group is protected by a heat-decomposable group refers to a group in which the heat-decomposable group is eliminated by heating to generate a carboxy group. The group in which the carboxy group is protected by a heat-decomposable group is preferably a group in which a carboxy group is generated by heating to a temperature of 120° C. to 290° C., more preferably 200° C. to 260° C.

Examples of the above-described protected carboxy group include a group having a structure in which a carboxy group is protected by a tertiary alkyl group, a group having a structure in which a carboxy group is protected by an acetal group or a ketal group, and a group having a structure in which a carboxy group is protected by a carbonate ester group, and from the viewpoint of dispersion stability of the coloring material and ease of generation of carboxy group by heating, a group having a structure in which a carboxy group is protected by a tertiary alkyl group is preferable. Specific examples of the protected carboxy group include a group represented by Formulae (b1-1) to (b1-3), and from the viewpoint of dispersion stability of the coloring material and ease of generation of carboxy group by heating, a group represented by Formula (b1-1) is preferable.

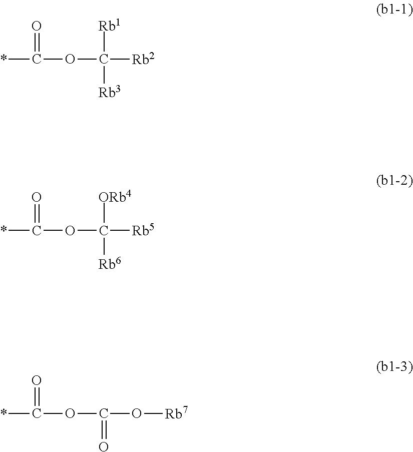

In Formula (b1-1), Rb¹ to Rb³ each independently represent an alkyl group or an aryl group, and Rb¹ and Rb² may be bonded to each other to form a ring.

In Formula (b1-2), Rb⁴ represents an alkyl group or an aryl group, Rb⁵ and Rb⁶ each independently represent a hydrogen atom, an alkyl group, or an aryl group, at least one of Rb⁵ or Rb⁶ is an alkyl group or an aryl group, and Rb⁴ and Rb⁵ may be bonded to each other to form a ring.

In Formula (b1-3), Rb⁷ represents an alkyl group or an aryl group.

* in Formulae (b1-1) to (b1-3) represents a bonding site.

The alkyl group represented by Rb¹ to Rb³ preferably has 1 to 10 carbon atoms, more preferably has 1 to 5 carbon atoms, and still more preferably has 1 to 3 carbon atoms. The alkyl group may be linear, branched, or cyclic, and is preferably linear or branched.

The aryl group represented by Rb¹ to Rb³ preferably has 6 to 20 carbon atoms, more preferably has 6 to 12 carbon atoms, and still more preferably has 6 to 10 carbon atoms.

Rb¹ to Rb³ are each independently preferably an alkyl group, more preferably a linear alkyl group, still more preferably a linear alkyl group having 1 to 5 carbon atoms, even more preferably a linear alkyl group having 1 to 3 carbon atoms, and particularly preferably a methyl group.

In Formula (b1-1), Rb¹ and Rb² may be bonded to each other to form a ring. The ring formed is preferably a 5-membered ring or a 6-membered ring.

The alkyl group represented by Rb⁴ to Rb⁶ preferably has 1 to 20 carbon atoms, more preferably has 1 to 10 carbon atoms, and still more preferably has 1 to 10 carbon atoms. The alkyl group may be linear, branched, or cyclic, and is preferably linear or branched.

The aryl group represented by Rb⁴ to Rb⁶ preferably has 6 to 20 carbon atoms, more preferably has 6 to 12 carbon atoms, and still more preferably has 6 to 10 carbon atoms.

In Formula (b1-2), Rb⁴ and Rb⁵ may be bonded to each other to form a ring. The ring formed is preferably a 5-membered ring or a 6-membered ring.

The alkyl group represented by Rb⁷ preferably has 1 to 20 carbon atoms, more preferably has 1 to 10 carbon atoms, and still more preferably has 1 to 10 carbon atoms. The alkyl group may be linear, branched, or cyclic, and is preferably linear or branched.

The aryl group represented by Rb¹ preferably has 6 to 20 carbon atoms, more preferably has 6 to 12 carbon atoms, and still more preferably has 6 to 10 carbon atoms.

Rb¹ to Rb³ in Formula (b1-1) are each independently preferably an alkyl group, more preferably a linear alkyl group, and still more preferably a methyl group.

Specific examples of the protected carboxy group include groups shown below, and a group represented by Formula (bb-1), that is, a t-butyl ester group is preferable. The t-butyl ester group has an optimum decomposition temperature, and it is easy to generate a carboxy group by a heating treatment during film formation. As a result, the crosslinking reaction of the oxetane group can be promoted more effectively, and a film having more excellent heat resistance can be formed. In addition, since a volume of an eliminated substance of the t-butyl ester group is small, it is possible to suppress generation voids in the film. In the formulae, * represents a bonding site.

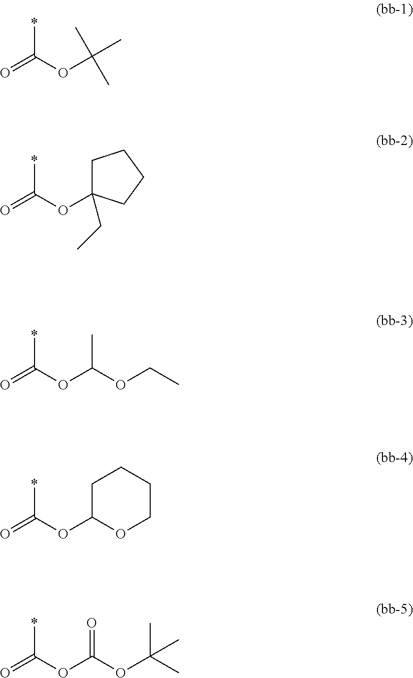

Examples of the repeating unit p2 include a repeating unit represented by Formulae (p2-1) to (p2-4).

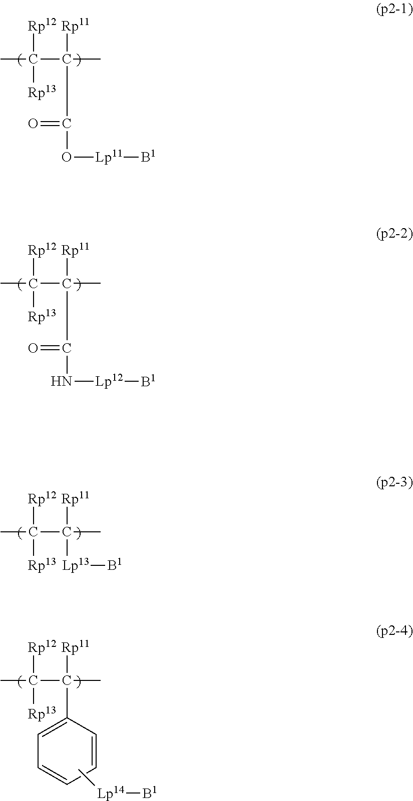

In the formulae, Rp¹¹ to Rp¹³ each independently represent a hydrogen atom, an alkyl group, or an aryl group, Lp¹¹ to Lp¹⁴ each independently represent a single bond or a divalent linking group, and B¹ represents the group represented Formula (b1-1), the group represented Formula (b1-2), or the group represented Formula (b1-3).

The alkyl group represented by Rp¹¹ to Rp¹³ preferably has 1 to 10 carbon atoms, more preferably has 1 to 5 carbon atoms, and still more preferably has 1 to 3 carbon atoms. The alkyl group may be linear, branched, or cyclic forms, and is preferably linear or branched and more preferably linear. The aryl group represented by Rp¹¹ to Rp¹³ preferably has 6 to 20 carbon atoms, more preferably has 6 to 12 carbon atoms, and still more preferably has 6 to 10 carbon atoms. Rp¹¹ is preferably a hydrogen atom or an alkyl group. Rp¹² and Rp¹³ are preferably hydrogen atoms.

Examples of the divalent linking group represented by Lp¹¹ to Lp¹⁴ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group including a combination of two or more thereof, and an alkylene group is preferable. The alkylene group and the arylene group may have a substituent. Examples of the substituent include a hydroxy group and a halogen atom.

B¹ represents the group represented Formula (b1-1), the group represented Formula (b1-2), or the group represented Formula (b1-3), and the group represented by Formula (b1-1) is preferable.

The repeating unit p2 is preferably a repeating unit represented by Formula (p2-10).

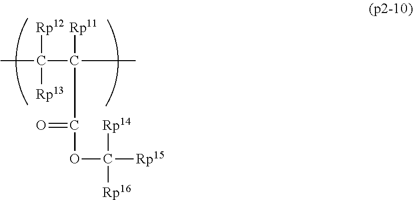

In the formula, Rp¹¹ to Rp¹³ each independently represent a hydrogen atom, an alkyl group, or an aryl group,

Rp¹⁴ to Rp¹⁶ represent an alkyl group or an aryl group, and Rp¹⁴ and Rp¹⁵ may be bonded to each other to form a ring.

The graft chain represented by P^{1a} may include a repeating unit other than the above-described repeating unit p1 and the above-described repeating unit p2. Examples of the other repeating units include a repeating unit having an ethylenically unsaturated bond-containing group, a repeating unit having an epoxy group, a repeating unit having a primary or secondary alkyl group, and a repeating unit having an aryl group. Examples of the ethylenically unsaturated bond-containing group include a (meth)acryloyl group, a (meth)acryloyloxy group, a (meth)acrylamide group, a vinylphenyl group, and an allyl group.

The content of the above-described p1 in the graft chain is preferably 30 mol % or more, more preferably 50 mol % or more, and still more preferably 70 mol % or more with respect to the total molar amount of repeating units included in the graft chain. The upper limit is not particularly limited and may be 100 mol % or less. In addition, the content of the above-described repeating unit p1 in the resin A is preferably 20 mol % or more, more preferably 30 mol % or more, still more preferably 40 mol % or more, even more preferably 50 mol % or more, even still more preferably 60 mol % or more, and particularly preferably 70 mol % or more with respect to the total molar amount of repeating units included in the resin A. The upper limit is not particularly limited, and may be 100 mol % or less, 90 mol % or less, or 95 mol % or less.

In a case where the graft chain includes the above-described repeating unit p2, the content of the above-described repeating unit p2 in the graft chain is preferably 5 to 70 mol % with respect to the total molar amount of repeating units included in the graft chain. The lower limit is preferably 10 mol % or more and more preferably 20 mol % or more. The upper limit is preferably 50 mol % or less and more preferably 40 mol % or less. A proportion of the above-described repeating unit p1 and the above-described repeating unit p2 is preferably 0.1 to 5 mol of the above-described repeating unit p2 with respect to 1 mol of the above-described repeating unit p1, more preferably 0.2 to 3 mol, and still more preferably 0.3 to 1 mol. In addition, the total content of the above-described p1 and the above-described repeating unit p2 in the graft chain is preferably 50 mol % or more, more preferably 70 mol % or more, and still more preferably 85 mol % or more with respect to the total molar amount of repeating units included in the graft chain. In addition, the total content of the above-described repeating unit p1 and the above-described repeating unit p2 in the resin A is preferably 30 mol % or more, more preferably 40 mol % or more, still more preferably 50 mol % or more, even more preferably 60 mol % or more, even still more preferably 70 mol % or more, and particularly preferably 85 mol % or more with respect to the total molar amount of repeating units included in the resin A. The upper limit is not particularly limited, and may be 100 mol % or less, 90 mol % or less, or 95 mol % or less.

A weight-average molecular weight of the graft chain represented by P^{1a} is preferably 500 to 10000.

The repeating unit represented by Formula (a1-1) is preferably a repeating unit represented by Formula (a-1-1).

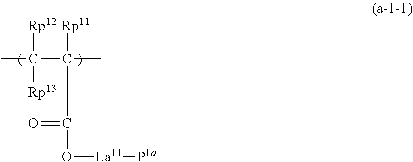

In the formula, Ra¹¹ to Ra¹³ each independently represent a hydrogen atom, an alkyl group, or an aryl group, La¹¹ represents a divalent linking group, P^{1a} represents a graft chain including the above-described repeating unit p1.

The graft chain represented by P^{1a} in Formula (a-1-1) has the same meaning as P^{1a} in Formula (a1-1) described above, and the preferred range is also the same.

The alkyl group represented by Ra¹¹ to Ra¹³ preferably has 1 to 10 carbon atoms, more preferably has 1 to 5 carbon atoms, and still more preferably has 1 to 3 carbon atoms. The alkyl group may be linear, branched, or cyclic forms, and is preferably linear or branched and more preferably linear. The aryl group represented by Ra¹¹ to Ra¹³ preferably has 6 to 20 carbon atoms, more preferably has 6 to 12 carbon atoms, and still more preferably has 6 to 10 carbon atoms. Ra¹¹ is preferably a hydrogen atom or an alkyl group. Ra¹² and Ra¹³ are preferably hydrogen atoms.

Examples of the divalent linking group represented by La¹¹ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups. The alkylene group and the arylene group may have a substituent. Examples of the substituent include a hydroxy group and a halogen atom. The divalent linking group represented by La¹¹ is preferably the group represented by Formula (L-1) described above.

The repeating unit represented by Formula (a1-1) is preferably a repeating unit represented by Formula (a-1-2).

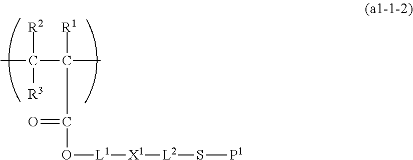

In the formula, R¹ to R³ each independently represent a hydrogen atom, an alkyl group, or an aryl group,

L¹ and L² each independently represent a divalent linking group, X¹ represents a single bond, —O—, —COO—, —OCO—, —NHCOO—, —OCONH—, or —NHCONH—, and

P¹ represents a graft chain including the above-described repeating unit p1.

The graft chain represented by P¹ in Formula (a-1-2) has the same meaning as P^{1a} in Formula (a1-1) described above, and the preferred range is also the same.

R¹ to R³ in Formula (a-1-2) have the same meaning as Ra¹¹ to Ra¹³ in Formula (a-1-1) described above, and the preferred ranges are also the same.

Examples of the divalent linking group represented by L¹ and L² in Formula (a-1-2) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups. The alkylene group and the arylene group may have a substituent. In a case where X¹ is —O—, —COO—, —OCO—, —NHCOO—, —OCONH—, or —NHCONH—, L¹ and L² are each independently preferably an alkylene group or an arylene group, and more preferably an alkylene group.

X¹ is preferably —O—, —COO—, —OCO—, —NHCOO—, —OCONH—, or —NHCONH—, and more preferably —NHCOO— or —OCONH—.

The content of the repeating unit represented by Formula (a1-1) described above in the resin A is preferably 5 mol % or more, more preferably 10 mol % or more, still more preferably 15 mol % or more, and even more preferably 20 mol % or more with respect to the total molar amount of repeating units included in the main chain of the resin A. The upper limit is not particularly limited, and may be 100 mol % or less, 90 mol % or less, 80 mol % or less, 70 mol % or less, 60 mol % or less, or 50 mol % or less.

In addition, the content of the repeating unit represented by Formula (a1-1) in the resin A is preferably 30% by mass or more, more preferably 40% by mass or more, and still more preferably 50% by mass or more with respect to the mass of the resin A. The upper limit may be 100% by mass or less, 95% by mass or less, 90% by mass or less, or 85% by mass or less.

The main chain of the resin A may include a repeating unit (also referred to as other repeating units) other than the repeating unit represented by Formula (a1-1). Examples of the other repeating units include a repeating unit having an acid group, a repeating unit having a basic group, a repeating unit having a crosslinkable group, a repeating unit having a group (protected carboxy group) in which a carboxy group is protected by a heat-decomposable group.

In a case where the main chain of the resin A includes a repeating unit having an acid group, dispersibility of the coloring material is further improved. Examples of the acid group include a phenolic hydroxy group, a carboxy group, a sulfo group, and a phosphoric acid group. Examples of a structure of the repeating unit having an acid group include a polyester repeating unit, a polyether repeating unit, and a repeating unit derived from a compound having an ethylenically unsaturated bond-containing group, and from the viewpoint of heat resistance of the obtained film, a repeating unit derived from a compound having an ethylenically unsaturated bond-containing group, and a polyvinyl repeating unit, a poly(meth)acrylic repeating unit, or a (poly)styrene repeating unit is more preferable. In a case where the main chain of the resin A includes the repeating unit having an acid group, an acid value of the resin A is preferably 20 to 200 mgKOH/g. The lower limit of the above-described acid value is preferably 30 mgKOH/g or more and more preferably 50 mgKOH/g or more. The upper limit of the above-described acid value is preferably 150 mgKOH/g or less. In addition, the content of the repeating unit having an acid group in the resin A is preferably 30 to 90 mol %, more preferably 50 to 85 mol %, and still more preferably 60 to 80 mol % with respect to the total molar amount of repeating units included in the main chain of the resin A.

In a case where the main chain of the resin A includes a repeating unit having a basic group, dispersibility of the coloring material is further improved. The basic group is preferably an amino group, more preferably a cyclic amino group, a secondary amino group, or a tertiary amino group, and still more preferably a tertiary amino group. Examples of the secondary amino group include a monoalkylamino group and a monoarylamino group, and a monoalkylamino group is preferable. Examples of the tertiary amino group include a dialkylamino group, a diarylamino group, and an alkylarylamino group, and a dialkylamino group is preferable. Examples of a structure of the repeating unit having a basic group include a polyester repeating unit, a polyether repeating unit, and a repeating unit derived from a compound having an ethylenically unsaturated bond-containing group, and from the viewpoint of heat resistance of the obtained film, a repeating unit derived from a compound having an ethylenically unsaturated bond-containing group, and a polyvinyl repeating unit, a poly(meth)acrylic repeating unit, or a (poly)styrene repeating unit is more preferable. In a case where the main chain of the resin A includes the repeating unit having a basic group, an amine value of the resin A is preferably 20 to 200 mgKOH/g. The lower limit of the above-described amine value is preferably 30 mgKOH/g or more and more preferably 50 mgKOH/g or more. The upper limit of the above-described amine value is preferably 150 mgKOH/g or less. In addition, the content of the repeating unit having a basic group in the resin A is preferably 30 to 90 mol %, more preferably 50 to 85 mol %, and still more preferably 60 to 80 mol % with respect to the total molar amount of repeating units included in the main chain of the resin A.

In a case where the main chain of the resin A includes a repeating unit having a crosslinkable group, it is easy to form a film having more excellent heat resistance. Examples of the crosslinkable group include an ethylenically unsaturated bond-containing group and a cyclic ether group. Examples of the ethylenically unsaturated bond-containing group include a (meth)acryloyl group, a (meth)acryloyloxy group, a (meth)acrylamide group, a vinylphenyl group, and an allyl group, and from the viewpoint of reactivity, a (meth)acryloyloxy group is preferable. Examples of the cyclic ether group include an epoxy group and an oxetane group. Examples of a structure of the repeating unit having a crosslinkable group include a polyester repeating unit, a polyether repeating unit, and a repeating unit derived from a compound having an ethylenically unsaturated bond-containing group, and from the viewpoint of heat resistance of the obtained film, a repeating unit derived from a compound having an ethylenically unsaturated bond-containing group, and a polyvinyl repeating unit, a poly(meth)acrylic repeating unit, or a (poly)styrene repeating unit is more preferable. The content of the repeating unit having a crosslinkable group in the resin A is preferably 10 to 60 mol %, more preferably 15 to 50 mol %, and still more preferably 20 to 40 mol % with respect to the total molar amount of repeating units included in the main chain of the resin A.

The repeating unit having a protected carboxy group in the main chain of the resin A can further promote the crosslinking reaction of the oxetane group during film formation, and it is easy to form a film having more excellent heat resistance. Examples of the protected carboxy group include groups having the above-described structures, and the same applies to the preferred range. Examples of a structure of the repeating unit having a protected carboxy group include a polyester repeating unit, a polyether repeating unit, and a repeating unit derived from a compound having an ethylenically unsaturated bond-containing group, and from the viewpoint of heat resistance of the obtained film, a repeating unit derived from a compound having an ethylenically unsaturated bond-containing group, and a polyvinyl repeating unit, a poly(meth)acrylic repeating unit, or a (poly)styrene repeating unit is more preferable. The content of the repeating unit having a protected carboxy group in the resin A is preferably 10 to 60 mol %, more preferably 15 to 50 mol %, and still more preferably 20 to 40 mol % with respect to the total molar amount of repeating units included in the main chain of the resin A.

In addition, the repeating unit (other repeating units) other than the repeating unit having the above-described graft chain included in the main chain of the resin A may be a repeating unit derived from a compound capable of copolymerizing with the repeating unit p1.

A weight-average molecular weight (Mw) of the resin A is preferably 5000 to 100000, more preferably 10000 to 100000, and still more preferably 10000 to 50000.

The maximum value of a molar absorption coefficient of the resin A in a wavelength of 400 to 1100 nm is preferably 0 to 1000 L·mol⁻¹·cm⁻¹, and more preferably 0 to 100 L·mol⁻¹·cm⁻¹.

From the reason that it is easy to form a film having more excellent heat resistance (crack suppression and film contraction suppression), an oxetane ratio of the resin A is preferably 20 to 95 mol %. The lower limit of the oxetane ratio is preferably 30 mol % or more, more preferably 40 mol % or more, still more preferably 50 mol % or more, and particularly preferably 60 mol % or more. The upper limit of the oxetane ratio is preferably 90 mol % or less, more preferably 85 mol % or less, and still more preferably 80 mol % or less. In the present specification, the oxetane ratio of the resin A means a mole fraction of repeating units having an oxetane group included in all repeating units of the resin A. As the oxetane ratio of the resin A is higher, heat resistance of the obtained film is improved.

An oxetane group value of the resin A is preferably 0.01 to 5 mmol/g. The lower limit of the oxetane group value is preferably 0.02 mmol/g or more, more preferably 0.03 mmol/g or more, still more preferably 0.05 mmol/g or more, and particularly preferably 0.10 mmol/g or more. The upper limit of the oxetane group value is preferably 3 mmol/g or less, more preferably 2 mmol/g or less, still more preferably 1.5 mmol/g or less, and particularly preferably 1 mmol/g or less. The oxetane group value of the resin A refers to the number of oxetane groups included in 1 g of the resin A.

The resin A preferably has a 5% by mass reduction temperature of 280° C. or higher, more preferably 300° C. or higher, and still more preferably 320° C. or higher by a thermogravimetry/differential thermal analysis (TG/DTA) under a nitrogen atmosphere. The upper limit of the above-described 5% by mass reduction temperature is not particularly limited, and for example, may be 1,000° C. or lower. The 5% by mass reduction temperature is determined by a known TG/DTA measuring method as a temperature at which the mass reduction rate is 5% in a case of being allowed to stand at a specific temperature for 5 hours under a nitrogen atmosphere.

In addition, the resin A preferably has a mass reduction rate of 10% or less, more preferably 5% or less, and still more preferably 2% or less in a case of being allowed to stand at 300° C. for 5 hours under a nitrogen atmosphere. The lower limit of the above-described mass reduction rate is not particularly limited, and may be 0% or more.

The mass reduction rate is a value calculated as a proportion of mass reduction in the resin A before and after being allowed to stand at 300° C. for 5 hours under a nitrogen atmosphere.

The resin preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is a graft resin. With regard to details of the graft resin, reference can be made to the description in paragraph Nos. 0025 to 0094 of JP2012-255128A, the contents of which are incorporated herein by reference. In addition, it is also preferable to use the above-described resin A as a dispersant.

It is also preferable that the resin used as a dispersant is a resin (resin Ac) having an aromatic carboxyl group. Examples of the resin having an aromatic carboxyl group include those described above.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. The content of the repeating unit having an ethylenically unsaturated bond-containing group in the side chain is preferably 10 mol % or more, more preferably 10 to 80 mol %, and still more preferably 20 to 70 mol % with respect to the total repeating units of the resin. In addition, as the dispersant, a resin described in JP2018-087939A can also be used.

A commercially available product is also available as the dispersant, and specific examples thereof include DISPERBYK series manufactured by BYK Chemie, Solsperse series manufactured by Lubrizol Japan Ltd., Efka series manufactured by BASF, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the resin used as a dispersant, block copolymers (EB-1) to (EB-9) described in paragraph Nos. 0219 to 0221 of JP6432077B can also be used.

A content of the resin in the total solid content of the coloring composition is preferably 1% to 80% by mass. The lower limit is preferably 5% by mass or more, more preferably 10% by mass or more, still more preferably 15% by mass or more, and particularly preferably 20% by mass or more. The upper limit is preferably 70% by mass or less, more preferably 60% by mass or less, still more preferably 50% by mass or less, and particularly preferably 40% by mass or less. The coloring composition according to the embodiment of the present invention may contain one resin or two or more kinds of resins. In a case of containing two or more kinds of resins, it is preferable that the total amount thereof is within the above-described range.

<<Solvent>>

The coloring composition according to the embodiment of the present invention contains a solvent. Examples of the solvent include an organic solvent. Basically, the type of the solvent is not particularly limited as long as it satisfies solubility of the respective components or coating properties of the composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the coloring composition is preferably 10% to 95% by mass, more preferably 20% to 90% by mass, and still more preferably 30% to 90% by mass.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

<<Pigment Derivative>>

The coloring composition according to the embodiment of the present invention can contain a pigment derivative. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

In addition, as the pigment derivative, a compound having a triazine skeleton and a structure having an acid group or a basic group can also be preferably used. Since the triazine skeleton of the pigment derivative and the pteridin skeleton of the pteridin pigment are similar, the pigment derivative is easily adsorbed on the surface of the pteridin pigment. As a result, it is presumed that a strong network is formed between the pteridin pigment, the pigment derivative, and the resin. By forming such a network, the dispersibility of the pteridin pigment in the coloring composition can be further improved, and the temporal stability of the coloring composition can be further improved. Further, it is easy to form a film in which generation of defects is suppressed. In addition, by strengthening the network between the pigment and the resin, the pigment can be easily developed together with the resin, and the developability can be further improved.

As the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later; compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A; and diketopyrrolopyrrole compounds having a thiol linking group, described in WO2020/002106A.

In a case of containing a pigment derivative, a content of the pigment derivative is preferably 1 to 30 parts by mass, more preferably 2 to 15 parts by mass, and still more preferably 4 to 10 parts by mass with respect to 100 parts by mass of the pigment. The pigment derivative may be used singly or in combination of two or more kinds thereof. In a case where two or more kinds thereof are used in combination, the total amount thereof is preferably within the above-described range.

<<Polymerizable Compound>>

The coloring composition according to the embodiment of the present invention can contain a polymerizable compound. As the polymerizable compound, a known compound which is cross-linkable by a radical, an acid, or heat can be used. In the present invention, the polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

In addition, as the polymerizable compound, a compound having a caprolactone structure can also be used. Examples of a commercially available product of the polymerizable compound having a caprolactone structure include KAYARAD DPCA-20, DPCA-30, DPCA-60, and DPCA-120 (all manufactured by Nippon Kayaku Co., Ltd.).

In addition, as the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

In addition, as the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable compound in the total solid content of the coloring composition is preferably 0.1% to 50% by mass. The lower limit is more preferably 0.5% by mass or more and still more preferably 1% by mass or more. The upper limit is more preferably 45% by mass or less and still more preferably 40% by mass or less. The polymerizable compound may be used singly or in combination of two or more kinds thereof. In a case where two or more kinds thereof are used in combination, the total thereof is preferably within the above-described range.

<<Photopolymerization Initiator>>

The coloring composition according to the embodiment of the present invention can contain a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. The oxime compound including a fluorine atom is preferably a compound represented by Formula (OX-1).

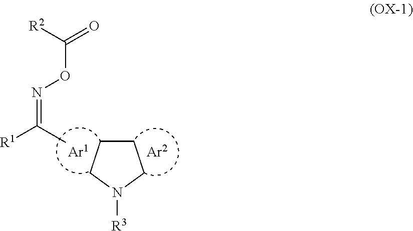

In Formula (OX-1), Ar¹ and Ar² each independently represent an aromatic hydrocarbon ring which may have a substituent, R¹ represents an aryl group having a group including a fluorine atom, and R² and R³ each independently represent an alkyl group or an aryl group.

The aromatic hydrocarbon ring represented by Ar¹ and Ar² in Formula (OX-1) may be a single ring or a fused ring. The number of carbon atoms constituting the ring of the aromatic hydrocarbon ring is preferably 6 to 20, more preferably 6 to 15, and particularly preferably 6 to 10. The aromatic hydrocarbon ring is preferably a benzene ring or a naphthalene ring. Among these, Ar¹ is preferably a benzene ring. Ar² is preferably a benzene ring or a naphthalene ring, and more preferably a naphthalene ring.

Examples of the substituent which may be included in Ar¹ and Ar² include an alkyl group, an aryl group, a heterocyclic group, a nitro group, a cyano group, a halogen atom, —OR^{X1}, —SR^{X1}, —COR^{X1}, —COOR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}. R^{X1} and R^{X2} each independently represent a hydrogen atom, an alkyl group, an aryl group, or a heterocyclic group.

Examples of the halogen atom include a fluorine atom, a chlorine atom, a bromine atom, and an iodine atom, and a fluorine atom is preferable. The alkyl group as the substituent and the alkyl group represented by R^{X1} and R^{X2} preferably have 1 to 30 carbon atoms. The alkyl group may be linear, branched, or cyclic, and is preferably linear or branched. In the alkyl group, a part or all of the hydrogen atoms may be substituted with halogen atoms (preferably fluorine atoms). In addition, in the alkyl group, a part or all of the hydrogen atoms may be substituted with the above-described substituents. The number of carbon atoms of the aryl group as the substituent and the aryl group represented by R^{X1} and R^{X2} is preferably 6 to 20, more preferably 6 to 15, and still more preferably 6 to 10. The aryl group may be a single ring or a fused ring. In addition, in the aryl group, a part or all of the hydrogen atoms may be substituted with the above-described substituents. The heterocyclic group as the substituent and the heterocyclic group represented by R^{X1} and R^{X2} are preferably a 5-membered ring or a 6-membered ring. The heterocyclic group may be a single ring or a fused ring. The number of carbon atoms constituting the heterocyclic group is preferably 3 to 30, more preferably 3 to 18, and more preferably 3 to 12. The number of heteroatoms constituting the heterocyclic group is preferably 1 to 3. The heteroatom constituting the heterocyclic group is preferably a nitrogen atom, an oxygen atom, or a sulfur atom. In addition, in the heterocyclic group, a part or all of the hydrogen atoms may be substituted with the above-described substituents.

The aromatic hydrocarbon ring represented by Ar¹ is preferably an unsubstituted aromatic hydrocarbon ring. The aromatic hydrocarbon ring represented by Ar² preferably has a substituent. As the substituent, —COR^{X1} is preferable. R^{X1} is preferably an alkyl group, an aryl group, or a heterocyclic group, and more preferably an aryl group. The aryl group may have a substituent or may be unsubstituted. Examples of the substituent include an alkyl group having 1 to 10 carbon atoms.

R¹ in Formula (OX-1) represents an aryl group having a group including a fluorine atom. The aryl group preferably has 6 to 20 carbon atoms, more preferably has 6 to 15 carbon atoms, and still more preferably has 6 to 10 carbon atoms. The group including a fluorine atom is preferably an alkyl group having a fluorine atom (hereinafter, also referred to as a fluorine-containing alkyl group) or a group including an alkyl group having a fluorine atom (hereinafter, also referred to as a fluorine-containing group). As the fluorine-containing group, at least one group selected from —OR^{F1}, —SR^{F1}, —COR^{F1}, —COOR^{F1}, —OCOR^{F1}, —NR^{F1}R^{F2}, —NHCOR^{F1}, —CONR^{F1}R^{F2}, —NHCONR^{F1}R^{F2}, —NHCOOR^{F1}, —SO₂R^{F1}, —SO₂OR^{F1}, and —NHSO₂R^{F1} is preferable. R^{F1} represents a fluorine-containing alkyl group, and R^{F2} represents a hydrogen atom, an alkyl group, a fluorine-containing alkyl group, an aryl group, or a heterocyclic group. The fluorine-containing group is preferably —OR^{F1}.

The fluorine-containing alkyl group represented by R^{F1} and R^{F2} and the alkyl group represented by R^{F2} preferably have 1 to 20 carbon atoms, more preferably have 1 to 15 carbon atoms, still more preferably have 1 to 10 carbon atoms, and particularly preferably 1 to 4 carbon atoms. The fluorine-containing alkyl group and the alkyl group may be linear, branched, or cyclic, and is preferably linear or branched. A substitution rate of fluorine atoms in the fluorine-containing alkyl group is preferably 40% to 100%, more preferably 50% to 100%, and still more preferably 60% to 100%. The substitution rate of fluorine atoms refers to a ratio (%) of the number substituted with fluorine atoms to the total number of hydrogen atoms in the alkyl group.

The aryl group represented by R^{F2} preferably has 6 to 20 carbon atoms, more preferably has 6 to 15 carbon atoms, and still more preferably has 6 to 10 carbon atoms.

The heterocyclic group represented by R^{F2} is preferably a 5-membered ring or a 6-membered ring. The heterocyclic group may be a single ring or a fused ring. The fused number is preferably 2 to 8, more preferably 2 to 6, still more preferably 3 to 5, and particularly preferably 3 or 4. The number of carbon atoms constituting the heterocyclic group is preferably 3 to 40, more preferably 3 to 30, and more preferably 3 to 20. The number of heteroatoms constituting the heterocyclic group is preferably 1 to 3. The heteroatom constituting the heterocyclic group is preferably a nitrogen atom, an oxygen atom, or a sulfur atom, and more preferably a nitrogen atom.

The group including a fluorine atom preferably has a terminal structure represented by Formula (1) or (2). * in the formulae represents a bonding site.

*—CHF₂ (1)

*—CF₃ (2)

R² in Formula (OX-1) represents an alkyl group or an aryl group, and is preferably an alkyl group. The alkyl group and the aryl group may be unsubstituted or may have a substituent. Examples of the substituent include the substituents described as the substituent which may be included in Ar¹ and Ar². The alkyl group preferably has 1 to 20 carbon atoms, more preferably has 1 to 15 carbon atoms, still more preferably has 1 to 10 carbon atoms, and particularly preferably has 1 to 4 carbon atoms. The alkyl group may be linear, branched, or cyclic, and is preferably linear or branched. The aryl group preferably has 6 to 20 carbon atoms, more preferably has 6 to 15 carbon atoms, and still more preferably has 6 to 10 carbon atoms.

R³ in Formula (OX-1) represents an alkyl group or an aryl group, and is preferably an alkyl group. The alkyl group and the aryl group may be unsubstituted or may have a substituent. Examples of the substituent include the substituents described as the substituent which may be included in Ar¹ and Ar². The alkyl group represented by R³ preferably has 1 to 20 carbon atoms, more preferably has 1 to 15 carbon atoms, and still more preferably has 1 to 10 carbon atoms. The alkyl group may be linear, branched, or cyclic, and is preferably linear or branched. The aryl group represented by R³ preferably has 6 to 20 carbon atoms, more preferably has 6 to 15 carbon atoms, and still more preferably has 6 to 10 carbon atoms.

Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include 0E-01 to 0E-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

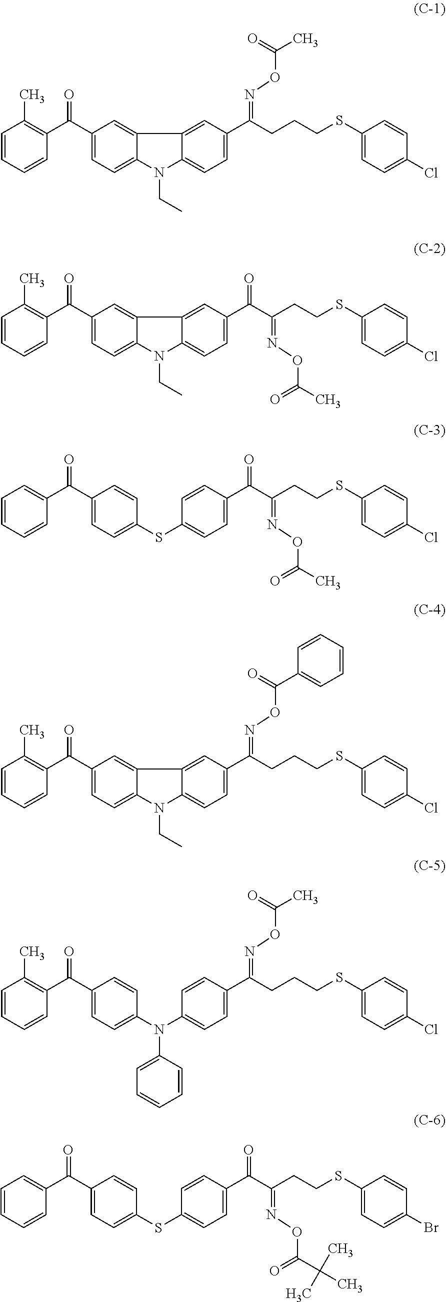 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

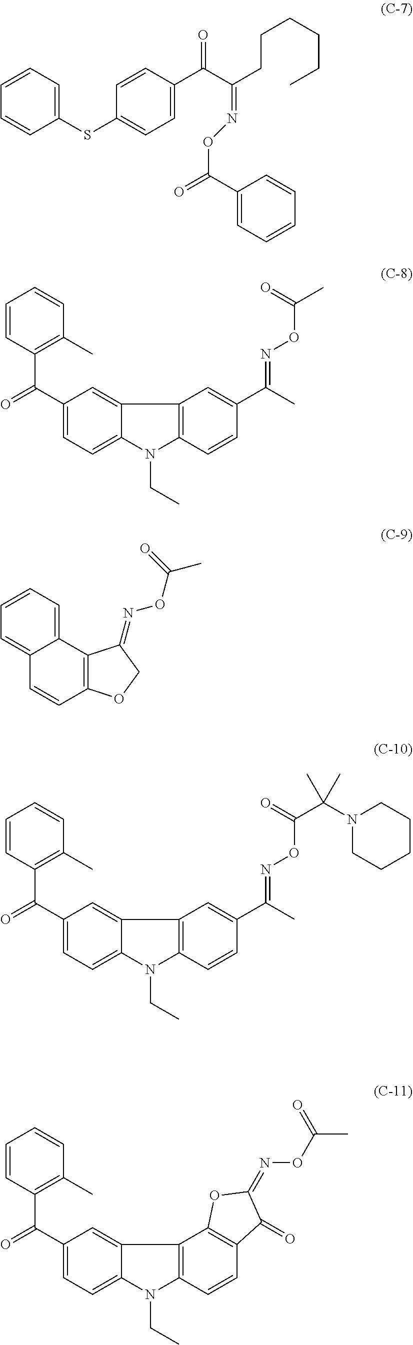

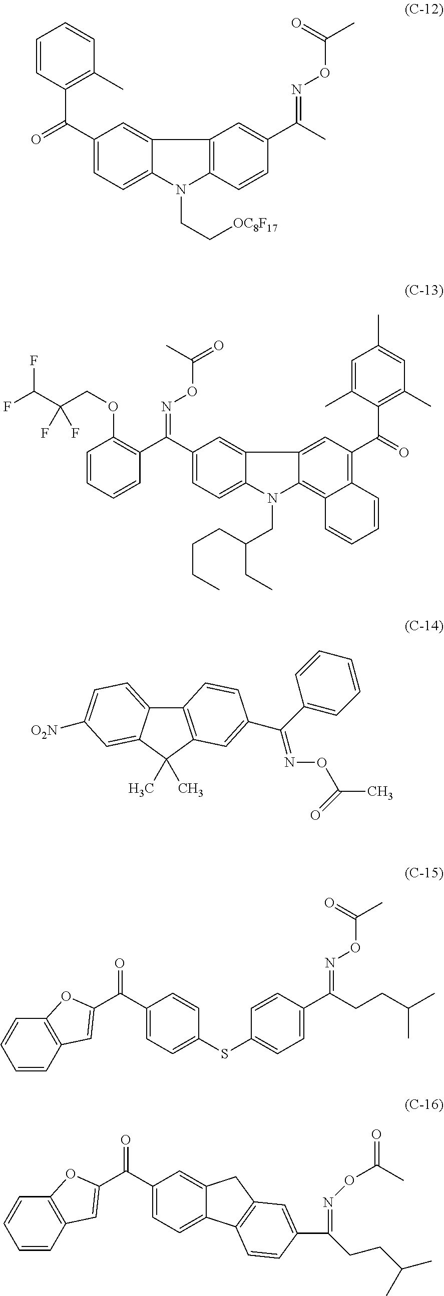

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

In a case of containing a photopolymerization initiator, a content of the photopolymerization initiator in the total solid content of the coloring composition is preferably 0.1% to 30% by mass. The lower limit is preferably 0.5% by mass or more and more preferably 1% by mass or more. The upper limit is preferably 20% by mass or less and more preferably 15% by mass or less. In the coloring composition according to the embodiment of the present invention, the photopolymerization initiator may be used singly or in combination of two or more kinds thereof. In a case where two or more kinds thereof are used, the total amount thereof is preferably within the above-described range.

<<Compound Having Cyclic Ether Group>>

The coloring composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

As the epoxy compound, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

A content of the compound having a cyclic ether group in the total solid content of the coloring composition is preferably 0.1% to 20% by mass. The lower limit is, for example, preferably 0.5% by mass or more and more preferably 1% by mass or more. The upper limit is, for example, preferably 15% by mass or less and still more preferably 10% by mass or less. The compound having a cyclic ether group may be used singly or in combination of two or more kinds thereof. In a case of using two or more kinds thereof, the total amount thereof is preferably within the above-described range.

<<Curing Accelerator>>

The coloring composition according to the embodiment of the present invention may contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds having an epoxy group described in JP2011-253054A, compounds described in paragraph Nos. 0085 to 0092 of JP5765059B, and carboxyl group-containing epoxy curing agent described in JP2017-036379A. In a case of containing a curing accelerator, a content of the curing accelerator in the total solid content of the coloring composition is preferably 0.3% to 8.9% by mass and more preferably 0.8% to 6.4% by mass.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd.), and Tinuvin series and Uvinul series manufactured by BASF. In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B, compounds described in paragraph Nos. 0059 to 0076 of WO2016/181987A, and thioaryl group-substituted benzotriazole type ultraviolet absorbers described in WO2020/137819A can also be used.

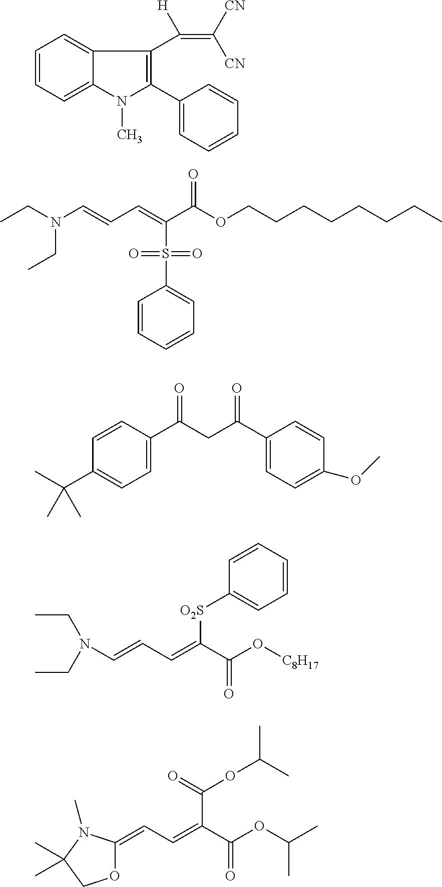

In a case of containing an ultraviolet absorber, a content of the ultraviolet absorber in the total solid content of the coloring composition is preferably 0.01% to 10% by mass and more preferably 0.01% to 5% by mass. In the present invention, the ultraviolet absorber may be used singly or in combination of two or more kinds thereof. In a case of using two or more kinds thereof, the total amount thereof is preferably within the above-described range.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. In a case of containing a polymerization inhibitor, a content of the polymerization inhibitor in the total solid content of the coloring composition is preferably 0.0001% to 5% by mass. The polymerization inhibitor may be used singly or in combination of two or more kinds thereof. In a case of two or more kinds thereof, the total amount thereof is preferably within the above-described range.

<<Silane Coupling Agent>>

The coloring composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. In a case of containing a silane coupling agent, a content of the silane coupling agent in the total solid content of the coloring composition is preferably 0.01% to 15.0% by mass and more preferably 0.05% to 10.0% by mass. The silane coupling agent may be used singly or in combination of two or more kinds thereof. In a case of two or more kinds thereof, the total amount thereof is preferably within the above-described range.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

In addition, as the surfactant, a silicone-based surfactant can be preferably used.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F475, F-477, F479, F482, F-554, F-555-A, F-556, F-557, F-558, F-559, F-560, F-561, F-565, F-563, F-568, F-575, F-780, EXP, MFS-330, R-01, R-30, R-40, R-40-LM, R-41, R-41-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FA, 710FL, 710FM, 710FS, and FTX-218 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

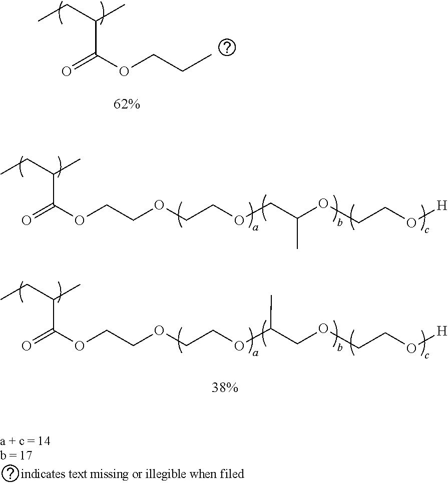

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by DuPont Toray Specialty Materials K.K.); TSF-4440, TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK Chemie).

In a case of containing a surfactant, a content of the surfactant in the total solid content of the coloring composition is preferably 0.001% to 5.0% by mass and more preferably 0.005% to 3.0% by mass. The surfactant may be used singly or in combination of two or more kinds thereof. In a case of two or more kinds thereof, the total amount thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. A content of the antioxidant in the total solid content of the coloring composition is preferably 0.01% to 20% by mass and more preferably 0.3% to 15% by mass. In a case of containing the antioxidant, the antioxidant may be used singly or in combination of two or more kinds thereof. In a case of using two or more kinds thereof, the total amount thereof is preferably within the above-described range.

<<Other Components>>

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference.

In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant.

The potential antioxidant is preferably a compound represented by Formula (AO-1).

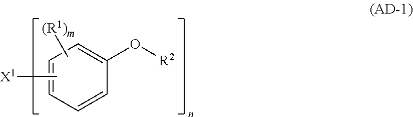

In the formula, R¹ represents a substituent,

R² represents —COOR¹¹, —CH₂—CH═CR¹²R¹³, —CH₂(—O-L^{R1})_{q}-O—R¹⁴, or —SiR¹⁵R¹⁶R¹⁷,

R¹¹, R¹², R¹⁴, R¹⁵, R¹⁶, and R¹⁷ each independently represent an alkyl group,

R¹³ represents a hydrogen atom or an alkyl group,

L^{R1} represents an alkylene group,

q represents 0 or 1,

in a case where q is 1, L^{R1} and R¹⁴ may be bonded to each other to form a ring,

m represents an integer of 0 to 4,

n represents an integer of 1 to 10, and

X¹ represents an n-valent group.

As the substituent represented by R¹ in Formula (AO-1), an alkyl group, an aryl group, or a heterocyclic group is preferable, and an alkyl group is more preferable. The alkyl group preferably has 1 to 30 carbon atoms, more preferably has 1 to 15 carbon atoms, and still more preferably 1 to 8 carbon atoms. The alkyl group may be linear, branched, or cyclic, but from the reason that the compound has a good function as a phenol-based antioxidant after elimination, the alkyl group is preferably branched or cyclic, and more preferably branched.

R² in Formula (AO-1) represents —COOR¹¹, —CH₂—CH═CR¹²R¹³, —CH₂(—O-L^{R1})_{q}-O—R¹⁴, or —SiR¹⁵R¹⁶R¹⁷. R¹¹, R¹⁴, R¹⁵, R¹⁶, and R¹⁷ each independently represent an alkyl group, R¹² and R¹³ each independently represent a hydrogen atom or an alkyl group, L^{R1} represents an alkylene group, q represents 0 or 1, and in a case where q is 1, L^{R1} and R¹⁴ may be bonded to each other to form a ring.

The alkyl group represented by R¹¹ preferably has 1 to 20 carbon atoms, more preferably has 1 to 10 carbon atoms, and still more preferably has 1 to 5 carbon atoms. The alkyl group may be linear, branched, or cyclic, but from the reason that an elimination temperature is appropriate, a branched alkyl group is preferable. The alkyl group represented by R¹¹ may have a substituent. As the substituent, an aryl group is preferable. Specific examples of R¹¹ include a tert-butyl group and a benzyl group.

The alkyl group represented by R¹² and R¹³ preferably has 1 to 20 carbon atoms, more preferably has 1 to 10 carbon atoms, and still more preferably has 1 to 5 carbon atoms. The alkyl group represented by R¹¹ and R¹² may be linear, branched, or cyclic, but from the reason that the compound can be produced at a lower cost, a linear or branched alkyl group is preferable, and a linear alkyl group is more preferable. Among these, R¹² and R¹³ are each independently preferably an alkyl group, and more preferably a methyl group.

The alkyl group represented by R¹⁴ preferably has 1 to 20 carbon atoms, more preferably has 1 to 10 carbon atoms, still more preferably has 1 to 5 carbon atoms, and particularly preferably has 1 to 3 carbon atoms. The alkyl group may be linear, branched, or cyclic, but from the reason that the compound can be produced at a lower cost, a linear alkyl group is preferable.

The alkyl group represented by R¹⁵ to R¹⁷ preferably has 1 to 20 carbon atoms, more preferably has 1 to 10 carbon atoms, still more preferably has 1 to 5 carbon atoms, and particularly preferably has 1 to 3 carbon atoms. The alkyl group may be linear, branched, or cyclic, but from the reason that the compound can be produced at a lower cost, a linear alkyl group is preferable.

The alkylene group represented by L^{R1} preferably has 1 to 20 carbon atoms, more preferably has 1 to 10 carbon atoms, still more preferably has 1 to 5 carbon atoms, and particularly preferably has 1 to 3 carbon atoms. The alkylene group may be linear, branched, or cyclic, but from the reason that the compound can be produced at a lower cost, a linear or branched alkylene group is preferable. In addition, L^{R1} and R¹⁴ may be bonded to each other to form a ring. In the group represented by “—CH₂(—O-L^{R1})_{q}-O—R¹⁴”, in a case where q is 0, the group has a structure represented by —CH₂—O—R¹⁴.

Specific examples of the group represented by R² include a tert-butoxycarbonyl group, a benzyloxycarbonyl group, a tetrahydropyranyl group, a methoxymethyl group, a 2-methoxyethoxymethyl group, a trimethylsilyl group, —CH₂—CH═C(CH₃)₂, and —CH₂—CH═CH₂, and a tert-butoxycarbonyl group or —CH₂—CH═C(CH₃)₂ is preferable.

Examples of the n-valent group represented by X¹ in Formula (AO-1) include an aliphatic hydrocarbon group, an aromatic hydrocarbon group, a heterocyclic group, —O—, —S—, —CO—, —COO—, —OCO—, —SO₂—, —NR^{X}—, —NR^{X}CO—, —CONR^{X}—, —NR^{X}SO₂—, —SO₂NR^{X}—, and a group consisting of a combination thereof, in which R^{X} represents a hydrogen atom, an alkyl group, or an aryl group. The aliphatic hydrocarbon group preferably has 1 to 20 carbon atoms, more preferably has 2 to 20 carbon atoms, still more preferably has 2 to 10 carbon atoms, and particularly preferably has 2 to 5 carbon atoms. The aliphatic hydrocarbon group may be linear, branched, or cyclic. In addition, the cyclic aliphatic hydrocarbon group may be a single ring or a fused ring. The aromatic hydrocarbon group preferably has 6 to 18 carbon atoms, more preferably 6 to 14 carbon atoms, and still more preferably 6 to 10 carbon atoms. The aromatic hydrocarbon group is preferably a single ring or a fused ring having 2 to 4 fused numbers. The aromatic hydrocarbon group is preferably a benzene ring group. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12. The aliphatic hydrocarbon group, the aromatic hydrocarbon group, and the heterocyclic group may have a substituent. In addition, the alkyl group represented by R^{X} preferably has 1 to 20 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The alkyl group represented by R^{X} may further have a substituent. The aryl group represented by R^{X} preferably has 6 to 30 carbon atoms, more preferably has 6 to 20 carbon atoms, and still more preferably has 6 to 12 carbon atoms. The aryl group represented by R^{X} may further have a substituent.

m in Formula (AO-1) represents an integer of 0 to 4, and is preferably an integer of 0 to 3, more preferably an integer of 0 to 2, and particularly preferably 1 or 2.

n in Formula (AO-1) represents an integer of 1 to 10, and the lower limit of n is preferably 2 or more and more preferably 3 or more. The upper limit of n is preferably 6 or less and more preferably 4 or less.

Specific examples of the potential antioxidant include compounds described in Examples described later, compounds described in WO2014/021023A, WO2017/030005A, and JP2017-008219A. Examples of a commercially available product of the potential antioxidant include ADEKAARKLS GPA-5001 (manufactured by ADEKA Corporation).

In the coloring composition according to the embodiment of the present invention, as described in JP2018-155881A, C. I. Pigment Yellow 129 may be added for the purpose of improving weather fastness. In addition, the coloring composition according to the embodiment of the present invention may contain an aromatic group-containing phosphonium salt described in JP2020-079833A.

In order to adjust the refractive index of a film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The coloring composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

The moisture content in the coloring composition according to the embodiment of the present invention is usually 3% by mass or less, preferably 0.01% to 1.5% by mass and more preferably in a range of 0.1% to 1.0% by mass. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

A storage container of the coloring composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A.

<Method of Preparing Coloring Composition>

The coloring composition according to the embodiment of the present invention can be prepared by mixing the above-described components with each other. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha, Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described coloring composition according to the embodiment of the present invention. The film according to the embodiment of the present invention can be used for an optical filter such as a color filter or an infrared transmitting filter.

A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In a case where the film according to the embodiment of the present invention is used as a color filter, the film according to the embodiment of the present invention preferably has a hue of green, red, blue, cyan, magenta, or yellow, and more preferably has a hue of green, red, or yellow. In addition, the film according to the embodiment of the present invention can be preferably used as a colored pixel of a color filter. Examples of the colored pixel include a red pixel, a green pixel, a blue pixel, a magenta pixel, a cyan pixel, and a yellow pixel, and a red pixel, a green pixel, or a yellow pixel is preferable.

In a case where the film according to the embodiment of the present invention is used as an infrared transmitting filter, it is preferable that the film according to the embodiment of the present invention has, for example, any one of the following spectral characteristics (1) to (4).

(1): maximum value of a light transmittance of the film in a thickness direction in a wavelength range of 400 to 640 nm is 20% or less (preferably 15% or less and more preferably 10% or less) and the minimum value of a light transmittance of the film in the thickness direction in a wavelength range of 800 to 1300 nm is 70% or more (preferably 75% or more and more preferably 80% or more). A film having such spectral characteristics can shield light having a wavelength range of 400 to 640 nm, and can transmit light having a wavelength exceeding 700 nm.

(2): film in which the maximum value of a light transmittance of the film in a thickness direction in a wavelength range of 400 to 750 nm is 20% or less (preferably 15% or less and more preferably 10% or less) and the minimum value of a light transmittance of the film in the thickness direction in a wavelength range of 900 to 1300 nm is 70% or more (preferably 75% or more and more preferably 80% or more). A film having such spectral characteristics can shield light having a wavelength range of 400 to 750 nm, and can transmit light having a wavelength exceeding 850 nm.

(3): film in which the maximum value of a light transmittance of the film in a thickness direction in a wavelength range of 400 to 830 nm is 20% or less (preferably 15% or less and more preferably 10% or less) and the minimum value of a light transmittance of the film in the thickness direction in a wavelength range of 1000 to 1300 nm is 70% or more (preferably 75% or more and more preferably 80% or more). A film having such spectral characteristics can shield light having a wavelength range of 400 to 830 nm, and can transmit light having a wavelength exceeding 940 nm.

(4): film in which the maximum value of a light transmittance of the film in a thickness direction in a wavelength range of 400 to 950 nm is 20% or less (preferably 15% or less and more preferably 10% or less) and the minimum value of a light transmittance of the film in the thickness direction in a wavelength range of 1100 to 1300 nm is 70% or more (preferably 75% or more and more preferably 80% or more). A film having such spectral characteristics can shield light having a wavelength range of 400 to 950 nm, and can transmit light having a wavelength exceeding 1040 nm.

<Method for Producing Film>

Next, a method for producing the film according to the embodiment of the present invention will be described. The film according to the embodiment of the present invention can be formed through a step of applying the coloring composition according to the embodiment of the present invention. The method for producing the film preferably further includes a step of forming a pattern (pixel). Examples of a method for forming the pattern (pixel) include a photolithography method and a dry etching method, and a photolithography method is preferable.

Pattern formation by a photolithography method preferably includes a step of forming a coloring composition layer on a support using the coloring composition according to the embodiment of the present invention, a step of exposing the coloring composition layer in a patterned manner, and a step of removing a non-exposed portion of the coloring composition layer by development to form a pattern (pixel). A step (pre-baking step) of baking the coloring composition layer and a step (post-baking step) of baking the developed pattern (pixel) may be provided, optionally.

In the step of forming a coloring composition layer, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. The base layer may be formed of a composition obtained by removing the coloring material from the coloring composition described in the present specification, a composition including the curable compound, surfactant, and the like described in the present specification, or the like. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the resin composition is good. The surface contact angle of the base layer can be adjusted by, for example, adding a surfactant.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and a metal mask printing; a transfer method using a mold or the like; and a nanoimprinting method. A method for applying the ink jet is not particularly limited, and examples thereof include a method described in “Extension of Use of Ink Jet—Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Optical Filter>

An optical filter according to an embodiment of the present invention has the above-described film according to the embodiment of the present invention. Examples of the type of the optical filter include a color filter and an infrared transmitting filter, and a color filter is preferable. As the color filter, it is preferable to have the film according to the embodiment of the present invention as a colored pixel of the color filter.

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. The partition wall in this case preferably has a low refractive index for each colored pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Production of Dispersion Liquid>

Raw materials described in the following table were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical value of the blending amount of each material in the tables below is parts by mass. Each value of the blending amounts of the resins (dispersants) is the value of the blending amount in the resin solution having a solid content of 20% by mass. Evaluation results of temporal stability and color unevenness of each dispersion liquid are also described.

TABLE 1

| | | | | | | | | | | Pigment |
|---|---|---|---|---|---|---|---|---|---|---|
| | Coloring material | | | | | | | | | derivative |
| Dispersion | | | | | | | | | Yellow | Derivative |
| liquid | PG58 | PG36 | PG62 | SQ1 | PT1 | PY150 | PY185 | PY129 | 1 | 1 |
| Dispersion | 14 | | | | 0.5 | | | | | |
| liquid G1 | | | | | | | | | | |
| Dispersion | 13.5 | | | | 1 | | | | | |
| liquid G2 | | | | | | | | | | |
| Dispersion | 13 | | | | 1.5 | | | | | |
| liquid G3 | | | | | | | | | | |
| Dispersion | 10 | | | | 4.5 | | | | | |
| liquid G4 | | | | | | | | | | |
| Dispersion | | 10 | | | 4.5 | | | | | |
| liquid G5 | | | | | | | | | | |
| Dispersion | | | 10 | | 4.5 | | | | | |
| liquid G6 | | | | | | | | | | |
| Dispersion | | | | 10 | 4.5 | | | | | |
| liquid G7 | | | | | | | | | | |
| Dispersion | 10 | | | | 2 | 2.5 | | | | |
| liquid G8 | | | | | | | | | | |
| Dispersion | 10 | | | | 2 | | 2.5 | | | |
| liquid G9 | | | | | | | | | | |
| Dispersion | 10 | | | | 2 | | | 2.5 | | |
| liquid G10 | | | | | | | | | | |
| Dispersion | 10 | | | | 2 | | | | 2.5 | |
| liquid G11 | | | | | | | | | | |
| Dispersion | 10 | | | | 2 | | 0.5 | 2 | | |
| liquid G12 | | | | | | | | | | |
| Dispersion | 8.5 | | | | 2 | 1 | 1 | 2 | | |
| liquid G13 | | | | | | | | | | |
| Dispersion | | 10 | | | 2 | | 0.5 | 2 | | |
| liquid G14 | | | | | | | | | | |
| Dispersion | | 8.5 | | | 2 | 1 | 1 | 2 | | |
| liquid G15 | | | | | | | | | | |
| Dispersion | | 10 | | | 2 | | | | 2.5 | 0.5 |
| liquid G16 | | | | | | | | | | |
| Dispersion | 10 | | | | 4.5 | | | | | 0.5 |
| liquid G17 | | | | | | | | | | |
| Dispersion | 10 | | | | 4.5 | | | | | |
| liquid G18 | | | | | | | | | | |
| Dispersion | 10 | | | | 4.5 | | | | | |
| liquid G19 | | | | | | | | | | |
| Dispersion | | 9 | | | 2.8 | | | 2.7 | | |
| liquid G20 | | | | | | | | | | |
| Dispersion | | 9 | | | 2.2 | | 0.4 | 2.9 | | |
| liquid G21 | | | | | | | | | | |
| Dispersion | | 9.3 | | | 2.2 | | 0.8 | 2.2 | | |
| liquid G22 | | | | | | | | | | |
| Dispersion | | 9 | | | 1.5 | 1.3 | | 2.7 | | |
| liquid G23 | | | | | | | | | | |
| Comparative | 13 | | | | | | | | 1.5 | |
| dispersion | | | | | | | | | | |
| liquid G1 | | | | | | | | | | |
| Comparative | 10 | | | | | | | | 4.5 | |
| dispersion | | | | | | | | | | |
| liquid G2 | | | | | | | | | | |
| | | | | | | | Concentration | Concentration | Performance of | |
| | | Pigment derivative | | | | | of coloring | of solid | dispersion liquid | |
| | Dispersion | Derivative | Derivative | Derivative | Resin | Solvent | material | contents | Temporal | Color |
| | liquid | 2 | 3 | 6 | B-3 | K-1 | (% by mass) | (% by mass) | stability | unevenness |
| | Dispersion | 0.5 | | | 25 | 60 | 14.5 | 20 | C | B |
| | liquid G1 | | | | | | | | | |
| | Dispersion | 0.5 | | | 25 | 60 | 14.5 | 20 | B | B |
| | liquid G2 | | | | | | | | | |
| | Dispersion | 0.5 | | | 25 | 60 | 14.5 | 20 | A | B |
| | liquid G3 | | | | | | | | | |
| | Dispersion | 0.5 | | | 25 | 60 | 14.5 | 20 | A | B |
| | liquid G4 | | | | | | | | | |
| | Dispersion | 0.5 | | | 25 | 60 | 14.5 | 20 | A | B |
| | liquid G5 | | | | | | | | | |
| | Dispersion | 0.5 | | | 25 | 60 | 14.5 | 20 | A | B |
| | liquid G6 | | | | | | | | | |
| | Dispersion | 0.5 | | | 25 | 60 | 14.5 | 20 | A | B |
| | liquid G7 | | | | | | | | | |
| | Dispersion | 0.5 | | | 25 | 60 | 14.5 | 20 | A | B |
| | liquid G8 | | | | | | | | | |
| | Dispersion | 0.5 | | | 25 | 60 | 14.5 | 20 | A | B |
| | liquid G9 | | | | | | | | | |
| | Dispersion | 0.5 | | | 25 | 60 | 14.5 | 20 | A | B |
| | liquid G10 | | | | | | | | | |
| | Dispersion | 0.5 | | | 25 | 60 | 14.5 | 20 | A | B |
| | liquid G11 | | | | | | | | | |
| | Dispersion | 0.5 | | | 25 | 60 | 14.5 | 20 | A | B |
| | liquid G12 | | | | | | | | | |
| | Dispersion | 0.5 | | | 25 | 60 | 14.5 | 20 | A | B |
| | liquid G13 | | | | | | | | | |
| | Dispersion | 0.5 | | | 25 | 60 | 14.5 | 20 | A | B |
| | liquid G14 | | | | | | | | | |
| | Dispersion | 0.5 | | | 25 | 60 | 14.5 | 20 | A | B |
| | liquid G15 | | | | | | | | | |
| | Dispersion | | | | 25 | 60 | 14.5 | 20 | A | B |
| | liquid G16 | | | | | | | | | |
| | Dispersion | | | | 25 | 60 | 14.5 | 20 | A | B |
| | liquid G17 | | | | | | | | | |
| | Dispersion | | 0.5 | | 25 | 60 | 14.5 | 20 | A | B |
| | liquid G18 | | | | | | | | | |
| | Dispersion | | | 0.5 | 25 | 60 | 14.5 | 20 | A | B |
| | liquid G19 | | | | | | | | | |
| | Dispersion | 0.5 | | | 25 | 60 | 14.5 | 20 | A | B |
| | liquid G20 | | | | | | | | | |
| | Dispersion | 0.5 | | | 25 | 60 | 14.5 | 20 | A | B |
| | liquid G21 | | | | | | | | | |
| | Dispersion | 0.5 | | | 25 | 60 | 14.5 | 20 | A | B |
| | liquid G22 | | | | | | | | | |
| | Dispersion | 0.5 | | | 25 | 60 | 14.5 | 20 | A | B |
| | liquid G23 | | | | | | | | | |
| | Comparative | 0.5 | | | 25 | 60 | 14.5 | 20 | D | D |
| | dispersion | | | | | | | | | |
| | liquid G1 | | | | | | | | | |
| | Comparative | 0.5 | | | 25 | 60 | 14.5 | 20 | D | D |
| | dispersion | | | | | | | | | |
| | liquid G2 | | | | | | | | | |

TABLE 2

| | | | | Pigment | Resin | | | | | | |
|---|---|---|---|---|---|---|---|---|---|---|---|
| Dispersion | Coloring material | | | derivative | A- | A- | B- | B- | B- | B- | B- |
| liquid | PG58 | PT1 | Yellow1 | Derivative 3 | 1 | 2 | 1 | 2 | 3 | 4 | 5 |
| Dispersion | 10 | 4.5 | | 0.5 | 25 | | | | | | |
| liquid G24 | | | | | | | | | | | |
| Dispersion | 10 | 4.5 | | 0.5 | | 25 | | | | | |
| liquid G25 | | | | | | | | | | | |
| Dispersion | 10 | 4.5 | | 0.5 | | | 25 | | | | |
| liquid G26 | | | | | | | | | | | |
| Dispersion | 10 | 4.5 | | 0.5 | | | | 25 | | | |
| liquid G27 | | | | | | | | | | | |
| Dispersion | 10 | 4.5 | | 0.5 | | | | | 25 | | |
| liquid G28 | | | | | | | | | | | |
| Dispersion | 10 | 4.5 | | 0.5 | | | | | | 25 | |
| liquid G29 | | | | | | | | | | | |
| Dispersion | 10 | 4.5 | | 0.5 | | | | | | | 25 |
| liquid G30 | | | | | | | | | | | |
| Dispersion | 10 | 4.5 | | 0.5 | | | | | | | |
| liquid G31 | | | | | | | | | | | |
| Dispersion | 10 | 4.5 | | 0.5 | | | | | | | |
| liquid G32 | | | | | | | | | | | |
| Dispersion | 10 | 4.5 | | 0.5 | 20 | | | | | | |
| liquid G33 | | | | | | | | | | | |
| Dispersion | 10 | 4.5 | | 0.5 | | 20 | | | | | |
| liquid G34 | | | | | | | | | | | |
| Dispersion | 10 | 4.5 | | 0.5 | | | 20 | | | | |
| liquid G35 | | | | | | | | | | | |
| Dispersion | 10 | 4.5 | | 0.5 | | | | | 20 | | |
| liquid G36 | | | | | | | | | | | |
| Dispersion | 10 | 4.5 | | 0.5 | | | | | 20 | | |
| liquid G37 | | | | | | | | | | | |
| Dispersion | 10 | 4.5 | | 0.5 | | | | | 20 | | |
| liquid G38 | | | | | | | | | | | |
| Dispersion | 10 | 4.5 | | | | | | | 20 | | |
| liquid G39 | | | | | | | | | | | |
| Comparative | 10 | | 4.5 | 0.5 | | | | | 20 | | |
| dispersion | | | | | | | | | | | |
| liquid G3 | | | | | | | | | | | |
| | | | | | | | | Concen- | Concen- | | |
| | | | | | | | | tration of | tration of | Performance of | |
| | | Resin | | | | | Sol- | coloring | solid | dispersion liqnid | |
| | Dispersion | B- | B- | C- | C- | C- | vent | material | contents | Temporal | Color |
| | liquid | 6 | 7 | 1 | 2 | 3 | K- 1 | (% by mass) | (% by mass) | stability | unevenness |
| | Dispersion | | | | | | 60 | 14.5 | 20 | B | B |
| | liquid G24 | | | | | | | | | | |
| | Dispersion | | | | | | 60 | 14.5 | 20 | B | B |
| | liquid G25 | | | | | | | | | | |
| | Dispersion | | | | | | 60 | 14.5 | 20 | A | B |
| | liquid G26 | | | | | | | | | | |
| | Dispersion | | | | | | 60 | 14.5 | 20 | A | B |
| | liquid G27 | | | | | | | | | | |
| | Dispersion | | | | | | 60 | 14.5 | 20 | A | B |
| | liquid G28 | | | | | | | | | | |
| | Dispersion | | | | | | 60 | 14.5 | 20 | A | B |
| | liquid G29 | | | | | | | | | | |
| | Dispersion | | | | | | 60 | 14.5 | 20 | A | B |
| | liquid G30 | | | | | | | | | | |
| | Dispersion | 25 | | | | | 60 | 14.5 | 20 | A | B |
| | liquid G31 | | | | | | | | | | |
| | Dispersion | | 25 | | | | 60 | 14.5 | 20 | A | B |
| | liquid G32 | | | | | | | | | | |
| | Dispersion | | | 5 | | | 60 | 14.5 | 20 | B | A |
| | liquid G33 | | | | | | | | | | |
| | Dispersion | | | 5 | | | 60 | 14.5 | 20 | B | A |
| | liquid G34 | | | | | | | | | | |
| | Dispersion | | | 5 | | | 60 | 14.5 | 20 | B | A |
| | liquid G35 | | | | | | | | | | |
| | Dispersion | | | 5 | | | 60 | 14.5 | 20 | A | A |
| | liquid G36 | | | | | | | | | | |
| | Dispersion | | | | 5 | | 60 | 14.5 | 20 | A | A |
| | liquid G37 | | | | | | | | | | |
| | Dispersion | | | | | 5 | 60 | 14.5 | 20 | A | A |
| | liquid G38 | | | | | | | | | | |
| | Dispersion | | | 7.5 | | | 58 | 14.5 | 20 | A | A |
| | liquid G39 | | | | | | | | | | |
| | Comparative | | | 5 | | | 60 | 14.5 | 20 | D | D |
| | dispersion | | | | | | | | | | |
| | liquid G3 | | | | | | | | | | |

TABLE 3

| | | | | | | | | | | Concentration | Concentration | Performance of | |
|---|---|---|---|---|---|---|---|---|---|---|---|---|---|
| | | | | | | | Pigment | | Sol- | of coloring | of solid | dispersion liquid | |
| Dispersion | Coloring material | | | | | | derivative | Resin | vent | material | contents | Temporal | Color |
| liquid | PG58 | PT1 | PT2 | PT3 | PT4 | PT5 | Derivative 1 | B-3 | K-1 | (% by mass) | (% by mass) | stability | unevenness |
| Dispersion | 10 | 4.5 | | | | | 0.5 | 25 | 60 | 14.5 | 20 | A | B |
| liquid G40 | | | | | | | | | | | | | |
| Dispersion | 10 | | 4.5 | | | | 0.5 | 25 | 60 | 14.5 | 20 | A | B |
| liquid G41 | | | | | | | | | | | | | |
| Dispersion | 10 | | | 4.5 | | | 0.5 | 25 | 60 | 14.5 | 20 | A | B |
| liquid G42 | | | | | | | | | | | | | |
| Dispersion | 10 | | | | 4.5 | | 0.5 | 25 | 60 | 14.5 | 20 | A | B |
| liquid G43 | | | | | | | | | | | | | |
| Dispersion | 10 | | | | | 4.5 | 0.5 | 25 | 60 | 14.5 | 20 | A | B |
| liquid G44 | | | | | | | | | | | | | |

TABLE 4

| | | | | | | | | | | | | | Concentration | Concentration | Performance of | |
|---|---|---|---|---|---|---|---|---|---|---|---|---|---|---|---|---|
| | | | | | | Pigment | Resin | | | | | Sol- | of coloring | of solid | dispersion liquid | |
| Dispersion | Coloring material | | | | | derivative | B- | B- | B- | B-1 | C- | vent | material | contents | Temporal | Color |
| liquid | PG58 | AP1 | AP2 | PT1 | SY82 | Derivative 3 | 3 | 8 | 9 | 0 | 3 | K-1 | (% by mass) | (% by mass) | stability | unevenness |
| Dispersion | 10 | | | 4.5 | | 0.5 | | 25 | | | | 60 | 14.5 | 20 | A | B |
| liquid G45 | | | | | | | | | | | | | | | | |
| Dispersion | 10 | | | 4.5 | | 0.5 | | | 25 | | | 60 | 14.5 | 20 | A | B |
| liquid G46 | | | | | | | | | | | | | | | | |
| Dispersion | 10 | | | 4.5 | | 0.5 | | | | 25 | | 60 | 14.5 | 20 | A | B |
| liquid G47 | | | | | | | | | | | | | | | | |
| Dispersion | 10 | | | 4.5 | | 0.5 | | 20 | | | 5 | 60 | 14.5 | 20 | A | A |
| liquid G48 | | | | | | | | | | | | | | | | |
| Dispersion | | 10 | | 4.5 | | 0.5 | 25 | | | | | 60 | 14.5 | 20 | A | B |
| liquid G49 | | | | | | | | | | | | | | | | |
| Dispersion | | | 10 | 4.5 | | 0.5 | 25 | | | | | 60 | 14.5 | 20 | A | B |
| liquid G50 | | | | | | | | | | | | | | | | |
| Dispersion | 10 | | | 4 | 0.5 | 0.5 | 25 | | | | | 60 | 14.5 | 20 | A | B |
| liquid G51 | | | | | | | | | | | | | | | | |

TABLE 5

| Dispersion | Coloring material | | | | | | | | |
|---|---|---|---|---|---|---|---|---|---|
| liquid | PR254 | PR264 | PR272 | PR177 | PR269 | PT1 | PY139 | PO71 | Yellow1 |
| Dispersion | 14 | | | | | 0.5 | | | |
| liquid R1 | | | | | | | | | |
| Dispersion | 13.5 | | | | | 1 | | | |
| liquid R2 | | | | | | | | | |
| Dispersion | 13 | | | | | 1.5 | | | |
| liquid R3 | | | | | | | | | |
| Dispersion | 10 | | | | | 4.5 | | | |
| liquid R4 | | | | | | | | | |
| Dispersion | | 10 | | | | 4.5 | | | |
| liquid R5 | | | | | | | | | |
| Dispersion | | | 10 | | | 4.5 | | | |
| liquid R6 | | | | | | | | | |
| Dispersion | | | | 10 | | 4.5 | | | |
| liquid R7 | | | | | | | | | |
| Dispersion | | | | | 10 | 4.5 | | | |
| liquid R8 | | | | | | | | | |
| Dispersion | 10 | | | | | 2 | 2.5 | | |
| liquid R9 | | | | | | | | | |
| Dispersion | 10 | | | | | 2 | | 2.5 | |
| liquid R10 | | | | | | | | | |
| Dispersion | 10 | | | | | 2 | | | 2.5 |
| liquid R11 | | | | | | | | | |
| Dispersion | | | | 10 | | 2 | | | 2.5 |
| liquid R12 | | | | | | | | | |
| Dispersion | 10 | | | | | 4.5 | | | |
| liquid R13 | | | | | | | | | |
| Dispersion | | | | 10 | | 4.5 | | | |
| liquid R14 | | | | | | | | | |
| Comparative | 13 | | | | | | | | 1.5 |
| dispersion | | | | | | | | | |
| liquid R1 | | | | | | | | | |
| Comparative | 10 | | | | | | | | 4.5 |
| dispersion | | | | | | | | | |
| liquid R2 | | | | | | | | | |
| | | | | | | Concentration | Concentration | Performance of | |
| | | | | | Sol- | of coloring | of solid | dispersion liquid | |
| Dispersion | Pigment derivative | | | Resin | vent | material | contents | Temporal | Color |
| liquid | Derivative 3 | Derivative 4 | Derivative 5 | B-3 | K-1 | (% by mass) | (% by mass) | stability | unevenness |
| Dispersion | 0.5 | | | 25 | 60 | 14.5 | 20 | C | B |
| liquid R1 | | | | | | | | | |
| Dispersion | 0.5 | | | 25 | 60 | 14.5 | 20 | B | B |
| liquid R2 | | | | | | | | | |
| Dispersion | 0.5 | | | 25 | 60 | 14.5 | 20 | A | B |
| liquid R3 | | | | | | | | | |
| Dispersion | 0.5 | | | 25 | 60 | 14.5 | 20 | A | B |
| liquid R4 | | | | | | | | | |
| Dispersion | 0.5 | | | 25 | 60 | 14.5 | 20 | A | B |
| liquid R5 | | | | | | | | | |
| Dispersion | 0.5 | | | 25 | 60 | 14.5 | 20 | A | B |
| liquid R6 | | | | | | | | | |
| Dispersion | 0.5 | | | 25 | 60 | 14.5 | 20 | A | B |
| liquid R7 | | | | | | | | | |
| Dispersion | 0.5 | | | 25 | 60 | 14.5 | 20 | A | B |
| liquid R8 | | | | | | | | | |
| Dispersion | 0.5 | | | 25 | 60 | 14.5 | 20 | A | B |
| liquid R9 | | | | | | | | | |
| Dispersion | 0.5 | | | 25 | 60 | 14.5 | 20 | A | B |
| liquid R10 | | | | | | | | | |
| Dispersion | 0.5 | | | 25 | 60 | 14.5 | 20 | A | B |
| liquid R11 | | | | | | | | | |
| Dispersion | | | 0.5 | 25 | 60 | 14.5 | 20 | A | B |
| liquid R12 | | | | | | | | | |
| Dispersion | | 0.5 | | 25 | 60 | 14.5 | 20 | A | B |
| liquid R13 | | | | | | | | | |
| Dispersion | | | 0.5 | 25 | 60 | 14.5 | 20 | A | B |
| liquid R14 | | | | | | | | | |
| Comparative | | 0.5 | | 25 | 60 | 14.5 | 20 | D | D |
| dispersion | | | | | | | | | |
| liquid R1 | | | | | | | | | |
| Comparative | | 0.5 | | 25 | 60 | 14.5 | 20 | D | D |
| dispersion | | | | | | | | | |
| liquid R2 | | | | | | | | | |

TABLE 6

| | | | | Pigment | Resin | | | | | | |
|---|---|---|---|---|---|---|---|---|---|---|---|
| Dispersion | Coloring material | | | derivative | A- | A- | B- | B- | B- | B- | B- |
| liquid | PR254 | PT1 | Yellow1 | Derivative 2 | 1 | 2 | 1 | 2 | 3 | 4 | 5 |
| Dispersion | 10 | 4.5 | | 0.5 | 25 | | | | | | |
| liquid R15 | | | | | | | | | | | |
| Dispersion | 10 | 4.5 | | 0.5 | | 25 | | | | | |
| liquid R16 | | | | | | | | | | | |
| Dispersion | 10 | 4.5 | | 0.5 | | | 25 | | | | |
| liquid R17 | | | | | | | | | | | |
| Dispersion | 10 | 4.5 | | 0.5 | | | | 25 | | | |
| liquid R18 | | | | | | | | | | | |
| Dispersion | 10 | 4.5 | | 0.5 | | | | | 25 | | |
| liquid R19 | | | | | | | | | | | |
| Dispersion | 10 | 4.5 | | 0.5 | | | | | | 25 | |
| liquid R20 | | | | | | | | | | | |
| Dispersion | 10 | 4.5 | | 0.5 | | | | | | | 25 |
| liquid R21 | | | | | | | | | | | |
| Dispersion | 10 | 4.5 | | 0.5 | | | | | | | |
| liquid R22 | | | | | | | | | | | |
| Dispersion | 10 | 4.5 | | 0.5 | | | | | | | |
| liquid R23 | | | | | | | | | | | |
| Dispersion | 10 | 4.5 | | 0.5 | 20 | | | | | | |
| liquid R24 | | | | | | | | | | | |
| Dispersion | 10 | 4.5 | | 0.5 | | 20 | | | | | |
| liquid R25 | | | | | | | | | | | |
| Dispersion | 10 | 4.5 | | 0.5 | | | 20 | | | | |
| liquid R26 | | | | | | | | | | | |
| Dispersion | 10 | 4.5 | | 0.5 | | | | | 20 | | |
| liquid R27 | | | | | | | | | | | |
| Dispersion | 10 | 4.5 | | 0.5 | | | | | 20 | | |
| liquid R28 | | | | | | | | | | | |
| Dispersion | 10 | 4.5 | | 0.5 | | | | | 20 | | |
| liquid R29 | | | | | | | | | | | |
| Dispersion | 10 | 4.5 | | | | | | | 20 | | |
| liquid R30 | | | | | | | | | | | |
| Comparative | 10 | | 4.5 | 0.5 | | | | | 20 | | |
| dispersion | | | | | | | | | | | |
| liquid R3 | | | | | | | | | | | |
| | | | | | | | | Concentration | Concentration | Performance of | |
| | | Resin | | | | | Sol- | of coloring | of solid | dispersion liquid | |
| | Dispersion | B- | B- | C- | C- | C- | vent | material | contents | Temporal | Color |
| | liquid | 6 | 7 | 1 | 2 | 3 | K-1 | (% by mass) | (% by mass) | stability | unevenness |
| | Dispersion | | | | | | 60 | 14.5 | 20 | B | B |
| | liquid R15 | | | | | | | | | | |
| | Dispersion | | | | | | 60 | 14.5 | 20 | B | B |
| | liquid R16 | | | | | | | | | | |
| | Dispersion | | | | | | 60 | 14.5 | 20 | A | B |
| | liquid R17 | | | | | | | | | | |
| | Dispersion | | | | | | 60 | 14.5 | 20 | A | B |
| | liquid R18 | | | | | | | | | | |
| | Dispersion | | | | | | 60 | 14.5 | 20 | A | B |
| | liquid R19 | | | | | | | | | | |
| | Dispersion | | | | | | 60 | 14.5 | 20 | A | B |
| | liquid R20 | | | | | | | | | | |
| | Dispersion | | | | | | 60 | 14.5 | 20 | A | B |
| | liquid R21 | | | | | | | | | | |
| | Dispersion | 25 | | | | | 60 | 14.5 | 20 | A | B |
| | liquid R22 | | | | | | | | | | |
| | Dispersion | | 25 | | | | 60 | 14.5 | 20 | A | B |
| | liquid R23 | | | | | | | | | | |
| | Dispersion | | | 5 | | | 60 | 14.5 | 20 | B | A |
| | liquid R24 | | | | | | | | | | |
| | Dispersion | | | 5 | | | 60 | 14.5 | 20 | B | A |
| | liquid R25 | | | | | | | | | | |
| | Dispersion | | | 5 | | | 60 | 14.5 | 20 | B | A |
| | liquid R26 | | | | | | | | | | |
| | Dispersion | | | 5 | | | 60 | 14.5 | 20 | A | A |
| | liquid R27 | | | | | | | | | | |
| | Dispersion | | | | 5 | | 60 | 14.5 | 20 | A | A |
| | liquid R28 | | | | | | | | | | |
| | Dispersion | | | | | 5 | 60 | 14.5 | 20 | A | A |
| | liquid R29 | | | | | | | | | | |
| | Dispersion | | | 7.5 | | | 58 | 14.5 | 20 | A | A |
| | liquid R30 | | | | | | | | | | |
| | Comparative | | | 5 | | | 60 | 14.5 | 20 | D | D |
| | dispersion | | | | | | | | | | |
| | liquid R3 | | | | | | | | | | |

TABLE 7

| | | | | | | | | | | Concentration | Concentration | Performance of | |
|---|---|---|---|---|---|---|---|---|---|---|---|---|---|
| | | | | | | | Pigment | | Sol- | of coloring | of solid | dispersion liquid | |
| | Coloring material | | | | | | derivative | Resin | vent | material | contents | Temporal | Color |
| Dispersion liquid | PR254 | PT1 | PT2 | PT3 | PT4 | PT5 | Derivative 1 | B-3 | K-1 | (% by mass) | (% by mass) | stability | unevenness |
| Dispersion liquid | 10 | 4.5 | | | | | 0.5 | 25 | 60 | 14.5 | 20 | A | B |
| R31 | | | | | | | | | | | | | |
| Dispersion liquid | 10 | | 4.5 | | | | 0.5 | 25 | 60 | 14.5 | 20 | A | B |
| R32 | | | | | | | | | | | | | |
| Dispersion liquid | 10 | | | 4.5 | | | 0.5 | 25 | 60 | 14.5 | 20 | A | B |
| R33 | | | | | | | | | | | | | |
| Dispersion liquid | 10 | | | | 4.5 | | 0.5 | 25 | 60 | 14.5 | 20 | A | B |
| R34 | | | | | | | | | | | | | |
| Dispersion liquid | 10 | | | | | 4.5 | 0.5 | 25 | 60 | 14.5 | 20 | A | B |
| R35 | | | | | | | | | | | | | |

TABLE 8

| | | | | | Pigment | | | | | | Concentration | Concentration | Performance of | |
|---|---|---|---|---|---|---|---|---|---|---|---|---|---|---|
| | | | | | derivative | | | | | | of coloring | of solid | dispersion liquid | |
| | Coloring material | | | | Derviative | Resin | | | | Solvent | material | contents | Temporal | Color |
| Dispersion liquid | PR254 | BR1 | BR2 | PT1 | 3 | B-3 | B-8 | B-9 | C-3 | K-1 | (% by mass) | (% by mass) | stability | unevenness |
| Dispersion liquid | 10 | | | 4.5 | 0.5 | | 25 | | | 60 | 14.5 | 20 | A | B |
| R36 | | | | | | | | | | | | | | |
| Dispersion liquid | 10 | | | 4.5 | 0.5 | | | 25 | | 60 | 14.5 | 20 | A | B |
| R37 | | | | | | | | | | | | | | |
| Dispersion liquid | 10 | | | 4.5 | 0.5 | | 20 | | 5 | 60 | 14.5 | 20 | A | A |
| R38 | | | | | | | | | | | | | | |
| Dispersion liquid | | 10 | | 4.5 | 0.5 | 25 | | | | 60 | 14.5 | 20 | A | B |
| R39 | | | | | | | | | | | | | | |
| Dispersion liquid | | | 10 | 4.5 | 0.5 | 25 | | | | 60 | 14.5 | 20 | A | B |
| R40 | | | | | | | | | | | | | | |

TABLE 9

| | | | | | | | | | | Con- | Con- | | |
|---|---|---|---|---|---|---|---|---|---|---|---|---|---|
| | | | | | | | | | | centration | centration | Performance of | |
| | Coloring material | | | | | | Pigment | | | of solid | of solid | dispersion liquid | |
| Dispersion | | | | | | Yellow | derivative | Resin | Solvent | material | contents | Temporal | Color |
| liquid | PT1 | PT5 | PY150 | PY185 | PY129 | 1 | Derivative 1 | B-3 | K-1 | (% by mass) | (% by mass) | stability | uneveness |
| Dispersion | 14.5 | | | | | | 0.5 | 25 | 60 | 14.5 | 20 | A | B |
| liquid Y1 | | | | | | | | | | | | | |
| Dispersion | | 14.5 | | | | | 0.5 | 25 | 60 | 14.5 | 20 | A | B |
| liquid Y2 | | | | | | | | | | | | | |
| Dispersion | 10 | 4.5 | | | | | 0.5 | 25 | 60 | 14.5 | 20 | A | B |
| liquid Y3 | | | | | | | | | | | | | |
| Dispersion | 10 | | 4.5 | | | | 0.5 | 25 | 60 | 14.5 | 20 | A | B |
| liquid Y4 | | | | | | | | | | | | | |
| Dispersion | 10 | | | 4.5 | | | 0.5 | 25 | 60 | 14.5 | 20 | A | B |
| liquid Y5 | | | | | | | | | | | | | |
| Dispersion | 10 | | | | 4.5 | | 0.5 | 25 | 60 | 14.5 | 20 | A | B |
| liquid Y6 | | | | | | | | | | | | | |
| Dispersion | 10 | | | | | 4.5 | 0.5 | 25 | 60 | 14.5 | 20 | A | B |
| liquid Y7 | | | | | | | | | | | | | |

TABLE 10

| | | Pig- | | | | | | | | | | | | | | Con- | Con- | | |
|---|---|---|---|---|---|---|---|---|---|---|---|---|---|---|---|---|---|---|---|
| | | ment | | | | | | | | | | | | | | centration | centration | Performance of | |
| | Color- | deriv- | | | | | | | | | | | | | | of coloring | of solid | dispersion liquid | |
| | ing | ative | | | | | | | | | | | | | Sol- | material | contents | | Color |
| Dispersion | material | Deriv- | Resin | | | | | | | | | | | | vent | (% by | (% by | Temporal | uneven- |
| liquid | PT1 | ative 1 | A-1 | A-2 | B-1 | B-2 | B-3 | B-4 | B-5 | B-6 | B-7 | C-1 | C-2 | C-3 | K-1 | mass) | mass) | stability | ness |
| Dispersion | 14.5 | 0.5 | 25 | | | | | | | | | | | | 60 | 14.5 | 20 | B | B |
| liquid Y8 | | | | | | | | | | | | | | | | | | | |
| Dispersion | 14.5 | 0.5 | | 25 | | | | | | | | | | | 60 | 14.5 | 20 | B | B |
| liquid Y9 | | | | | | | | | | | | | | | | | | | |
| Dispersion | 14.5 | 0.5 | | | 25 | | | | | | | | | | 60 | 14.5 | 20 | A | B |
| liquid Y10 | | | | | | | | | | | | | | | | | | | |
| Dispersion | 14.5 | 0.5 | | | | 25 | | | | | | | | | 60 | 14.5 | 20 | A | B |
| liquid Y11 | | | | | | | | | | | | | | | | | | | |
| Dispersion | 14.5 | 0.5 | | | | | 25 | | | | | | | | 60 | 14.5 | 20 | A | B |
| liquid Y12 | | | | | | | | | | | | | | | | | | | |
| Dispersion | 14.5 | 0.5 | | | | | | 25 | | | | | | | 60 | 14.5 | 20 | A | B |
| liquid Y13 | | | | | | | | | | | | | | | | | | | |
| Dispersion | 14.5 | 0.5 | | | | | | | 25 | | | | | | 60 | 14.5 | 20 | A | B |
| liquid Y14 | | | | | | | | | | | | | | | | | | | |
| Dispersion | 14.5 | 0.5 | | | | | | | | 25 | | | | | 60 | 14.5 | 20 | A | B |
| liquid Y15 | | | | | | | | | | | | | | | | | | | |
| Dispersion | 14.5 | 0.5 | | | | | | | | | 25 | | | | 60 | 14.5 | 20 | A | B |
| liquid Y16 | | | | | | | | | | | | | | | | | | | |
| Dispersion | 14.5 | 0.5 | 20 | | | | | | | | | 5 | | | 60 | 14.5 | 20 | B | A |
| liquid Y17 | | | | | | | | | | | | | | | | | | | |
| Dispersion | 14.5 | 0.5 | | 20 | | | | | | | | 5 | | | 60 | 14.5 | 20 | B | A |
| liquid Y18 | | | | | | | | | | | | | | | | | | | |
| Dispersion | 14.5 | 0.5 | | | 20 | | | | | | | 5 | | | 60 | 14.5 | 20 | B | A |
| liquid Y19 | | | | | | | | | | | | | | | | | | | |
| Dispersion | 14.5 | 0.5 | | | | | 20 | | | | | 5 | | | 60 | 14.5 | 20 | A | A |
| liquid Y20 | | | | | | | | | | | | | | | | | | | |
| Dispersion | 14.5 | 0.5 | | | | | 20 | | | | | | 5 | | 60 | 14.5 | 20 | A | A |
| liquid Y21 | | | | | | | | | | | | | | | | | | | |
| Dispersion | 14.5 | 0.5 | | | | | 20 | | | | | | | 5 | 60 | 14.5 | 20 | A | A |
| liquid Y22 | | | | | | | | | | | | | | | | | | | |
| Dispersion | 14.5 | | | | | | 20 | | | | | 7.5 | | | 58 | 14.5 | 20 | A | A |
| liquid Y23 | | | | | | | | | | | | | | | | | | | |

TABLE 11

| | | | | | | | | | Con- | Con- | | |
|---|---|---|---|---|---|---|---|---|---|---|---|---|
| | | | | | | | | | centration | centration | Performance of | |
| | | | | | | Pigment | | | of coloring | of solid | dispersion liquid | |
| | Coloring material | | | | | derivative | Resin | Solvent | material | contents | Temporal | Color |
| Dispersion liquid | PT1 | PR254 | PB15:6 | PV23 | IR1 | Derivative 1 | B-3 | K-1 | (% by mass) | (% by mass) | stability | unevenness |
| Dispersion liquid IR1 | 3 | 4.5 | 4.5 | 2.5 | | 0.5 | 25 | 60 | 14.5 | 20 | A | B |
| Dispersion liquid IR2 | 3 | 4.5 | 4.5 | | 2.5 | 0.5 | 25 | 60 | 14.5 | 20 | A | B |
| Dispersion liquid IR3 | 6 | | | 8.5 | | 0.5 | 25 | 60 | 14.5 | 20 | A | B |

The raw materials described by abbreviations shown in the above tables are as follows.

(Coloring material)

PG36: C. I. Pigment Green 36 (green coloring material, phthalocyanine compound)

PG58: C. I. Pigment Green 58 (green coloring material, phthalocyanine compound)

PG62: C. I. Pigment Green 62 (green coloring material, phthalocyanine compound)

SQ1: compound having the following structure (green coloring material, squarylium compound)

[symbol]

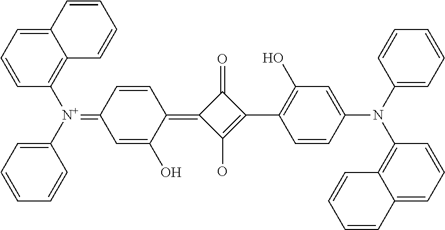 [SMILES: O=C1C(c2ccc(N(c3ccccc3)c3cccc4ccccc34)cc2O)=C(O)/C1=C1C=C/C(=[N+](/c2ccccc2)c2cccc3ccccc23)C=C/1O]

AP1: compound having the following structure (green coloring material, phthalocyanine compound)

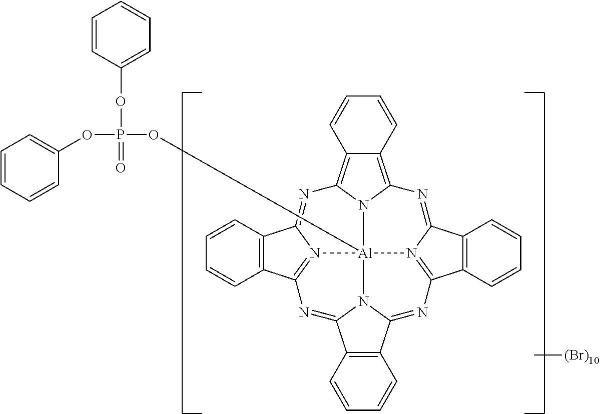

[symbol]

AP2: compound having the following structure (green coloring material, phthalocyanine compound)

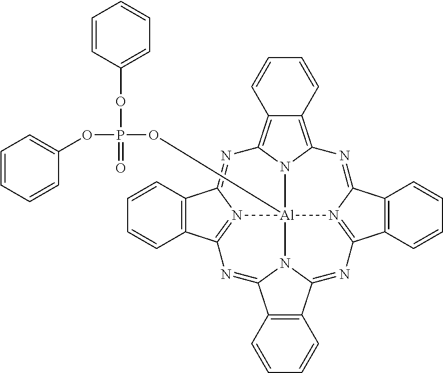

PT1: C. I. Pigment Yellow 215 (yellow coloring material, pteridin pigment)

PT2: compound having the following structure (yellow coloring material, pteridin pigment; synthesized according to Example 1 of JP4808884B)

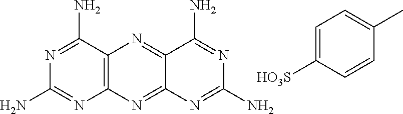

PT3: compound having the following structure (yellow coloring material, pteridin pigment; synthesized according to Example 4 of JP4808884B)

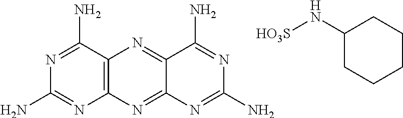 [SMILES: Nc1nc(N)c2nc3c(N)nc(N)nc3nc2n1 ; O=S(=O)(O)NC1CCCCC1]

PT4: compound having the following structure (yellow coloring material, pteridin pigment; synthesized according to Example 8 of JP4808884B)

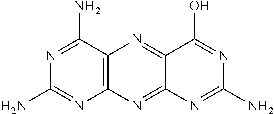 [SMILES: Nc1nc(N)c2nc3c(O)nc(N)nc3nc2n1]

PT5: compound having the following structure (yellow coloring material, pteridin pigment; synthesized according to Example 7 of JP4808884B)

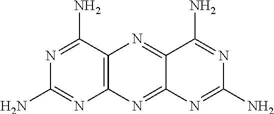 [SMILES: Nc1nc(N)c2nc3c(N)nc(N)nc3nc2n1]

PY129: C. I. Pigment Yellow 129 (yellow coloring material, azo compound)

PY138: C. I. Pigment Yellow 138 (yellow coloring material, quinophthalone compound)

PY139: C. I. Pigment Yellow 139 (yellow coloring material, isoindoline compound)

PY150: C. I. Pigment Yellow 150 (yellow coloring material, azo compound)

PY185: C. I. Pigment Yellow 185 (yellow coloring material, isoindoline compound)

SY82: C. I. Solvent Yellow 82 (yellow coloring material, azo compound)

Yellow1: compound having the following structure (yellow coloring material, quinophthalone compound)

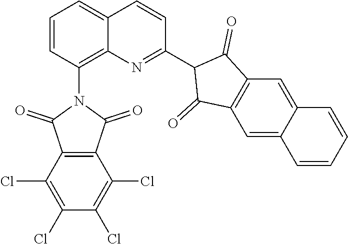 [SMILES: O=C1c2cc3ccccc3cc2C(=O)C1c1ccc2cccc(N3C(=O)c4c(Cl)c(Cl)c(Cl)c(Cl)c4C3=O)c2n1]

PO71: C. I. Pigment Orange 71 (orange coloring material, diketopyrrolopyrrole compound)

PR177: C. I. Pigment Red 177 (red coloring material, anthraquinone compound)

PR254: C. I. Pigment Red 254 (red coloring material, diketopyrrolopyrrole compound)

PR264: C. I. Pigment Red 264 (red coloring material, diketopyrrolopyrrole compound)

PR269: C. I. Pigment Red 269 (red coloring material, azo compound)

PR272: C. I. Pigment Red 272 (red coloring material, diketopyrrolopyrrole compound)

BR1: compound having the following structure

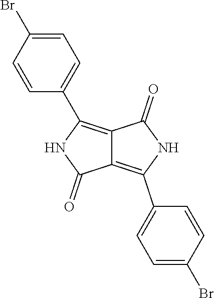 [SMILES: O=C1NC(c2ccc(Br)cc2)=C2C(=O)NC(c3ccc(Br)cc3)=C12]

BR2: mixture of a compound having the following structure (compound on the left: compound on the right=9:1 (mass ratio))

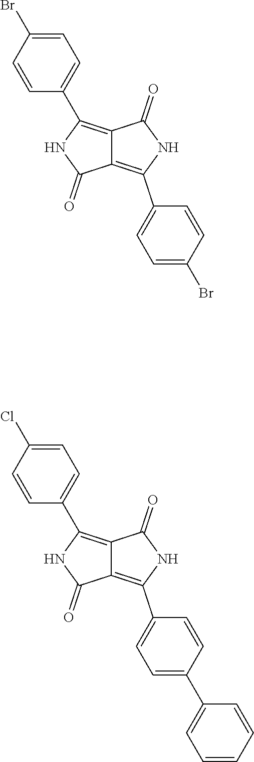 [SMILES: O=C1NC(c2ccc(Br)cc2)=C2C(=O)NC(c3ccc(Br)cc3)=C12 ; O=C1NC(c2ccc(-c3ccccc3)cc2)=C2C(=O)NC(c3ccc(Cl)cc3)=C12]

PB15:6: C. I. Pigment Blue 15:6 (blue coloring material, phthalocyanine compound)

PV23: C. I. Pigment Violet 23 (violet coloring material, dioxazine compound)

IR1: compound having the following structural formula (infrared absorbing coloring material; in the following structural formula, Me represents a methyl group and Ph represents a phenyl group; pyrrolopyrrole compound)

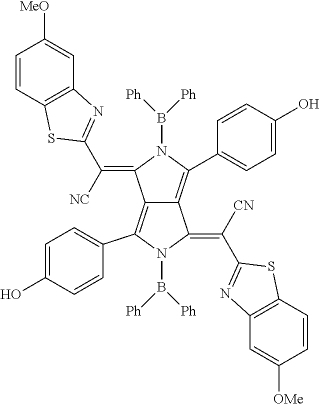 [SMILES: COc1ccc2sc(/C(C#N)=c3/c4c(-c5ccc(O)cc5)n(B(c5ccccc5)c5ccccc5)/c(=C(/C#N)c5nc6cc(OC)ccc6s5)c4c(-c4ccc(O)cc4)n3B(c3ccccc3)c3ccccc3)nc2c1]

(Pigment Derivative)

Derivative 1: compound having the following structure

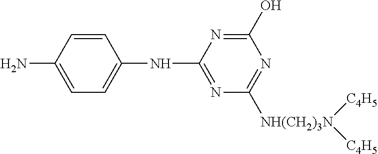

Derivative 2: compound having the following structure

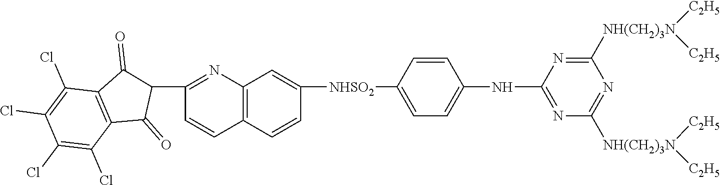

Derivative 3: compound having the following structure

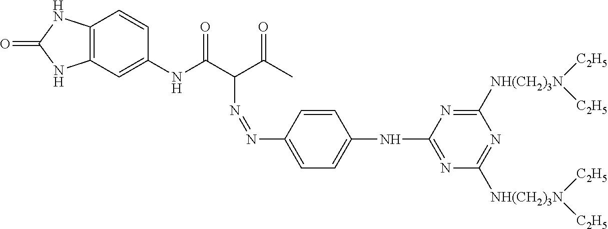

Derivative 4: compound having the following structure

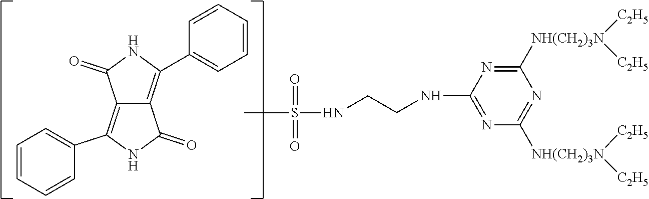

Derivative 5: compound having the following structure

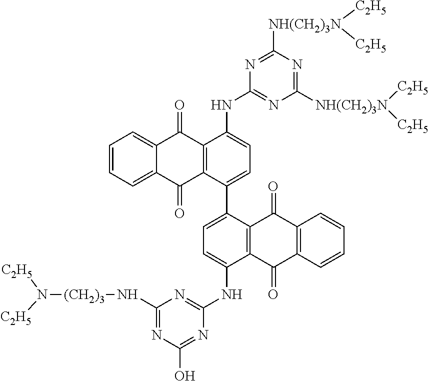

Derivative 6: compound having the following structure

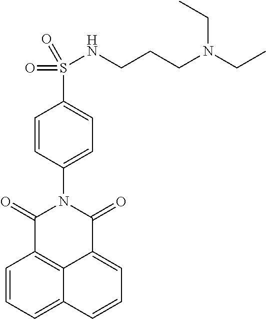 [SMILES: CCN(CC)CCCNS(=O)(=O)c1ccc(N2C(=O)c3cccc4cccc(c34)C2=O)cc1]

<Resin>

A-1: 20% by mass propylene glycol monomethyl ether acetate (PGMEA) solution of a resin having the following structure (the numerical value described together with the main chain indicates a molar ratio, and the numerical value described together with the side chain indicates the number of repeating units; Mw=24000, acid value: 47 mgKOH/g)

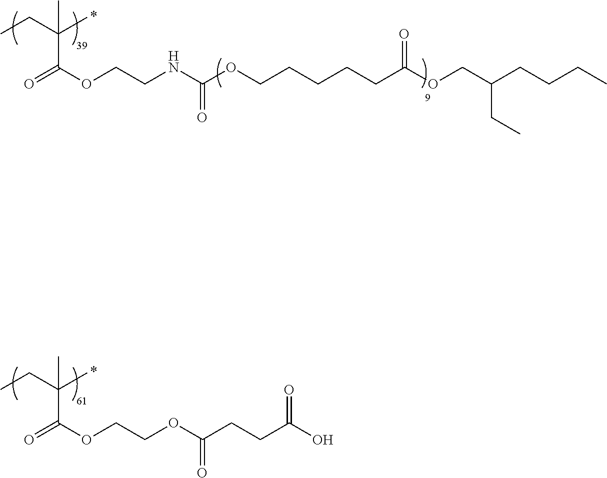

A-2: 20% by mass PGMEA solution of a resin having the following structure (the numerical value described together with the main chain indicates a molar ratio, and the numerical value described together with the side chain indicates the number of repeating units; Mw=16000, acid value: 67 mgKOH/g)

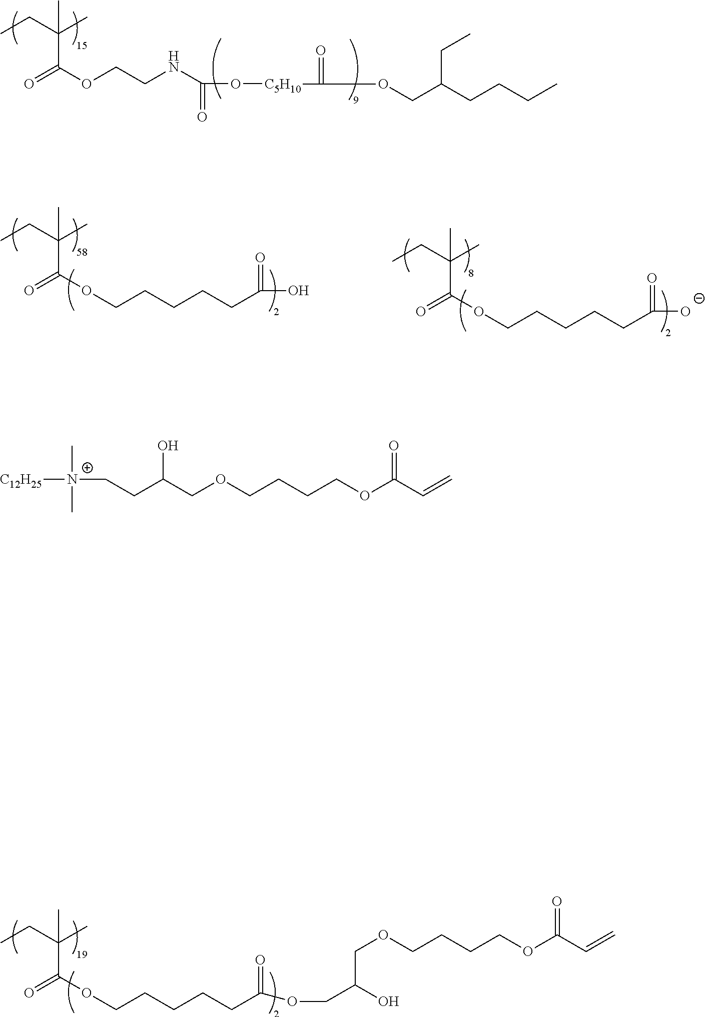

A-3: 20% by mass PGMEA solution of a resin having the following structure (the numerical value described together with the main chain indicates a molar ratio; Mw=11000, acid value: 69 mgKOH/g)

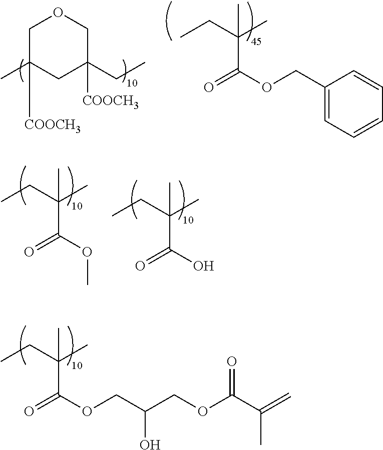

B-1: resin solution of a resin B-1 synthesized by the following method (concentration of solid contents: 20% by mass)

50 parts by mass of methyl methacrylate, 50 parts by mass of n-butyl methacrylate, and 45.4 parts by mass of propylene glycol monomethyl ether acetate (PGMEA) were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 20% by mass, thereby obtaining a resin solution of a resin B-1 having an acid value of 43 mgKOH/g and a weight-average molecular weight (Mw) of 9000.

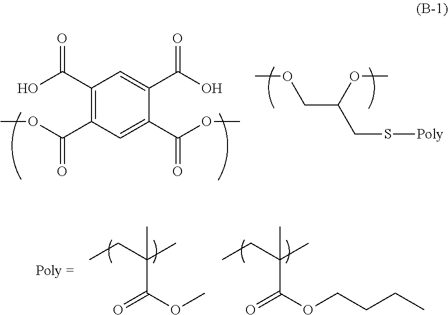

B-2: resin solution of a resin B-2 synthesized by the following method (concentration of solid contents: 20% by mass)

50 parts by mass of methyl methacrylate, 30 parts by mass of n-butyl methacrylate, 20 parts by mass of t-butyl methacrylate, and 45.4 parts by mass of PGMEA were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 20% by mass, thereby obtaining a resin solution of a resin B-2 having an acid value of 43 mgKOH/g and a weight-average molecular weight (Mw) of 9000.

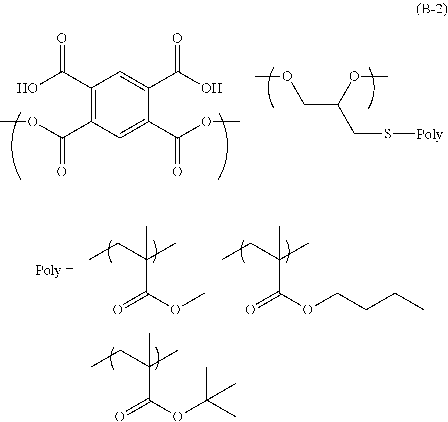

B-3: resin solution of a resin B-3 synthesized by the following method (concentration of solid contents: 20% by mass)

A resin solution of a resin B-3 having an acid value of 43 mgKOH/g and a weight-average molecular weight (Mw) of 9,000 was obtained in the same manner as in the synthesis of the resin B-2, except that 20 parts by mass of t-butyl methacrylate was changed to (3-ethyloxetan-3-yl)methyl methacrylate.

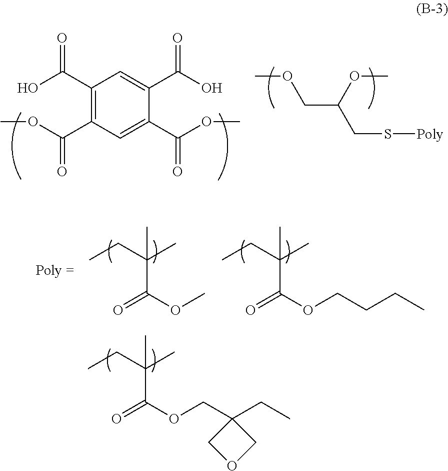

B-4: resin solution of a resin B-4 synthesized by the following method (concentration of solid contents: 20% by mass)

A resin solution of a resin B-4 having an acid value of 43 mgKOH/g and a weight-average molecular weight (Mw) of 9000 was obtained in the same manner as in the synthesis of the resin B-2, except that 20 parts by mass of t-butyl methacrylate was changed to 20 parts by mass of “Karenz MOI-BM” manufactured by SHOWA DENKO K.K.

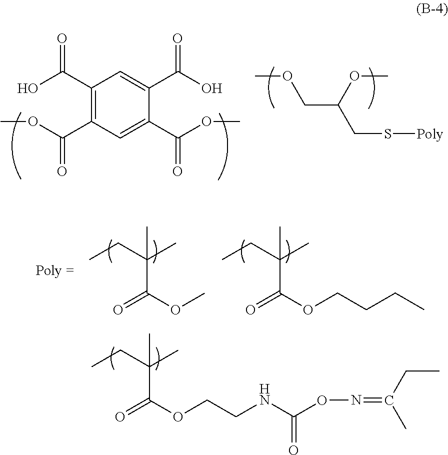

B-5: resin solution of a resin B-5 synthesized by the following method (concentration of solid contents: 20% by mass)

6.0 parts by mass of 3-mercapto-1,2-propanediol, 9.5 parts by mass of pyromellitic acid anhydride, 62 parts by mass of PGMEA, and 0.2 parts by mass of 1,8-diazabicyclo-[5.4.0]-7-undecene were charged into a reaction container, and the atmosphere gas was replaced with nitrogen gas. The inside of the reaction container was heated to 100° C., and the mixture was reacted for 7 hours. After confirming by acid value measurement that 98% or more of the acid anhydride was half-esterified, the temperature in the system was lowered to 70° C., 53.5 parts by mass of PGMEA solution in which 65 parts by mass of methyl methacrylate, 5.0 parts by mass of ethyl acrylate, 15 parts by mass of t-butyl acrylate, 5.0 parts by mass of methacrylic acid, 10 parts by mass of hydroxyethyl methacrylate, and 0.1 parts by mass of 2,2′-azobisisobutyronitrile were dissolved was added thereto, and the mixture was reacted for 10 hours. It was confirmed by solid content measurement that the polymerization had proceeded by 95%, and the reaction was terminated. PGMEA was added thereto to adjust non-volatile content (concentration of solid contents) to be 20% by mass, thereby obtaining a resin solution of a resin B-5 having an acid value of 70.5 mgKOH/g and a weight-average molecular weight (Mw) of 10000.

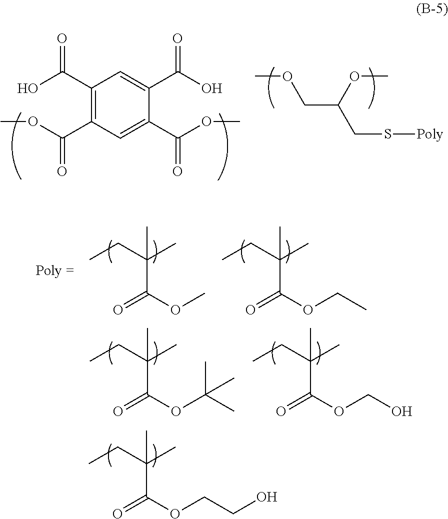

B-6: resin solution of a resin B-6 synthesized by the following method (concentration of solid contents: 20% by mass)

108 parts by mass of 1-thioglycerol, 174 parts by mass of pyromellitic acid anhydride, 650 parts by mass of methoxypropyl acetate, and 0.2 parts by mass of monobutyltin oxide as a catalyst were charged into a reaction container, the atmosphere gas was replaced with nitrogen gas, and the mixture was reacted at 120° C. for 5 hours (first step). It was confirmed by acid value measurement that 95% or more of the acid anhydride was half-esterified. Next, 160 parts by mass of the compound obtained in the first step expressed in terms of solid contents, 200 parts by mass of 2-hydroxypropyl methacrylate, 200 parts by mass of ethyl acrylate, 150 parts by mass of t-butyl acrylate, 200 parts by mass of 2-methoxyethyl acrylate, 200 parts by mass of methyl acrylate, 50 parts by mass of methacrylic acid, and 663 parts by mass of PGMEA were charged to a reaction container, the inside of the reaction container was heated to 80° C., 1.2 parts by mass of 2,2′-azobis(2,4-dimethylvaleronitrile) was added thereto, and the mixture was reacted for 12 hours (second step). It was confirmed by solid content measurement that 95% thereof was reacted. Finally, 500 parts by mass of PGMEA solution of 50% by mass of the compound obtained in the second step, 27.0 parts by mass of 2-methacryloyloxyethyl isocyanate (MOI), 0.1 parts by mass of hydroquinone were charged to a reaction container, the reaction was performed until the disappearance of the peak of 2270 cm⁻¹ based on the isocyanate group was confirmed (third step). After confirming the disappearance of the peak, the reaction solution was cooled, and PGMEA was added thereto to adjust non-volatile content (concentration of solid contents) to be 20 mass %, thereby obtaining a resin solution of a resin B-6 having an acid value of 68 mgKOH/g, an unsaturated double bond value of 0.62 mmol/g, and a weight-average molecular weight (Mw) of 13000.

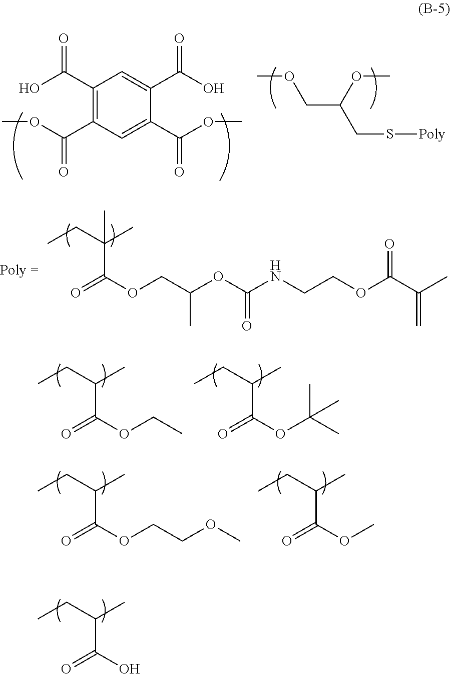

B-7: resin solution of a resin B-7 synthesized by the following method (concentration of solid contents: 20% by mass)

40 parts by mass of methyl methacrylate, 60 parts by mass of n-butyl methacrylate, and 45.4 parts by mass of propylene glycol monomethyl ether acetate (PGMEA) were charged into a reaction container, and the atmosphere gas was replaced with nitrogen gas. The inside of the reaction container was heated to 70° C., 8 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 13 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 20% by mass, thereby obtaining a resin solution of a resin B-7 having an acid value of 55 mgKOH/g and a weight-average molecular weight (Mw) of 10000.

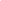

B-8: resin solution of a resin B-8 synthesized by the following method (concentration of solid contents: 20% by mass)

300 g of propylene glycol monomethyl ether acetate (PGMEA) was charged into a three-neck flask, and heated to 60° C. under a nitrogen atmosphere. 380 g of (3-ethyloxetan-3-yl)methyl acrylate (manufactured by OSAKA ORGANIC CHEMICAL INDUSTRY LTD., OXE-10), 18.3 g of 6-mercaptohexanol (manufactured by TOKYO CHEMICAL INDUSTRY CO., LTD.), 2.4 g of dimethyl 2,2′-azobisisobutyrate (manufactured by FUJIFILM Wako Pure Chemical Corporation, V-601), and 300 g of PGMEA solution were added dropwise thereto over 2 hours. Thereafter, 2.4 g of dimethyl 2,2′-azobisisobutyrate was added thereto, and the mixture was heated for another 4 hours to synthesize a macromonomer precursor. After cooling this macromonomer precursor solution to 5° C., 0.4 g of dibutylhydroxytoluene (BHT) and 0.16 g of NEOSTANN U-600 (manufactured by Nitto Kasei Co., Ltd.) were added thereto, and then 22.1 g of 2-isocyanatoethyl methacrylate (manufactured by SHOWA DENKO K.K., Karenz MOI) was added dropwise thereto over 30 minutes. The mixture was further stiffed at 5° C. for 1 hour, returned to room temperature, and further stirred for 6 hours to obtain a 40% PGMEA solution of a macromonomer AA-1 having the following structure. The weight-average molecular weight (Mw) of the obtained macromonomer AA-1 was 2800.

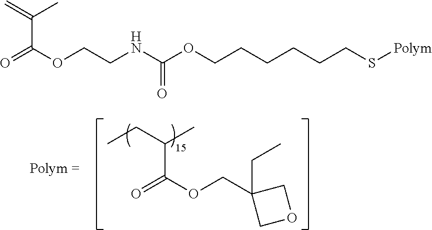

7.0 g of acrylic acid (manufactured by FUJIFILM Wako Pure Chemical Corporation) and 170 g of the 40% PGMEA solution of the macromonomer AA-1 obtained above were charged into a three-neck flask, 70 g of PGMEA was further added thereto, and the mixture was heated to 80° C. under a nitrogen atmosphere. 1.2 g of dodecanethiol (manufactured by FUJIFILM Wako Pure Chemical Corporation) and 0.35 g of dimethyl 2,2′-azobisisobutyrate were added thereto, and the mixture was heated for 6 hours. Thereafter, PGMEA was added thereto to adjust non-volatile content (concentration of solid contents) to be 20% by mass, thereby obtaining a resin solution of a resin B-8 having the following structure. The weight-average molecular weight of the resin B-8 was 30623, and the acid value was 70 mgKOH/g. In the following formula, the numerical value described together with the main chain of the repeating unit indicates mol %, and the description of “Polym” indicates that the polymer chain of the structure in which the repeating unit of the structure indicated by “Polym” is bonded by the number of subscripts is bonded to the sulfur atom (S).

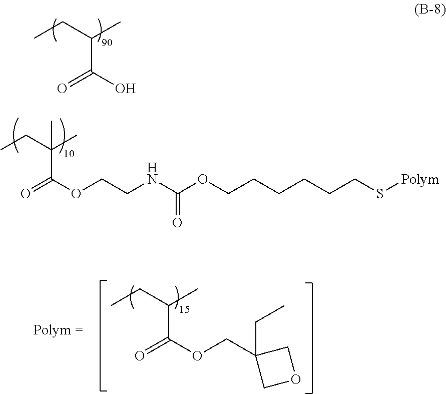

B-9: resin solution of a resin B-9 synthesized by the following method (concentration of solid contents: 20% by mass)

A resin B-9 was synthesized by the same method as for the resin B-8. In the following formula, the numerical value described together with the main chain of the repeating unit indicates mol %, and the description of “Polym” indicates that the polymer chain of the structure in which the repeating unit of the structure indicated by “Polym” is bonded by the number of subscripts is bonded to the sulfur atom (S).

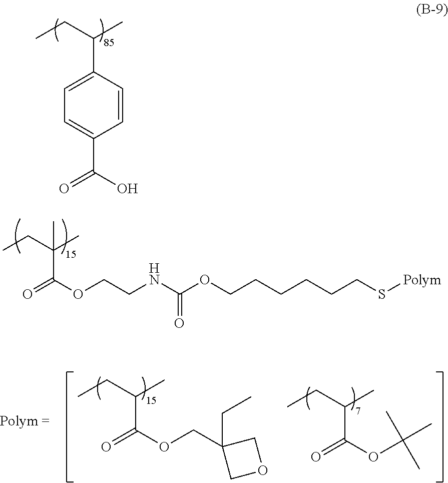

B-10: 20% by mass PGMEA solution of a resin having the following structure (graft resin having an acid group; the numerical value described together with the main chain indicates a mass ratio, and the numerical value described together with the side chain indicates the number of repeating units; weight-average molecular weight: 13000, acid value: 19 mgKOH/g)

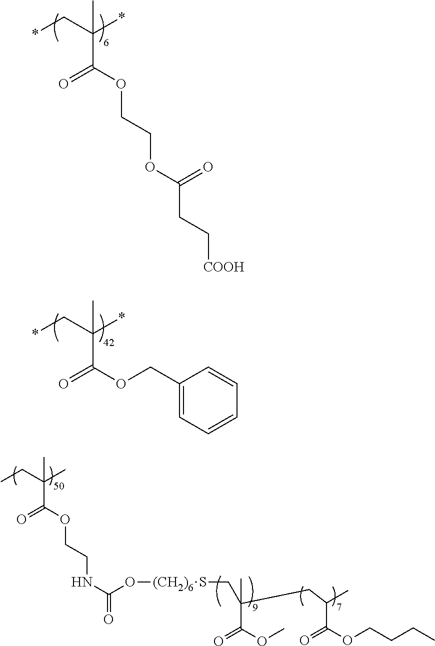

C-1: PGMEA solution of DISPERBYK-2001 (resin having a basic group, amine value: 29 mgKOH/g, manufactured by BYK Chemie Japan) having a concentration of solid contents of 20% by mass

C-2: 20% by mass PGMEA solution of a resin having the following structure (block copolymer; the numerical value described together with the main chain is a mass ratio; amine value: 71 mgKOH/g, Mw=9900)

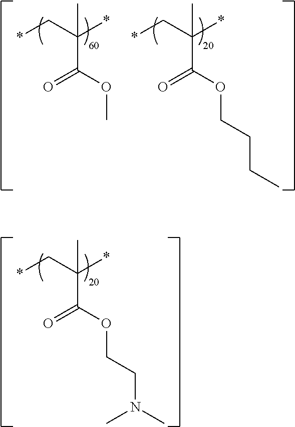

C-3: 20% by mass PGMEA solution of a resin having the following structure (block copolymer; the numerical value described together with the main chain is a mass ratio; amine value: 80 mgKOH/g, Mw=8500)

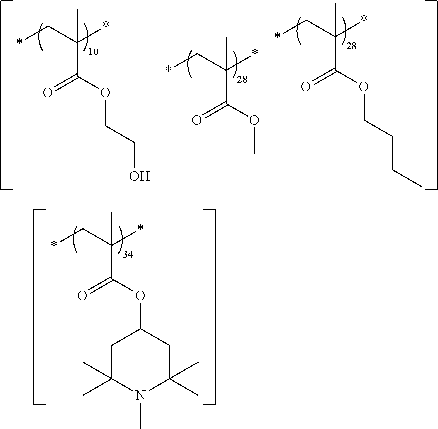

(Solvent)

K-1: propylene glycol monomethyl ether acetate (PGMEA)

<Performance Evaluation of Dispersion Liquid>

(Temporal Stability)

A viscosity (mPa·s) of each dispersion liquid immediately after production was measured with “RE-85L” manufactured by TOKI SANGYO CO., LTD. After the above-described measurement, each dispersion liquid was allowed to stand at 45° C. under the conditions of light shielding for 3 days, and the viscosity (mPa·s) was measured again.

Storage stability was evaluated according to the following evaluation standard from a viscosity difference (ΔVis) before and after leaving to stand. The evaluation results are described in the column of “Temporal stability” in the above tables. It can be said that, as the numerical value of the viscosity difference (ΔVis) is smaller, the temporal stability of the dispersion liquid is better. In each of the above-described viscosity measurements, the temperature and humidity were controlled to 22±5° C. and 60±20% in a laboratory, and the temperature of the dispersion liquid was adjusted to 25° C.

—Evaluation Standard—

A: ΔVis was 0.5 mPa·s or less.

B: ΔVis was more than 0.5 mPa·s and 1.0 mPa·s or less.

C: ΔVis was more than 1.0 mPa·s and 2.0 mPa·s or less.

D: ΔVis was more than 2.0 mPa·s.

(Color Unevenness)

Each dispersion liquid immediately after production was applied to a silicon wafer using a spin coater (H-3605, manufactured by Mikasa Co., Ltd.) such that a film thickness after pre-baking was 1.0 μm. Next, the dispersion liquid was pre-baked at 100° C. for 120 seconds to form a film. Foreign matters included in the film were detected by a foreign matter evaluation device ComPLUS III (manufactured by Applied Materials, Inc.), foreign matters (coarse particle) having a maximum width of 1.0 μm or more were visually classified from all the detected foreign matters, and then the number of foreign matters (number per 1 cm²) was counted. As the number of foreign matters is smaller, the color unevenness is smaller.

A: number of foreign matters was less than 10 pieces/1 cm².

B: number of foreign matters was 10 pieces/1 cm² or more and less than 30 pieces/1

C: number of foreign matters was 30 pieces/1 cm² or more and less than 100 pieces/1

D: number of foreign matters was 100 pieces/1 cm² or more.

<Production of Coloring Composition>

Raw materials described in the following tables were mixed to prepare a coloring composition.

TABLE 12

| | | | | | | | Photo- | | | | | | | | | | Con- |
|---|---|---|---|---|---|---|---|---|---|---|---|---|---|---|---|---|---|
| | | | | | Poly- | | polymer- | | | | | | Polymer- | | | | centration |
| | Dispersion | | | | merizable | | ization | | | | | | ization | | | | of |
| | liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% by |
| | Type | mass | Type | mass | Type | mass | Type | mass | Type | mass | Type | mass | Type | mass | Type | mass | mass) |
| Example G1 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G1 | | | | | | | | | | | | | | | | |
| Example G2 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G2 | | | | | | | | | | | | | | | | |
| Example G3 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G3 | | | | | | | | | | | | | | | | |
| Example G4 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G4 | | | | | | | | | | | | | | | | |
| Example G5 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G5 | | | | | | | | | | | | | | | | |
| Example G6 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G6 | | | | | | | | | | | | | | | | |
| Example G7 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G7 | | | | | | | | | | | | | | | | |
| Example G8 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G8 | | | | | | | | | | | | | | | | |
| Example G9 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G9 | | | | | | | | | | | | | | | | |
| Example G10 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G10 | | | | | | | | | | | | | | | | |
| Example G11 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G11 | | | | | | | | | | | | | | | | |
| Example G12 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G12 | | | | | | | | | | | | | | | | |
| Example G13 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G13 | | | | | | | | | | | | | | | | |
| Example G14 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G14 | | | | | | | | | | | | | | | | |
| Example G15 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G15 | | | | | | | | | | | | | | | | |
| Example G16 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G16 | | | | | | | | | | | | | | | | |
| Example G17 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G17 | | | | | | | | | | | | | | | | |
| Example G18 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G18 | | | | | | | | | | | | | | | | |
| Example G19 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G19 | | | | | | | | | | | | | | | | |
| Example G20 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G20 | | | | | | | | | | | | | | | | |
| Example G21 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G21 | | | | | | | | | | | | | | | | |
| Example G22 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G22 | | | | | | | | | | | | | | | | |
| Example G23 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G23 | | | | | | | | | | | | | | | | |
| Example G24 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G24 | | | | | | | | | | | | | | | | |
| Example G25 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G25 | | | | | | | | | | | | | | | | |

TABLE 13

| | | | | | | | Photo- | | | | | | | | | | Con- |
|---|---|---|---|---|---|---|---|---|---|---|---|---|---|---|---|---|---|
| | | | | | Poly- | | polymer- | | | | | | Polymer- | | | | centration |
| | | | | | merizable | | ization | | | | | | ization | | | | of |
| | Dispersion liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% by |
| | Type | mass | Type | mass | Type | mass | Type | mass | Type | mass | Type | mass | Type | mass | Type | mass | mass) |
| Example G26 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G26 | | | | | | | | | | | | | | | | |
| Example G27 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G27 | | | | | | | | | | | | | | | | |
| Example G28 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G28 | | | | | | | | | | | | | | | | |
| Example G29 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G29 | | | | | | | | | | | | | | | | |
| Example G30 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G30 | | | | | | | | | | | | | | | | |
| Example G31 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G31 | | | | | | | | | | | | | | | | |
| Example G32 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G32 | | | | | | | | | | | | | | | | |
| Example G33 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G33 | | | | | | | | | | | | | | | | |
| Example G34 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G34 | | | | | | | | | | | | | | | | |
| Example G35 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G35 | | | | | | | | | | | | | | | | |
| Example G36 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G36 | | | | | | | | | | | | | | | | |
| Example G37 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G37 | | | | | | | | | | | | | | | | |
| Example G38 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G38 | | | | | | | | | | | | | | | | |
| Example G39 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G39 | | | | | | | | | | | | | | | | |
| Example G40 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G40 | | | | | | | | | | | | | | | | |
| Example G41 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G41 | | | | | | | | | | | | | | | | |
| Example G42 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G42 | | | | | | | | | | | | | | | | |
| Example G43 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G43 | | | | | | | | | | | | | | | | |
| Example G44 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid G44 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example G1 | dispersion | | | | | | | | | | | | | | | | |
| | liquid G1 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example G2 | dispersion | | | | | | | | | | | | | | | | |
| | liquid G2 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example G3 | dispersion | | | | | | | | | | | | | | | | |
| | liquid G3 | | | | | | | | | | | | | | | | |

TABLE 14

| | | | | | | | Photo- | | | | | | | | | | |
|---|---|---|---|---|---|---|---|---|---|---|---|---|---|---|---|---|---|
| | | | | | Poly- | | polymer- | | | | | | Polymer- | | | | Con- |
| | | | | | merizable | | ization | | | | | | ization | | | | centration |
| | Dispersion liquid | | Resin | | compound | | initiator | | Additive | | Surfactant | | inhibitor | | Solvent | | of coloring |
| | | Part | | Part | | Part | | Part | | Part | | Part | | Part | | Part | material |
| | | by | | by | | by | | by | | by | | by | | by | | by | (% by |
| | Type | mass | Type | mass | Type | mass | Type | mass | Type | mass | Type | mass | Type | mass | Type | mass | mass) |
| Example G45 | Dispersion | 50 | A-3 | 20.0 | E-1 | 3.1 | G-1 | 0.8 | | | I-1 | 5.0 | J-1 | 0.01 | K-1 | 21.1 | 40 |
| | liquid G4 | | | | | | | | | | | | | | | | |
| Example G46 | Dispersion | 60 | A-3 | 10.0 | E-1 | 2.6 | G-1 | 0.7 | | | I-1 | 5.0 | J-1 | 0.01 | K-1 | 21.7 | 50 |
| | liquid G4 | | | | | | | | | | | | | | | | |
| Example G47 | Dispersion | 72 | A-3 | 2.6 | E-1 | 1.7 | G-1 | 0.6 | | | I-1 | 5.0 | J-1 | 0.01 | K-1 | 18.1 | 60 |
| | liquid G4 | | | | | | | | | | | | | | | | |
| Example G48 | Dispersion | 80 | | | E-1 | 1.3 | G-1 | 0.5 | | | I-1 | 5.0 | J-1 | 0.01 | K-1 | 13.2 | 65 |
| | liquid G4 | | | | | | | | | | | | | | | | |
| Example G49 | Dispersion | 80 | | | E-1 | 1.3 | G-1 | 0.5 | | | I-1 | 5.0 | J-1 | 0.01 | K-1 | 13.2 | 65 |
| | liquid G9 | | | | | | | | | | | | | | | | |
| Example G50 | Dispersion | 80 | | | E-1 | 1.3 | G-1 | 0.5 | | | I-1 | 5.0 | J-1 | 0.01 | K-1 | 13.2 | 65 |
| | liquid G13 | | | | | | | | | | | | | | | | |
| Example G51 | Dispersion | 80 | | | E-1 | 1.3 | G-1 | 0.5 | | | I-1 | 5.0 | J-1 | 0.01 | K-1 | 13.2 | 65 |
| | liquid G20 | | | | | | | | | | | | | | | | |
| Example G52 | Dispersion | 80 | | | E-1 | 1.3 | G-1 | 0.5 | | | I-1 | 5.0 | J-1 | 0.01 | K-1 | 13.2 | 65 |
| | liquid G22 | | | | | | | | | | | | | | | | |
| Example G53 | Dispersion | 80 | | | E-1 | 1.3 | G-1 | 0.5 | | | I-1 | 5.0 | J-1 | 0.01 | K-1 | 13.2 | 65 |
| | liquid G23 | | | | | | | | | | | | | | | | |
| Example G54 | Dispersion | 80 | | | E-1 | 1.3 | G-1 | 0.5 | | | I-1 | 5.0 | J-1 | 0.01 | K-1 | 13.2 | 65 |
| | liquid G33 | | | | | | | | | | | | | | | | |
| Example G55 | Dispersion | 65 | A-3 | 5.0 | E-1 | 2.6 | G-1 | 0.7 | H-1 | 0.4 | I-1 | 5.0 | J-1 | 0.01 | K-1 | 21.3 | 53 |
| | liquid G17 | | | | | | | | | | | | | | | | |
| Example G56 | Dispersion | 65 | A-3 | 7.0 | E-2 | 2.6 | G-1 | 0.7 | | | I-1 | 5.0 | J-1 | 0.01 | K-1 | 19.7 | 53 |
| | liquid G17 | | | | | | | | | | | | | | | | |
| Example G57 | Dispersion | 65 | A-3 | 7.0 | E-1 | 1.3 | G-1 | 0.7 | | | I-1 | 5.0 | J-1 | 0.01 | K-1 | 19.7 | 53 |
| | liquid G17 | | | | E-3 | 1.3 | | | | | | | | | | | |
| Example G58 | Dispersion | 65 | A-3 | 7.0 | E-1 | 2.6 | G-1 | 0.35 | | | I-1 | 5.0 | J-1 | 0.01 | K-1 | 19.7 | 53 |
| | liquid G17 | | | | | | G-2 | 0.35 | | | | | | | | | |
| Example G59 | Dispersion | 65 | A-3 | 7.0 | E-1 | 2.6 | G-3 | 0.7 | | | I-1 | 5.0 | J-1 | 0.01 | K-1 | 19.7 | 53 |
| | liquid G17 | | | | | | | | | | | | | | | | |
| Example G60 | Dispersion | 65 | A-3 | 7.0 | E-1 | 2.6 | G-1 | 0.35 | | | I-1 | 5.0 | J-1 | 0.01 | K-1 | 19.7 | 53 |
| | liquid G17 | | | | | | G-3 | 0.35 | | | | | | | | | |
| Example G61 | Dispersion | 65 | A-3 | 7.0 | E-1 | 2.6 | G-1 | 0.7 | | | I-1 | 5.0 | J-1 | 0.01 | K-1 | 22.7 | 53 |
| | liquid G17 | | | | | | | | | | | | | | K-2 | | |
| Example G62 | Dispersion | 65 | A-3 | 4.0 | E-1 | 2.6 | G-4 | 0.7 | H-2 | 0.4 | I-2 | 5.0 | J-1 | 0.01 | K-1 | 19.7 | 53 |
| | liquid G33 | | | | E-2 | | | | | | | | | | | | |
| Comparative | Comparative | 50 | A-3 | 20.0 | E-1 | 3.1 | G-1 | 0.8 | | | I-1 | 5.0 | J-1 | 0.01 | K-1 | 21.1 | 40 |
| Example G4 | dispersion | | | | | | | | | | | | | | | | |
| | liquid G2 | | | | | | | | | | | | | | | | |
| Comparative | Comparative | 60 | A-3 | 10.0 | E-1 | 2.6 | G-1 | 0.7 | | | I-1 | 5.0 | J-1 | 0.01 | K-1 | 21.7 | 50 |
| Example G5 | dispersion | | | | | | | | | | | | | | | | |
| | liquid G2 | | | | | | | | | | | | | | | | |
| Comparative | Comparative | 72 | A-3 | 2.6 | E-1 | 1.7 | G-1 | 0.6 | | | I-1 | 5.0 | J-1 | 0.01 | K-1 | 18.1 | 60 |
| Example G6 | dispersion | | | | | | | | | | | | | | | | |
| | liquid G2 | | | | | | | | | | | | | | | | |

TABLE 15

| | | | | | | | Photo- | | | | | | | | | | |
|---|---|---|---|---|---|---|---|---|---|---|---|---|---|---|---|---|---|
| | | | | | Poly- | | polymer- | | | | | | Polymer- | | | | Con- |
| | Dispersion | | | | merizable | | ization | | | | | | ization | | | | centration |
| | liquid | | Resin | | compound | | initiator | | Additive | | Surfactant | | inhibitor | | Solvent | | of coloring |
| | | Part | | Part | | Part | | Part | | Part | | Part | | Part | | Part | material |
| | | by | | by | | by | | by | | by | | by | | by | | by | (% by |
| | Type | mass | Type | mass | Type | mass | Type | mass | Type | mass | Type | mass | Type | mass | Type | mass | mass) |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G63 | liquid G45 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G64 | liquid G46 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G65 | liquid G47 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G66 | liquid G48 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G67 | liquid G49 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G68 | liquid G50 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| G69 | liquid G51 | | | | | | | | | | | | | | | | |
| Example | Dispersion | 65 | A-3 | 5.0 | E-1 | 2.6 | G-1 | 0.7 | H-3 | 0.4 | I-1 | 5.0 | J-1 | 0.01 | K-1 | 21.3 | 53 |
| G70 | liquid G17 | | | | | | | | | | | | | | | | |

TABLE 16

| | | | | | | | Photo- | | | | | | | | | | Con- |
|---|---|---|---|---|---|---|---|---|---|---|---|---|---|---|---|---|---|
| | | | | | Poly- | | polymer- | | | | | | Polymer- | | | | centration |
| | | | | | merizable | | ization | | | | | | ization | | | | of |
| | Dispersion liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% by |
| | Type | mass | Type | mass | Type | mass | Type | mass | Type | mass | Type | mass | Type | mass | Type | mass | mass) |
| Example R1 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R1 | | | | | | | | | | | | | | | | |
| Example R2 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R2 | | | | | | | | | | | | | | | | |
| Example R3 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R3 | | | | | | | | | | | | | | | | |
| Example R4 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R4 | | | | | | | | | | | | | | | | |
| Example R5 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R5 | | | | | | | | | | | | | | | | |
| Example R6 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R6 | | | | | | | | | | | | | | | | |
| Example R7 | Disperson | 65 | A-3 | 7.0 | E-1 | 2.6 | G-1 | 0.7 | | | I-1 | 5.0 | J-1 | 0.01 | K-1 | 19.7 | 53 |
| | liquid R7 | | | | | | | | | | | | | | | | |
| Example R8 | Disperson | 65 | A-3 | 7.0 | E-1 | 2.6 | G-1 | 0.7 | | | I-1 | 5.0 | J-1 | 0.01 | K-1 | 19.7 | 53 |
| | liquid R8 | | | | | | | | | | | | | | | | |
| Example R9 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R9 | | | | | | | | | | | | | | | | |
| Example R10 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R10 | | | | | | | | | | | | | | | | |
| Example R11 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R11 | | | | | | | | | | | | | | | | |
| Example R12 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R12 | | | | | | | | | | | | | | | | |
| Example R13 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R13 | | | | | | | | | | | | | | | | |
| Example R14 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R14 | | | | | | | | | | | | | | | | |
| Example R15 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R15 | | | | | | | | | | | | | | | | |
| Example R16 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R16 | | | | | | | | | | | | | | | | |
| Example R17 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R17 | | | | | | | | | | | | | | | | |
| Example R18 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R18 | | | | | | | | | | | | | | | | |
| Example R19 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R19 | | | | | | | | | | | | | | | | |
| Example R20 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R20 | | | | | | | | | | | | | | | | |
| Example R21 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R21 | | | | | | | | | | | | | | | | |
| Example R22 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R22 | | | | | | | | | | | | | | | | |
| Example R23 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R23 | | | | | | | | | | | | | | | | |
| Example R24 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R24 | | | | | | | | | | | | | | | | |
| Example R25 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R25 | | | | | | | | | | | | | | | | |
| Example R26 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R26 | | | | | | | | | | | | | | | | |
| Example R27 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R27 | | | | | | | | | | | | | | | | |
| Example R28 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R28 | | | | | | | | | | | | | | | | |
| Example R29 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R29 | | | | | | | | | | | | | | | | |
| Example R30 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R30 | | | | | | | | | | | | | | | | |
| Example R31 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R31 | | | | | | | | | | | | | | | | |
| Example R32 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R32 | | | | | | | | | | | | | | | | |
| Example R33 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R33 | | | | | | | | | | | | | | | | |
| Example R34 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R34 | | | | | | | | | | | | | | | | |
| Example R35 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid R35 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example R1 | dispersion | | | | | | | | | | | | | | | | |
| | liquid R1 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example R2 | dispersion | | | | | | | | | | | | | | | | |
| | liquid R2 | | | | | | | | | | | | | | | | |
| Comparative | Comparative | 65 | A-3 | 7.0 | E-1 | 2.6 | G-1 | 0.7 | | | I-1 | 5.0 | J-1 | 0.01 | K-1 | 19.7 | 53 |
| Example R3 | dispersion | | | | | | | | | | | | | | | | |
| | liquid R3 | | | | | | | | | | | | | | | | |

TABLE 17

| | | | | | | | Photo- | | | | | | | | | | |
|---|---|---|---|---|---|---|---|---|---|---|---|---|---|---|---|---|---|
| | | | | | Poly- | | polymer- | | | | | | Polymer- | | | | Con- |
| | | | | | merizable | | ization | | | | | | ization | | | | centration |
| | Dispersion liquid | | Resin | | compound | | initiator | | Additive | | Surfactant | | inhibitor | | Solvent | | of coloring |
| | | Part | | Part | | Part | | Part | | Part | | Part | | Part | | Part | material |
| | | by | | by | | by | | by | | by | | by | | by | | by | (% |
| | Type | mass | Type | mass | Type | mass | Type | mass | Type | mass | Type | mass | Type | mass | Type | mass | by mass) |
| Example R36 | Dispersion | 50 | A-3 | 20.0 | E-1 | 3.1 | G-1 | 0.8 | | | I-1 | 5.0 | J-1 | 0.01 | K-1 | 21.1 | 40 |
| | liquid R4 | | | | | | | | | | | | | | | | |
| Example R37 | Dispersion | 60 | A-3 | 10.0 | E-1 | 2.6 | G-1 | 0.7 | | | I-1 | 5.0 | J-1 | 0.01 | K-1 | 21.7 | 50 |
| | liquid R4 | | | | | | | | | | | | | | | | |
| Example R38 | Dispersion | 72 | A-3 | 2.6 | E-1 | 1.7 | G-1 | 0.6 | | | I-1 | 5.0 | J-1 | 0.01 | K-1 | 18.1 | 60 |
| | liquid R4 | | | | | | | | | | | | | | | | |
| Example R39 | Dispersion | 80 | | | E-1 | 1.3 | G-1 | 0.5 | | | I-1 | 5.0 | J-1 | 0.01 | K-1 | 13.2 | 65 |
| | liquid R4 | | | | | | | | | | | | | | | | |
| Example R40 | Dispersion | 65 | A-3 | 5.0 | E-1 | 2.6 | G-1 | 0.7 | H-1 | 0.4 | I-1 | 5.0 | J-1 | 0.01 | K-1 | 21.3 | 53 |
| | liquid R17 | | | | | | | | | | | | | | | | |
| Example R41 | Dispersion | 65 | A-3 | 7.0 | E-2 | 2.6 | G-1 | 0.7 | | | I-1 | 5.0 | J-1 | 0.01 | K-1 | 19.7 | 53 |
| | liquid R17 | | | | | | | | | | | | | | | | |
| Example R42 | Dispersion | 65 | A-3 | 7.0 | E-1 | 1.3 | G-1 | 0.7 | | | I-1 | 5.0 | J-1 | 0.01 | K-1 | 19.7 | 53 |
| | liquid R17 | | | | E-3 | 1.3 | | | | | | | | | | | |
| Example R43 | Dispersion | 65 | A-3 | 7.0 | E-1 | 2.6 | G-1 | 0.35 | | | I-1 | 5.0 | J-1 | 0.01 | K-1 | 19.7 | 53 |
| | liquid R17 | | | | | | G-2 | 0.35 | | | | | | | | | |
| Example R44 | Dispersion | 65 | A-3 | 7.0 | E-1 | 2.6 | G-3 | 0.7 | | | I-1 | 5.0 | J-1 | 0.01 | K-1 | 19.7 | 53 |
| | liquid R17 | | | | | | | | | | | | | | | | |
| Example R45 | Dispersion | 65 | A-3 | 7.0 | E-1 | 2.6 | G-1 | 0.35 | | | I-1 | 5.0 | J-1 | 0.01 | K-1 | 19.7 | 53 |
| | liquid R17 | | | | | | G-3 | 0.35 | | | | | | | | | |
| Example R46 | Dispersion | 65 | A-3 | 7.0 | E-1 | 2.6 | G-1 | 0.7 | | | I-1 | 5.0 | J-1 | 0.01 | K-1 | 22.7 | 53 |
| | liquid R17 | | | | | | | | | | | | | | K-2 | | |
| Example R47 | Dispersion | 65 | A-3 | 4.0 | E-4 | 2.6 | G-4 | 0.7 | H-2 | 0.4 | I-2 | 5.0 | J-1 | 0.01 | K-1 | 19.7 | 53 |
| | liquid R17 | | | | | | | | | | | | | | | | |
| Comparative | Comparative | 50 | A-3 | 20.0 | E-1 | 3.1 | G-1 | 0.8 | | | I-1 | 5.0 | J-1 | 0.01 | K-1 | 21.1 | 40 |
| Example R4 | dispersion | | | | | | | | | | | | | | | | |
| | liquid R2 | | | | | | | | | | | | | | | | |
| Comparative | Comparative | 60 | A-3 | 10.0 | E-1 | 2.6 | G-1 | 0.7 | | | I-1 | 5.0 | J-1 | 0.01 | K-1 | 21.7 | 50 |
| Example R5 | dispersion | | | | | | | | | | | | | | | | |
| | liquid R2 | | | | | | | | | | | | | | | | |
| Comparative | Comparative | 72 | A-3 | 2.6 | E-1 | 1.7 | G-1 | 0.6 | | | I-1 | 5.0 | J-1 | 0.01 | K-1 | 18.1 | 60 |
| Example R6 | dispersion | | | | | | | | | | | | | | | | |
| | liquid R2 | | | | | | | | | | | | | | | | |

TABLE 18

| | | | | | | | Photo- | | | | | | | | | | |
|---|---|---|---|---|---|---|---|---|---|---|---|---|---|---|---|---|---|
| | | | | | Poly- | | polymer- | | | | | | Polymer- | | | | Con- |
| | Dispersion | | | | merizable | | ization | | | | | | ization | | | | centration of |
| | liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% |
| | Type | mass | Type | mass | Type | mass | Type | mass | Type | mass | Type | mass | Type | mass | Type | mass | by mass) |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| R48 | liquid R36 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| R49 | liquid R37 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| R50 | liquid R38 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| R51 | liquid R39 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| R52 | liquid R40 | | | | | | | | | | | | | | | | |
| Example | Dispersion | 65 | A-3 | 5.0 | E-1 | 2.6 | G-1 | 0.7 | H-3 | 0.4 | I-1 | 5.0 | J-1 | 0.01 | K-1 | 21.3 | 53 |
| R53 | liquid R17 | | | | | | | | | | | | | | | | |

TABLE 19

| | | | | | | | Photo- | | | | | | | | | | Con- |
|---|---|---|---|---|---|---|---|---|---|---|---|---|---|---|---|---|---|
| | | | | | Poly- | | polymer- | | | | | | Polymer- | | | | centration |
| | Dispersion | | | | merizable | | ization | | | | | | ization | | | | of |
| | liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% |
| | Type | mass | Type | mass | Type | mass | Type | mass | Type | mass | Type | mass | Type | mass | Type | mass | by mass) |
| Example Y1 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y1 | | | | | | | | | | | | | | | | |
| Example Y2 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y2 | | | | | | | | | | | | | | | | |
| Example Y3 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y3 | | | | | | | | | | | | | | | | |
| Example Y4 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y4 | | | | | | | | | | | | | | | | |
| Example Y5 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y5 | | | | | | | | | | | | | | | | |
| Example Y6 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y6 | | | | | | | | | | | | | | | | |
| Example Y7 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y7 | | | | | | | | | | | | | | | | |
| Example Y8 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y8 | | | | | | | | | | | | | | | | |
| Example Y9 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y9 | | | | | | | | | | | | | | | | |
| Example Y10 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y10 | | | | | | | | | | | | | | | | |
| Example Y11 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y11 | | | | | | | | | | | | | | | | |
| Example Y12 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y12 | | | | | | | | | | | | | | | | |
| Example Y13 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y13 | | | | | | | | | | | | | | | | |
| Example Y14 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y14 | | | | | | | | | | | | | | | | |
| Example Y15 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y15 | | | | | | | | | | | | | | | | |
| Example Y16 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y16 | | | | | | | | | | | | | | | | |
| Example Y17 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y17 | | | | | | | | | | | | | | | | |
| Example Y18 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y18 | | | | | | | | | | | | | | | | |
| Example Y19 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y19 | | | | | | | | | | | | | | | | |
| Example Y20 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y20 | | | | | | | | | | | | | | | | |
| Example Y21 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y21 | | | | | | | | | | | | | | | | |
| Example Y22 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y22 | | | | | | | | | | | | | | | | |
| Example Y23 | Dispersion | 65 | A-3 | 7.0 | E-1 | 2.6 | G-1 | 0.7 | | | I-1 | 5.0 | J-1 | 0.01 | K-1 | 19.7 | 53 |
| | liquid Y23 | | | | | | | | | | | | | | | | |

TABLE 20

| | | | | | | | Photo- | | | | | | | | | | |
|---|---|---|---|---|---|---|---|---|---|---|---|---|---|---|---|---|---|
| | | | | | Poly- | | polymer- | | | | | | Polymer- | | | | Con- |
| | Dispersion | | | | merizable | | ization | | | | | | ization | | | | centration of |
| | liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% |
| | Type | mass | Type | mass | Type | mass | Type | mass | Type | mass | Type | mass | Type | mass | Type | mass | by mass) |
| Example | Dispersion | 50 | A-3 | 20.0 | E-1 | 3.1 | G-1 | 0.8 | | | I-1 | 5.0 | J-1 | 0.01 | K-1 | 21.1 | 40 |
| Y24 | liquid Y1 | | | | | | | | | | | | | | | | |
| Example | Dispersion | 60 | A-3 | 10.0 | E-1 | 2.6 | G-1 | 0.7 | | | I-1 | 5.0 | J-1 | 0.01 | K-1 | 21.7 | 50 |
| Y25 | liquid Y1 | | | | | | | | | | | | | | | | |
| Example | Dispersion | 72 | A-3 | 2.6 | E-1 | 1.7 | G-1 | 0.6 | | | I-1 | 5.0 | J-1 | 0.01 | K-1 | 18.1 | 60 |
| Y26 | liquid Y1 | | | | | | | | | | | | | | | | |
| Example | Dispersion | 65 | A-3 | 5.0 | E-1 | 2.6 | G-1 | 0.7 | H-1 | 0.4 | I-1 | 5.0 | J-1 | 0.01 | K-1 | 21.3 | 53 |
| Y27 | liquid Y10 | | | | | | | | | | | | | | | | |
| Example | Dispersion | 65 | A-3 | 7.0 | E-2 | 2.6 | G-1 | 0.7 | | | I-1 | 5.0 | J-1 | 0.01 | K-1 | 19.7 | 53 |
| Y28 | liquid Y10 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| Y29 | liquid Y10 | | | | E-3 | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| Y30 | liquid Y10 | | | | | | G-2 | | | | | | | | | | |
| Example | Dispersion | 65 | A-3 | 7.0 | E-1 | 2.6 | G-3 | 0.7 | | | I-1 | 5.0 | J-1 | 0.01 | K-1 | 19.7 | 53 |
| Y31 | liquid Y10 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| Y32 | liquid Y10 | | | | | | G-3 | | | | | | | | | | |
| Example | Dispersion | 65 | A-3 | 4.0 | E-1 | 2.6 | G-1 | 0.7 | | | I-1 | 5.0 | J-1 | 0.01 | K-1 | 22.7 | 53 |
| Y33 | liquid Y10 | | | | | | | | | | | | | | K-2 | | |

TABLE 21

| | | | | | | | Photo- | | | | | | | | | | Con- |
|---|---|---|---|---|---|---|---|---|---|---|---|---|---|---|---|---|---|
| | | | | | Poly- | | polymer- | | | | | | Polymer- | | | | centration |
| | Dispersion | | | | merizable | | ization | | | | | | ization | | | | of |
| | liquid | | Resin | | compound | | initiator | | Additive | | Surfactant | | inhibitor | | Solvent | | coloring |
| | | Part | | Part | | Part | | Part | | Part | | Part | | Part | | Part | material |
| | | by | | by | | by | | by | | by | | by | | by | | by | (% |
| | Type | mass | Type | mass | Type | mass | Type | mass | Type | mass | Type | mass | Type | mass | Type | mass | by mass) |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| IR1 | liquid IR1 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| IR2 | liquid IR2 | | | | | | | | | | | | | | | | |
| Example | Dispersion | 65 | A-3 | 7.0 | E-1 | 2.6 | G-1 | 0.7 | | | I-1 | 5.0 | J-1 | 0.01 | K-1 | 19.7 | 53 |
| IR3 | liquid IR3 | | | | | | | | | | | | | | | | |

The raw materials described by abbreviations shown in the above tables are as follows.

(Dispersion Liquid)

Dispersion Liquids G1 to G51: dispersion liquids G1 to G51 described above

Dispersion Liquids R1 to R40: dispersion liquids R1 to R40 described above

Dispersion liquids Y1 to Y23: dispersion liquids Y1 to Y23 described above

Dispersion liquids IR1 to IR3: dispersion liquids IR1 to IR3 described above

Comparative dispersion liquids G1 to G3: comparative dispersion liquids G1 to G3 described above

Comparative dispersion liquids R1 to R3: comparative dispersion liquids R1 to R3 described above

(Resin)

A-3: 20% by mass PGMEA solution of a resin having the following structure (the numerical value described together with the main chain indicates a molar ratio; Mw=11000)

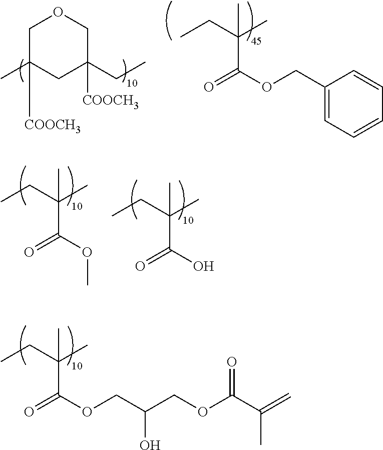

(Polymerizable Compound)

E-1: dipentaerythritol hexaacrylate (manufactured by Nippon Kayaku Co., Ltd., KAYARAD DPHA, molecular weight: 578)

E-2: trimethylolpropane triacrylate (manufactured by TOAGOSEI CO., LTD, ARONIX M-309, molecular weight: 296)

E-3: tris(2-acryloyloxyethyl) isocyanurate (manufactured by TOAGOSEI CO., LTD, ARONIX M-315, molecular weight: 423)

E-4: trimethylolpropane EO-modified triacrylate (manufactured by TOAGOSEI CO., LTD, ARONIX M-350)

(Photopolymerization Initiator)

G-1: compound having the following structure

G-2: compound having the following structure

G-3: compound having the following structure

G-4: compound having the following structure

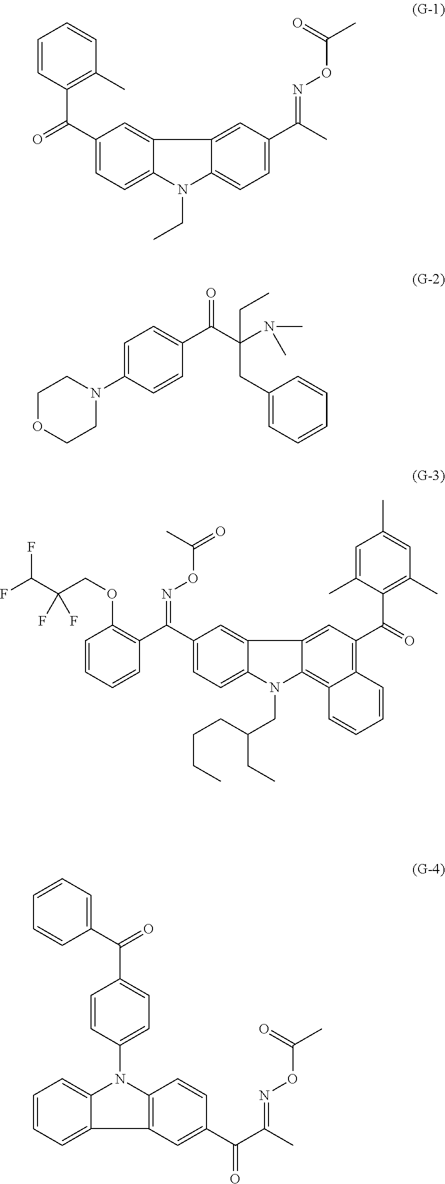 [SMILES: CCn1c2ccc(C(=O)c3ccccc3C)cc2c2cc(/C(C)=N/OC(C)=O)ccc21 ; CCC(Cc1ccccc1)(C(=O)c1ccc(N2CCOCC2)cc1)N(C)C ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\C)C(=O)c1ccc2c(c1)c1ccccc1n2-c1ccc(C(=O)c2ccccc2)cc1]

(Additive)

H-1: EHPE-3150 (manufactured by Daicel Corporation, epoxy compound)

H-2: compound having the following structure (TINUVIN 326, manufactured by BASF, ultraviolet absorber)

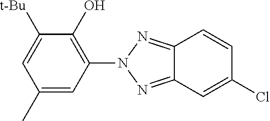 [SMILES: Cc1cc(-n2nc3ccc(Cl)cc3n2)c(O)c(C(C)(C)C)c1]

H-3: compound having the following structure (potential antioxidant)

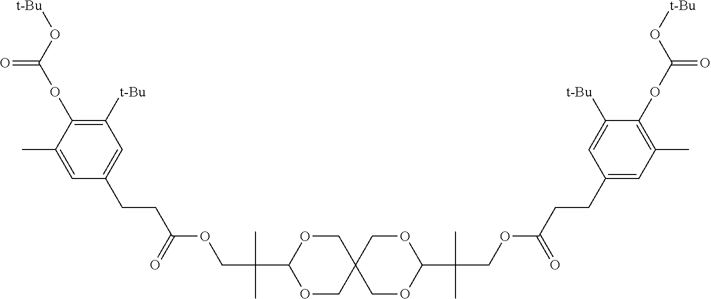 [SMILES: Cc1cc(CCC(=O)OCC(C)(C)C2OCC3(CO2)COC(C(C)(C)COC(=O)CCc2cc(C)c(OC(=O)OC(C)(C)C)c(C(C)(C)C)c2)OC3)cc(C(C)(C)C)c1OC(=O)OC(C)(C)C]

(Surfactant)

I-1: 1% by mass PGMEA solution of a mixture shown below (Mw=14000); in the following formula, % representing the proportion of a repeating unit is % by mass.

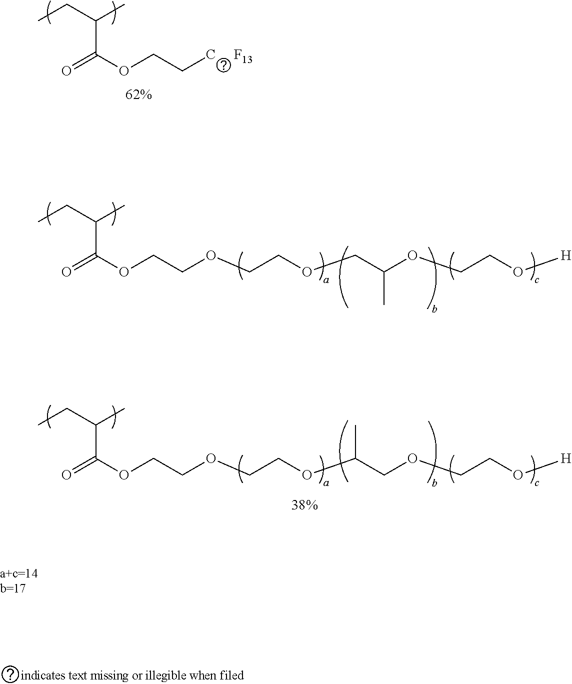

I-2: solution prepared by adding PGMEA to FZ-2122 (manufactured by DuPont Toray Specialty Materials K.K.) to adjust a concentration of solid contents to 1% by mass

(Polymerization Inhibitor)

J-1: p-methoxyphenol

(Solvent)

K-1: PGMEA

K-2: cyclohexanone

<Performance Evaluation of Coloring Composition>

(Temporal Stability)

A viscosity (mPa·s) of each coloring composition immediately after production was measured with “RE-85L” manufactured by TOKI SANGYO CO., LTD. After the above-described measurement, each coloring composition was allowed to stand at 45° C. under the conditions of light shielding for 3 days, and the viscosity (mPa·s) was measured again.

Storage stability was evaluated according to the following evaluation standard from a viscosity difference (ΔVis) before and after leaving to stand. The evaluation results are described in the column of “Temporal stability” in the above tables. It can be said that, as the numerical value of the viscosity difference (ΔVis) is smaller, the temporal stability of the coloring composition is better. In each of the above-described viscosity measurements, the temperature and humidity were controlled to 22±5° C. and 60±20% in a laboratory, and the temperature of the coloring composition was adjusted to 25° C.

—Evaluation Standard—

A: ΔVis was 0.5 mPa·s or less.

B: ΔVis was more than 0.5 mPa·s and 1.0 mPa·s or less.

C: ΔVis was more than 1.0 mPa·s and 2.0 mPa·s or less.

D: ΔVis was more than 2.0 mPa·s.

(Developability)

A CT-4000L solution (manufactured by Fujifilm Electronic Materials Co., Ltd.; transparent base coat agent) was applied to a silicon wafer with a diameter of 8 inches (1 inch=25.4 mm) so that a thickness of a dried film was 0.1 μm, and dried to form a base layer, and a heating treatment was performed at 220° C. for 5 minutes. Each coloring composition was applied to the silicon wafer on which the base layer had been formed using a spin coater such that a film thickness after pre-baking was 0.6 μm, and a heating treatment (pre-baking) was performed for 120 seconds using a hot plate at 100° C. Next, using an i-ray stepper exposure device FPA-3000 i5+(manufactured by Canon Inc.), light having a wavelength of 365 nm was irradiated thereto with an exposure amount of 500 mJ/cm² for exposure through a mask pattern in which each of the square pixels with a side length of 1.1 μm was arranged on a substrate in a region of 4 mm×3 mm. The silicon wafer with the film after exposure was placed on a horizontal rotary table of a spin-shower developing machine (DW-30 Type, manufactured by Chemitronics Co., Ltd.), and subjected to a puddle development at 23° C. for 60 seconds using an alkali developer (CD-2060, manufactured by Fujifilm Electronic Materials Co., Ltd.). Next, the silicon wafer after the puddle development was fixed on the horizontal rotary table by a vacuum chuck method, a rinse treatment (23 seconds×2 times) was performed by supplying pure water from above a rotation center in shower-like from an ejection nozzle while rotating the silicon wafer at a rotation speed of 50 rpm by a rotating device, and then the silicon wafer was spin-dried. Next, a heating treatment (post-baking) was performed for 300 seconds using a hot plate at 200° C. to form a colored pattern (pixel). Using a length measuring scanning electron microscope (SEM) (S-7800H, manufactured by Hitachi, Ltd.), the silicon wafer on which the colored pattern (pixel) had been formed was observed at a magnification of 30000 times from the silicon wafer. Developability was evaluated according to the following standard.

A: no residue was observed in the non-exposed portion.

B: 1 to 3 residues were observed in 1.1 μm square of the non-exposed portion.

C: 4 to 10 residues were observed in 1.1 μm square of the non-exposed portion.

D: 11 or more residues were observed in 1.1 μm square of the non-exposed portion.

(Evaluation of Defects)

A colored pattern (pixel) was formed by performing the same operation as for the developability, except that, as the mask, a mask capable of forming an island pattern of 1.4 μm×1.4 μm with a period of 2.8 μm×2.8 μm was used. Defects were evaluated by counting the number of defects in the pixels formed on the silicon wafer. The number of defects in the pixels was examined using a wafer defect evaluation device (ComPLUS3, manufactured by AMAT).

A: total number of defects in pixels formed on silicon wafer ≤30

B: 30≤total number of defects in pixels formed on silicon wafer ≤100

C: 100≤total number of defects in pixels formed on silicon wafer ≤300

D: 300≤total number of defects in pixels formed on silicon wafer

(Evaluation of Surface Roughness)

A surface roughness (Ra) of the pixels obtained in the developability evaluation was measured using an atomic force microscope Dimension FastScan AFM (manufactured by Bruker). The evaluation standard for the surface roughness is as follows.

A: surface roughness (Ra) was 0 nm or more and less than 3 nm.

B: surface roughness (Ra) was 3 nm or more and less than 5 nm.

C: surface roughness (Ra) was 5 nm or more and less than 7 nm.

D: surface roughness (Ra) was 7 nm or more.

TABLE 22

| | Evaluation | | | |
|---|---|---|---|---|
| | Temporal | Develop- | | Surface |
| | stability | ability | Defect | roughness |
| Example G1 | C | A | A | A |
| Example G2 | C | A | A | A |
| Example G3 | B | A | A | A |
| Example G4 | B | A | A | A |
| Example G5 | B | A | A | A |
| Example G6 | B | A | A | A |
| Example G7 | B | A | B | A |
| Example G8 | B | A | A | A |
| Example G9 | A | A | A | A |
| Example G10 | B | A | A | A |
| Example G11 | A | A | A | A |
| Example G12 | A | A | A | A |
| Example G13 | A | A | A | A |
| Example G14 | A | A | A | A |
| Example G15 | A | A | A | B |
| Example G16 | A | A | A | A |
| Example G17 | B | A | A | A |
| Example G18 | B | A | A | A |
| Example G19 | B | A | A | B |
| Example G20 | B | A | A | A |
| Example G21 | A | A | A | A |
| Example G22 | A | A | A | A |
| Example G23 | B | A | A | A |
| Example G24 | B | A | A | B |
| Example G25 | B | A | A | A |
| Example G26 | B | A | A | B |
| Example G27 | B | A | A | A |
| Example G28 | B | A | A | A |
| Example G29 | B | A | A | A |
| Example G30 | B | A | A | A |
| Example G31 | B | A | A | A |
| Example G32 | B | A | A | B |
| Example G33 | B | A | A | A |
| Example G34 | B | A | A | A |
| Example G35 | B | A | A | A |
| Example G36 | B | A | A | A |
| Example G37 | B | A | A | A |
| Example G38 | B | A | A | A |
| Example G39 | B | C | A | A |
| Example G40 | B | A | A | A |
| Example G41 | B | A | A | A |
| Example G42 | B | A | B | A |
| Example G43 | B | A | B | A |
| Example G44 | B | A | B | A |
| Comparative Example G1 | D | D | D | D |
| Comparative Example G2 | D | D | D | D |
| Comparative Example G3 | D | D | D | D |

TABLE 23

| | Evaluation | | | |
|---|---|---|---|---|
| | Temporal | Develop- | | Surface |
| | stability | ability | Defect | roughness |
| Example G45 | B | A | A | A |
| Example G46 | B | A | A | A |
| Example G47 | B | A | A | A |
| Example G48 | B | A | A | A |
| Example G49 | A | A | A | A |
| Example G50 | A | A | A | A |
| Example G51 | B | A | A | A |
| Example G52 | A | A | A | A |
| Example G53 | B | A | A | A |
| Example G54 | B | A | A | A |
| Example G55 | B | A | A | A |
| Example G56 | B | A | A | A |
| Example G57 | B | A | A | A |
| Example G58 | B | A | A | A |
| Example G59 | B | A | A | A |
| Example G60 | B | A | A | A |
| Example G61 | B | A | A | A |
| Example G62 | B | A | A | A |
| Comparative Example G4 | D | D | D | D |
| Comparative Example G5 | D | D | D | D |
| Comparative Example G6 | D | D | D | D |

TABLE 24

| | Evaluation | | | |
|---|---|---|---|---|
| | Temporal | Develop- | | Surface |
| | stability | ability | Defect | roughness |
| Example G63 | B | A | A | B |
| Example G64 | B | A | A | B |
| Example G65 | B | A | A | B |
| Example G66 | B | A | A | B |
| Example G67 | B | A | A | B |
| Example G68 | B | A | A | B |
| Example G69 | B | A | A | B |
| Example G70 | B | A | A | A |

TABLE 25

| | Evaluation | | | |
|---|---|---|---|---|
| | Temporal | Develop- | | Surface |
| | stability | ability | Defect | roughness |
| Example R1 | C | A | A | A |
| Example R2 | C | A | A | A |
| Example R3 | B | A | A | A |
| Example R4 | B | A | A | A |
| Example R5 | B | A | A | A |
| Example R6 | B | A | A | A |
| Example R7 | B | A | C | A |
| Example R8 | B | A | A | A |
| Example R9 | A | A | A | A |
| Example R10 | B | A | A | A |
| Example R11 | A | A | A | A |
| Example R12 | A | A | A | A |
| Example R13 | B | A | A | A |
| Example R14 | B | A | A | A |
| Example R15 | B | A | A | B |
| Example R16 | B | A | A | A |
| Example R17 | B | A | A | B |
| Example R18 | B | A | A | A |
| Example R19 | B | A | A | A |
| Example R20 | B | A | A | A |
| Example R21 | B | A | A | A |
| Example R22 | B | A | A | A |
| Example R23 | B | A | A | B |
| Example R24 | B | A | A | A |
| Example R25 | B | A | A | A |
| Example R26 | B | A | A | A |
| Example R27 | B | A | A | A |
| Example R28 | B | A | A | A |
| Example R29 | B | A | A | A |
| Example R30 | B | C | A | A |
| Example R31 | B | A | A | A |
| Example R32 | B | A | A | A |
| Example R33 | B | A | B | A |
| Example R34 | B | A | B | A |
| Example R35 | B | A | B | A |
| Comparative Example R1 | D | D | D | D |
| Comparative Example R2 | D | D | D | D |
| Comparative Example R3 | D | D | D | D |

TABLE 26

| | Evaluation | | | |
|---|---|---|---|---|
| | Temporal | Develop- | | Surface |
| | stability | ability | Defect | roughness |
| Example R36 | B | A | A | A |
| Example R37 | B | A | A | A |
| Example R38 | B | A | A | A |
| Example R39 | B | A | A | A |
| Example R40 | B | A | A | A |
| Example R41 | B | A | A | B |
| Example R42 | B | A | A | B |
| Example R43 | B | A | A | B |
| Example R44 | B | A | A | A |
| Example R45 | B | A | A | A |
| Example R46 | B | A | A | B |
| Example R47 | B | A | A | B |
| Comparative Example R4 | D | D | D | D |
| Comparative Example R5 | D | D | D | D |
| Comparative Example R6 | D | D | D | D |

TABLE 27

| | Evaluation | | | |
|---|---|---|---|---|
| | Temporal | Develop- | | Surface |
| | stability | ability | Defect | roughness |
| Example R48 | B | A | A | B |
| Example R49 | B | A | A | B |
| Example R50 | B | A | A | B |
| Example R51 | B | A | A | B |
| Example R52 | B | A | A | B |
| Example R53 | B | A | A | A |

TABLE 28

| | Evaluation | | | |
|---|---|---|---|---|
| | Temporal | Develop- | | Surface |
| | stability | ability | Defect | roughness |
| Example Y1 | B | A | A | A |
| Example Y2 | B | A | B | A |
| Example Y3 | B | A | B | A |
| Example Y4 | B | A | A | A |
| Example Y5 | A | A | A | A |
| Example Y6 | B | A | A | A |
| Example Y7 | A | A | A | A |
| Example Y8 | B | A | A | B |
| Example Y9 | B | A | A | A |
| Example Y10 | B | A | A | B |
| Example Y11 | B | A | A | A |
| Example Y12 | B | A | A | A |
| Example Y13 | B | A | A | A |
| Example Y14 | B | A | A | A |
| Example Y15 | B | A | A | A |
| Example Y16 | B | A | A | B |
| Example Y17 | B | A | A | A |
| Example Y18 | B | A | A | A |
| Example Y19 | B | A | A | A |
| Example Y20 | B | A | A | A |
| Example Y21 | B | A | A | A |
| Example Y22 | B | A | A | A |
| Example Y23 | B | C | A | A |

TABLE 29

| | Evaluation | | | |
|---|---|---|---|---|
| | Temporal | Develop- | | Surface |
| | stability | ability | Defect | roughness |
| Example Y24 | B | A | A | A |
| Example Y25 | B | A | A | A |
| Example Y26 | B | A | A | A |
| Example Y27 | B | A | A | A |
| Example Y28 | B | A | A | B |
| Example Y29 | B | A | A | B |
| Example Y30 | B | A | A | B |
| Example Y31 | B | A | A | A |
| Example Y32 | B | A | A | A |
| Example Y33 | B | A | A | B |

TABLE 30

| | Evaluation | | | |
|---|---|---|---|---|
| | Temporal | Develop- | | Surface |
| | stability | ability | Defect | roughness |
| Example IR1 | B | A | C | A |
| Example IR2 | B | A | C | A |
| Example IR3 | B | A | C | A |

As shown in the above tables, the coloring compositions of Examples had better temporal stability than the coloring compositions of Comparative Examples.

In each of Examples G32, G57, G64, R12, R33, and R50, even in a case where the surfactant I-1 was replaced with the following 1-3 to 1-22, the evaluation results were the same.

I-3: solution prepared by adding PGMEA to BYK-330 (manufactured by BYK Chemie, silicone-based surfactant) to adjust a concentration of solid contents to 1% by mass

I-4: solution prepared by adding PGMEA to BYK-322 (manufactured by BYK Chemie, silicone-based surfactant) to adjust a concentration of solid contents to 1% by mass

I-5: solution prepared by adding PGMEA to BYK-323 (manufactured by BYK Chemie, silicone-based surfactant) to adjust a concentration of solid contents to 1% by mass

I-6: solution prepared by adding PGMEA to BYK-3760 (manufactured by BYK Chemie, silicone-based surfactant) to adjust a concentration of solid contents to 1% by mass

I-7: solution prepared by adding PGMEA to BYK-UV3510 (manufactured by BYK Chemie, silicone-based surfactant) to adjust a concentration of solid contents to 1% by mass

I-8: solution prepared by adding PGMEA to BYK-333 (manufactured by BYK Chemie, silicone-based surfactant) to adjust a concentration of solid contents to 1% by mass

I-9: solution prepared by adding PGMEA to 67 Additive (manufactured by DuPont Toray Specialty Materials K.K., silicone-based surfactant) to adjust a concentration of solid contents to 1% by mass

I-10: solution prepared by adding PGMEA to SH 8400 FLUID (manufactured by DuPont Toray Specialty Materials K.K., silicone-based surfactant) to adjust a concentration of solid contents to 1% by mass

I-11: solution prepared by adding PGMEA to 74 Additive (manufactured by DuPont Toray Specialty Materials K.K., silicone-based surfactant) to adjust a concentration of solid contents to 1% by mass

I-12: solution prepared by adding PGMEA to DC3PA (manufactured by DuPont Toray Specialty Materials K.K., silicone-based surfactant) to adjust a concentration of solid contents to 1% by mass

I-13: solution prepared by adding PGMEA to M Additive (manufactured by DuPont Toray Specialty Materials K.K., silicone-based surfactant) to adjust a concentration of solid contents to 1% by mass

I-14: solution prepared by adding PGMEA to SF 8419 OIL (manufactured by DuPont Toray Specialty Materials K.K., silicone-based surfactant) to adjust a concentration of solid contents to 1% by mass

I-15: solution prepared by adding PGMEA to KF-6000 (manufactured by Shin-Etsu Chemical Co., Ltd., silicone-based surfactant) to adjust a concentration of solid contents to 1% by mass

I-16: solution prepared by adding PGMEA to KF-6001 (manufactured by Shin-Etsu Chemical Co., Ltd., silicone-based surfactant) to adjust a concentration of solid contents to 1% by mass

I-17: solution prepared by adding PGMEA to KF-6002 (manufactured by Shin-Etsu Chemical Co., Ltd., silicone-based surfactant) to adjust a concentration of solid contents to 1% by mass

I-18: solution prepared by adding PGMEA to KF-6003 (manufactured by Shin-Etsu Chemical Co., Ltd., silicone-based surfactant) to adjust a concentration of solid contents to 1% by mass

I-19: solution prepared by adding PGMEA to FTERGENT 710LA (manufactured by NEOS COMPANY LIMITED, fluorine-based surfactant) to adjust a concentration of solid contents to 1% by mass

I-20: solution prepared by adding PGMEA to FTERGENT 710FM (manufactured by NEOS COMPANY LIMITED, fluorine-based surfactant) to adjust a concentration of solid contents to 1% by mass

I-21: solution prepared by adding PGMEA to FTERGENT 710FS (manufactured by NEOS COMPANY LIMITED, fluorine-based surfactant) to adjust a concentration of solid contents to 1% by mass

I-22: solution prepared by adding PGMEA to FTERGENT 601ADH2 (manufactured by NEOS COMPANY LIMITED, fluorine-based surfactant) to adjust a concentration of solid contents to 1% by mass

### Example 1001

A silicon wafer was coated with a green coloring composition by a spin coating method so that the thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green coloring composition was patterned by heating at 200° C. for 5 minutes using a hot plate to form a green pixel. In the same process, a red coloring composition and a blue coloring composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green coloring composition, the coloring composition of Example G13 was used. As the red coloring composition, the coloring composition of Example R9 was used. The blue coloring composition will be described later.

(Preparation of Blue Coloring Composition)

The following components were mixed and stiffed, and the obtained mixture was filtered through a nylon filter (manufactured by Nihon Pall Corporation) having a pore size of 0.45 μm to prepare the blue coloring composition.

Blue pigment dispersion liquid: 44.9 parts by mass

Resin 101: 2.1 parts by mass

Polymerizable compound 101: 1.5 parts by mass

Polymerizable compound 102: 0.7 parts by mass

Photopolymerization initiator 101: 0.8 parts by mass

Surfactant 101: 4.2 parts by mass

PGMEA: 45.8 parts by mass

Raw materials used to prepare the blue coloring composition are as follows.

Blue pigment dispersion liquid

A mixed solution consisting of 9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), and 82.4 parts by mass of PGMEA was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining the blue pigment dispersion liquid.

Polymerizable compound 101: KAYARAD DPHA (manufactured by Nippon Kayaku Co., Ltd.)

Polymerizable compound 102: compound having the following structure

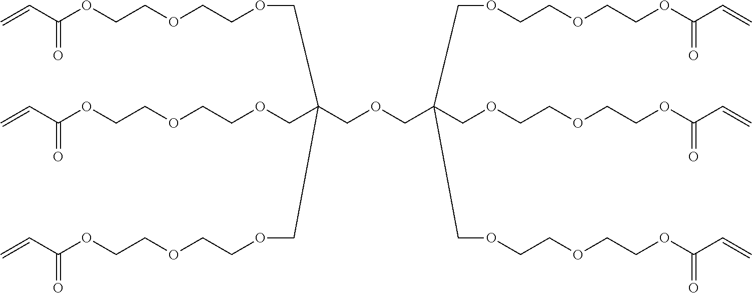 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 101: resin having the following structure (Mw=11000; the numerical value described together with the main chain indicates a molar ratio)

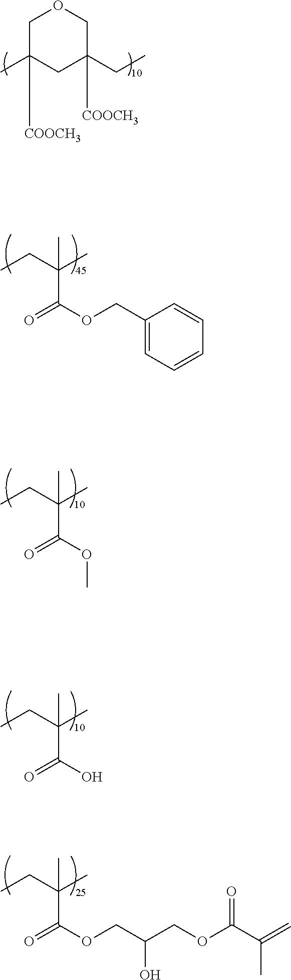

Photopolymerization initiator 101: Irgacure OXE01 (manufactured by BASF)

Surfactant 101: 1% by mass PGMEA solution of a compound having the following structure (Mw=14000; the numerical value “%” representing the proportion of the repeating unit is mol %)

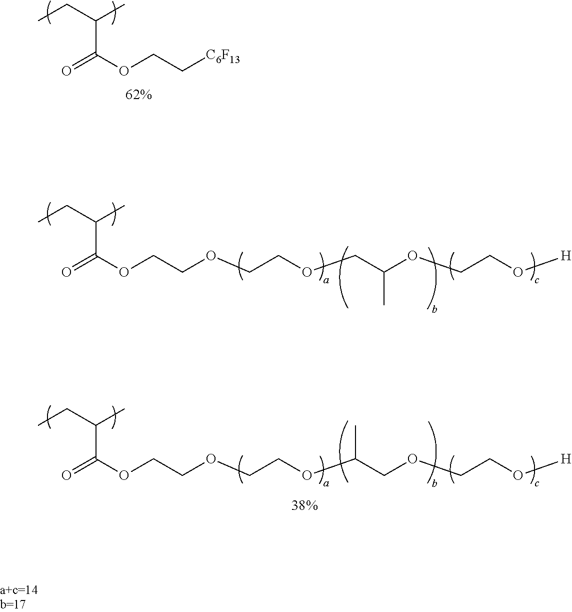

### Example 1002

A silicon wafer was coated with a cyan coloring composition using a spin coating method so that the thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the cyan coloring composition was patterned by heating at 200° C. for 5 minutes using a hot plate to form a cyan pixel. In the same process, a yellow coloring composition and a magenta coloring composition were patterned to sequentially form a yellow pixel and a magenta pixel, thereby forming a color filter having the cyan pixel, yellow pixel, and magenta pixel. In this color filter, the cyan pixel was formed in a Bayer pattern, and the yellow pixel and magenta pixel were formed in an island pattern in an adjacent region thereof. The obtained color filter was incorporated into a solid-state imaging element according to a known method. The solid-state imaging element had a suitable image recognition ability. As the yellow coloring composition, the coloring composition of Example Y1 was used. The cyan coloring composition and magenta coloring composition will be described later.

(Preparation of Cyan Coloring Composition and Magenta Coloring Composition)

Coloring materials of the types described in the following table, dispersants of the types described in the following table, and a part of solvents described in the following table were mixed, and 230 parts by mass of zirconia beads having a diameter of 0.3 mm were added thereto to perform a dispersion treatment for 5 hours using a paint shaker. The beads were separated by filtration, and a pigment dispersion liquid having a solid content of 20% by weight was produced.

Next, the obtained pigment dispersion liquid, the rest of the solvents of the types described in the following table, binders of the types described in the following table, polymerizable compounds of the types described in the following table, photopolymerization initiators of the types described in the following table, and ultraviolet absorbers of the types described in the following table were mixed to prepare a coloring composition. The following table shows the blending amount of each component in each coloring composition. The numerical value of the blending amount of each component is parts by mass.

TABLE 31

| | | Cyan coloring | Magenta coloring |
|---|---|---|---|
| | Type | composition | composition |
| Coloring material | PB15:4 | 2.2 | |
| | PR122 | | 6.1 |
| Dispersant | D1 | | 2.6 |
| | D2 | 1.2 | 0.4 |
| | D4 | 2.3 | |
| Binder | D2 | 0.9 | |
| | D3 | | 2.3 |
| Polymerizable | M1 | 2.7 | |
| compound | M2 | | 2.6 |
| Photopolymerization | F1 | 0.5 | 0.4 |
| initiator | | | |
| Ultraviolet absorber | UV1 | 0.20 | 0.37 |
| Surfactant | W1 | 0.01 | 0.04 |
| Epoxy compound | G1 | | 0.12 |
| Solvent | S1 | 90.0 | 83.2 |
| | S2 | | 1.9 |

The materials indicated by the above abbreviations are as follows.

(Coloring Material)

PB15:4: C. I. Pigment Blue 15:4

PR122: C. I. Pigment Red 122

(Dispersant and Binder)

D1: resin having the following structure (the numerical value described together with the main chain indicates a molar ratio, and the numerical value described together with the side chain indicates the number of repeating units; Mw=24000)

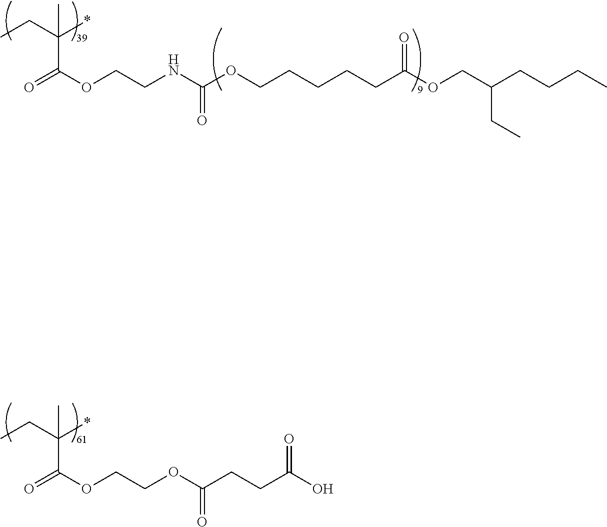

D2: resin having the following structure (the numerical value described together with the main chain indicates a molar ratio; Mw=11000)

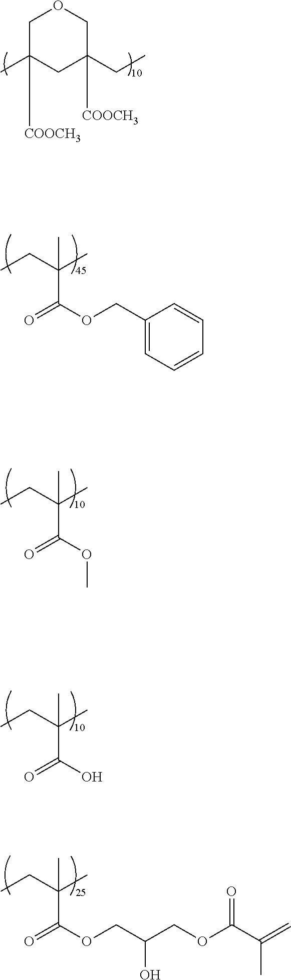

D3: resin having the following structure (the numerical value described together with the main chain indicates a molar ratio, and the numerical value described together with the side chain indicates the number of repeating units; Mw=16000)

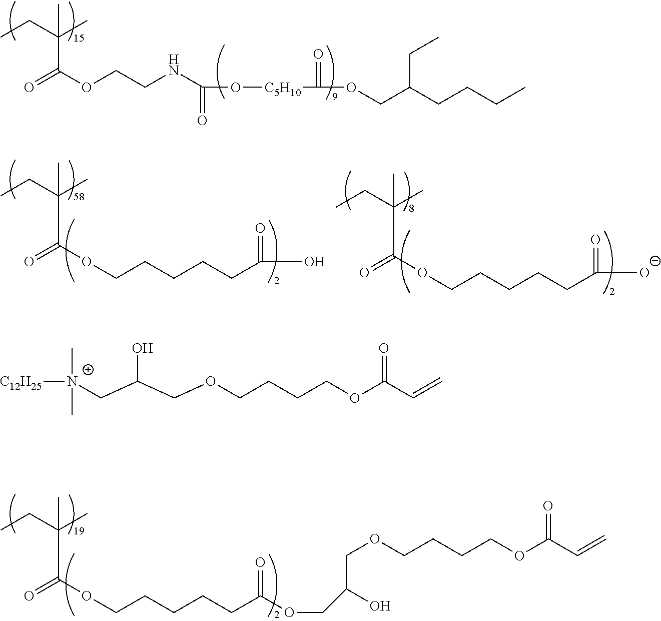

D4: Efka Px 4300 (manufactured by BASF, acrylic resin)

(Polymerizable Compound)

M1: mixture of compounds having the following structures (mixture in which a molar ratio of a compound on the left (hexafunctional (meth)acrylate compound) and a compound on the right (pentafuctional (meth)acrylate compound) was 7:3)

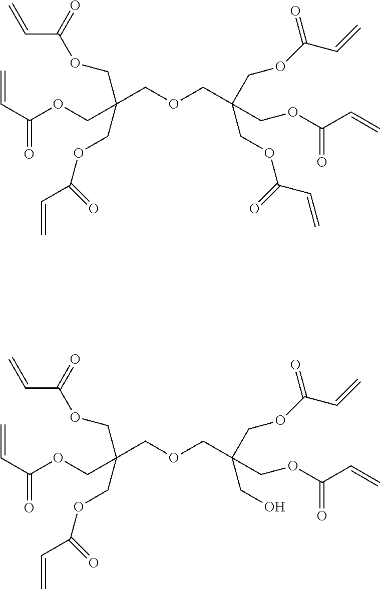 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

M2: compound having the following structure

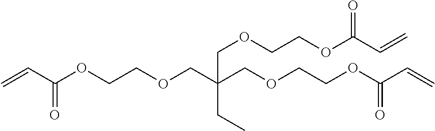 [SMILES: C=CC(=O)OCCOCC(CC)(COCCOC(=O)C=C)COCCOC(=O)C=C]

(Photopolymerization Initiator)

F1: Irgacure OXE02 (manufactured by BASF)

(Ultraviolet Absorber)

UV1: compound having the following structure

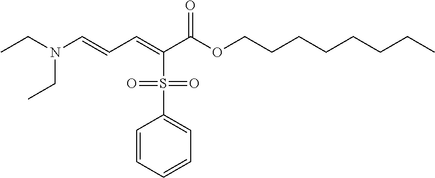 [SMILES: CCCCCCCCOC(=O)/C(=C/C=C/N(CC)CC)S(=O)(=O)c1ccccc1]

(Surfactant)

W1: compound having the following structure (Mw=14000; the numerical value “%” representing the proportion of the repeating unit is mol %; fluorine-based surfactant)

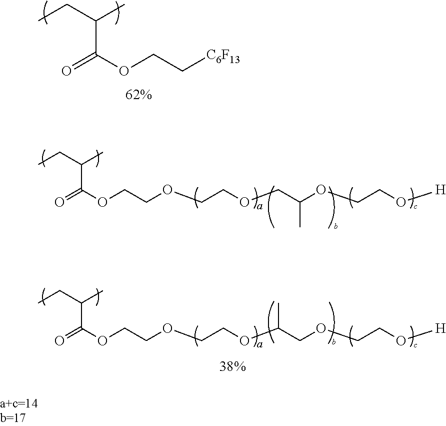

(Epoxy Compound)

G1: EHPE-3150 (manufactured by Daicel Corporation, epoxy compound)

(Solvent)

S1: propylene glycol monomethyl ether acetate (PGMEA)

S2: propylene glycol monomethyl ether (PGME)

What is claimed is:

1. A coloring composition comprising:
a coloring material;
a resin; and
a solvent,
wherein the coloring material contains a pteridin pigment, and
a content of the coloring material in a total solid content of the coloring composition is 40% by mass or more.

2. The coloring composition according to claim 1,
wherein the pteridin pigment includes at least one selected from Color Index Pigment Yellow 215, a compound represented by Formula (pt-1), or a salt of the compound represented by Formula (pt-1), 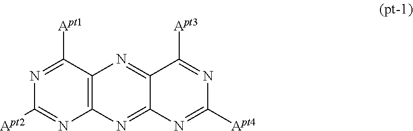
in the formula, A^{pt1} to A^{pt4} each independently represent a hydrogen atom, a hydroxy group, a thiol group, an alkyl group, an alkoxy group, an aryl group, an aryloxy group, or —NR^{pt1}R^{pt2},
R^{pt1} and R^{pt2} each independently represent a hydrogen atom, an alkyl group, an aryl group, —CO—R^{pt3}, —COO—R^{pt3}, or —CONH—R^{pt3}, and
R^{pt3} represents an alkyl group or an aryl group.

3. The coloring composition according to claim 1,
wherein the coloring material further contains a yellow coloring material other than the pteridin pigment.

4. The coloring composition according to claim 3,
wherein the yellow coloring material other than the pteridin pigment is at least one selected from an isoindoline compound or a quinophthalone compound.

5. The coloring composition according to claim 1,
wherein the coloring composition further includes at least one selected from a red coloring material or a green coloring material.

6. The coloring composition according to claim 1,
wherein the coloring composition contains the coloring material in an amount of 50% by mass or more in the total solid content of the coloring composition.

7. The coloring composition according to claim 1,
wherein the resin includes a resin having an aromatic carboxyl group.

8. The coloring composition according to claim 1,
wherein the resin includes a resin having an acid group and a resin having a basic group.

9. The coloring composition according to claim 1, further comprising:
a polymerizable compound; and
a photopolymerization initiator.

10. The coloring composition according to claim 1,
wherein the coloring composition is used for a color filter or an infrared transmitting filter.

11. A film obtained from the coloring composition according to claim 1.

12. An optical filter comprising:
the film according to claim 11.

13. A solid-state imaging element comprising:
the film according to claim 11.

14. An image display device comprising:
the film according to claim 11.
